(19) United States
(12) Patent Application Publication
(10) Pub. No.: US 2018/0101100 A1
(43) Pub. Date: Apr. 12, 2018

(54) TREATMENT LIQUID AND PATTERN FORMING METHOD

(71) Applicant: FUJIFILM Corporation, Tokyo (JP)

(72) Inventors: Hideaki TSUBAKI, Shizuoka (JP); Toru TSUCHIHASHI, Shizuoka (JP); Wataru NIHASHI, Shizuoka (JP)

(73) Assignee: FUJIFILM Corporation, Tokyo (JP)

(21) Appl. No.: 15/838,366

(22) Filed: Dec. 12, 2017

Related U.S. Application Data
(63) Continuation of application No. PCT/JP2016/064697, filed on May 18, 2016.

(30) Foreign Application Priority Data
Jun. 24, 2015 (JP) 2015-127008

(51) Int. Cl. G03F 7/32; G03F 7/20; G03F 7/16; G03F 7/38; G03F 7/40

(52) U.S. Cl. CPC G03F 7/325; G03F 7/2002; G03F 7/16; G03F 7/2037; G03F 7/38; G03F 7/40; G03F 7/168

(57) ABSTRACT

A treatment liquid for rinsing and patterning a resist film obtained from an actinic ray-sensitive composition includes an organic solvent in which a content of a compound containing a sulfur atom in the treatment liquid is 10 mmol/L or lower, and the organic solvent is a hydrocarbon solvent. A pattern forming method includes: forming a resist film using an actinic ray-sensitive or radiation-sensitive composition; exposing the resist film; and treating the exposed resist film with the treatment liquid.

### CROSS-REFERENCE TO RELATED APPLICATIONS

This application is a Continuation of PCT International Application No. PCT/JP2016/064697 filed on May 18, 2016, which claims priority under 35 U.S.C § 119(a) to Japanese Patent Application No. 2015-127008 filed on Jun. 24, 2015. Each of the above application(s) is hereby expressly incorporated by reference, in its entirety, into the present application.

### BACKGROUND OF THE INVENTION

### 1. Field of the Invention

The present invention relates to a treatment liquid for patterning a resist film and a pattern forming method.

More specifically, the present invention relates to a treatment liquid which is used in a manufacturing process of a semiconductor such as an integrated circuit (IC), a manufacturing process of a circuit substrate such as a liquid crystal or a thermal head, a lithography process of other photofabrication processes, and the like, and a pattern forming method.

### 2. Description of the Related Art

In the related art, in a manufacturing process of a semiconductor device such as an integrated circuit (IC) or a large scale integrated circuit (LSI), lithographic microfabrication using a photoresist composition has been performed. Recently, along with high integration of integrated circuits, ultrafine pattern formation on a submicron region or a quarter micron region has been required. Accordingly, a g-line has been used for exposure in the related art, whereas an i-line and further KrF excimer laser light are currently used for exposure. Therefore, the exposure wavelength tends to be shortened. Further, the development of not only lithography using excimer laser light but also lithography using an electron beam, an X-ray, or an extreme ultraviolet (EUV) ray has been progressing.

In this lithography, after forming a film using a photoresist composition (also called an actinic ray-sensitive or radiation-sensitive composition or a chemically amplified resist composition), the obtained film may be developed with a developer, or the developed film may be rinsed with a rinsing liquid.

For example, JP2014-217884A discloses that an organic treatment liquid including an ester solvent or a hydrocarbon solvent as an organic solvent is used as a developer or a rinsing liquid.

### SUMMARY OF THE INVENTION

Recently, along with high integration of integrated circuits, fine pattern formation using a photoresist composition (actinic ray-sensitive or radiation-sensitive composition) has been required. During this fine pattern formation, foreign matter formed on a surface of a resist pattern causes a defect, which leads to deterioration in the performance of the resist pattern. The present inventors repeatedly performed an investigation on this problem, and found that this foreign matter is formed particularly due to a compound containing a sulfur atom (hereinafter, also referred to as “sulfur-containing compound”), the sulfur-containing compound being incorporated from the organic solvent or the like which is included in the developer and the rinsing liquid described in JP2014-217884A. That is, it is presumed that the sulfur-containing compound derived from the organic solvent material interacts with a component in the resist pattern and thus remains on the surface of the resist pattern without being volatilized even after drying in a rinsing step, which causes the defect of the foreign matter.

The present invention has been made in consideration of the above-described points, an object thereof is to provide a treatment liquid for patterning a resist film and a pattern forming method, the treatment liquid being capable of suppressing occurrence of a defect on a resist pattern.

The present inventors found that the desired effect can be obtained by adjusting the content of a sulfur-containing compound in a treatment liquid to be a specific value or lower. More specifically, the present inventors found that the object can be achieved with the following configurations.

(1) A treatment liquid for rinsing and patterning a resist film obtained from an actinic ray-sensitive or radiation-sensitive composition, the treatment liquid includes an organic solvent,

in which a content of a compound containing a sulfur atom in the treatment liquid is 10 mmol/L or lower.

(2) The treatment liquid according to (1) may be used for developing a resist film obtained from an actinic ray-sensitive or radiation-sensitive composition. (3) The treatment liquid according to (2),

in which the organic solvent is an ester solvent.

(4) The treatment liquid according to (3),

in which the ester solvent is at least one selected from the group consisting of butyl acetate, amyl acetate, isoamyl acetate, 2-methylbutyl acetate, 1-methylbutyl acetate, hexyl acetate, pentyl propionate, hexyl propionate, heptyl propionate, and butyl butanoate.

(5) The treatment liquid according to (1)

in which the treatment liquid is a rinsing liquid.

(6) The treatment liquid according to (5),

in which the organic solvent is a hydrocarbon solvent.

(7) The treatment liquid according to (6),

in which the organic solvent is a hydrocarbon solvent having 5 or more carbon atoms.

(8) The treatment liquid according to (6) or (7),

in which the hydrocarbon solvent includes undecane.

(9) The treatment liquid according to any one of (1) to (8),

in which a content of a compound containing a phosphorus atom in the treatment liquid is 10 mmol/L or lower.

(10) The treatment liquid according to any one of (1) to (9),

in which a boiling point of the compound containing a sulfur atom is 190° C. or higher.

(11) A pattern forming method comprising:

forming a resist film using an actinic ray-sensitive or radiation-sensitive composition;

exposing the resist film; and

treating the exposed resist film with the treatment liquid according to (1), (2), (3), (4), (9), or (10).

(12) The pattern forming method according to (11),

in which the treating includes rinsing with a rinsing liquid, and

the rinsing liquid is the treatment liquid according to (1), (5), (6), (7), (8), (9), or (10).

According to the present invention, a treatment liquid for patterning a resist film and a pattern forming method can be provided, the treatment liquid being capable of suppressing occurrence of a defect on a resist pattern.

### DESCRIPTION OF THE PREFERRED EMBODIMENTS

[Treatment Liquid]

A treatment liquid according to the present invention is a treatment liquid for patterning a resist film, the treatment liquid including an organic solvent and being used for rinsing a resist film obtained from an actinic ray-sensitive or radiation-sensitive composition. A content of a sulfur-containing compound in the treatment liquid according to the present invention is 10 mmol/L or lower. The treatment liquid may be used for developing a resist film obtained from an actinic ray-sensitive or radiation-sensitive composition.

With the treatment liquid according to the present invention, occurrence of a defect on a resist pattern can be suppressed. The detailed reason for this is not clear but is presumed to be as follows.

That is, since the content of the sulfur-containing compound in the treatment liquid used as a developer or a rinsing liquid is low, a reaction between the sulfur-containing compound included in the treatment liquid and a component, in particular, a polar group in a polymer component included in an exposed film (resist film) can be suppressed. As a result, formation of foreign matter on a surface of the resist pattern, which may occur due to the reaction between the sulfur-containing compound and the polar group or the like in the polymer component, can be suppressed. Therefore, formation of a defect on the resist pattern can be suppressed.

In addition, it is preferable the content of the sulfur-containing compound in a treatment liquid used for a subsequent step is lower, that is, it is preferable that the treatment liquid according to the present invention is used as a rinsing liquid.

In the treatment liquid according to the present invention, the content (concentration) of the sulfur-containing compound is 10 mmol/L or lower, preferably 2.5 mmol/L or lower, and more preferably 1.0 mmol/L or lower, and it is most preferable that the treatment liquid does not substantially include the sulfur-containing compound.

By adjusting the content of the sulfur-containing compound to be 10 mmol/L or lower as described above, occurrence of a defect on a resist pattern can be suppressed, for example, even in a case where the treatment liquid is used after stored in a storage container (for example, a container described in JP2014-112176A) at room temperature (23° C.) for 6 months in a state where the storage container is closed with a stopper.

Here, “substantially not including the sulfur-containing compound” represents that, in a case where the content (concentration) of the sulfur-containing compound is measured using a method (for example, a measurement method described below) capable of measuring the content of the sulfur-containing compound, the measured value is not detected (is lower than a detection limit value).

Regarding the lower limit of the content (concentration) of the sulfur-containing compound, as described above, it is most preferable that the treatment liquid does not substantially include the sulfur-containing compound. However, in a case where a treatment such as distillation is performed as described below to reduce the content of the sulfur-containing compound, the costs increase. In consideration of the costs for industrial use, the content of the sulfur-containing compound may be 0.01 mmol/L or higher.

In the present invention, the sulfur-containing compound denotes an organic matter containing a sulfur atom which is originally included as an impurity in components constituting the treatment liquid. For example, in a naturally-derived hydrocarbon solvent such as decane or undecane, for example, a small amount of a sulfur-containing compound having a similar boiling point to that of the hydrocarbon solvent such as benzothiophene or 3-methylbenzothiophene tends to remain without being completely removed therefrom even after petroleum refining and distillation.

Examples of the sulfur-containing compound included in the treatment liquid include a thiol, a sulfide, and a thiophene. Among these, a sulfur compound having a boiling point of 190° C. or higher (preferably 220° C. or higher, and more preferably 280° C. or higher) is used.

Specific examples of the thiol include methanethiol, ethanethiol (ethylmercaptan), 3-methyl-2-butene-1-thiol, 2-methyl-3-butenethiol, furfurylthiol (furfurylmercaptan), 3-mercapto-3-methylbutyl formate, phenylmercaptan, methylfurfurylmercaptan, ethyl 3-mercaptobutanoate, 3-mercapto-3-methylbutanol, and 4-mercapto-4-methyl-2-pentanone.

Examples of the sulfide include dimethyl sulfide, dimethyl trisulfide, diisopropyl trisulfide, and bis(2-methyl-3-furyl)disulfide.

Examples of the thiophene include alkylthiophene, benzothiophene, dibenzothiophene, phenanthrothiophene, benzonaphthothiophene, and thiophene sulfide.

By adjusting the content of a thiophene, in particular, a benzothiophene (for example, benzothiophene or 3-methylbenzothiophene) to be 10 mmol/L or lower, occurrence of a defect on a resist pattern can be suppressed.

The content of the sulfur-containing compound in the treatment liquid according to the present invention can be measured using a method defined in JIS K 2541-6:2013 “Determination of Sulfur Content (Ultraviolet Fluorescence Method)”.

The present inventors found that, in a case where the treatment liquid further includes a compound containing a phosphorus atom (hereinafter, also referred to as “phosphorus-containing compound”), the phosphorus-containing compound is likely to cause a defect of foreign matter as in the case of the sulfur-containing compound. It is presumed that the phosphorus-containing compound interacts with a component in a resist pattern and thus remains on a surface of the resist pattern without being volatilized even after drying in a rinsing step.

Therefore, in the treatment liquid according to the present invention, the content of the compound containing a phosphorus atom is preferably 10 mmol/L or lower, more preferably 5 mmol/L or lower or lower, still more preferably 2.5 mmol/L or lower or lower, and even still more preferably 1.0 mmol/L or lower, and it is even yet still more preferable that the treatment liquid does not substantially include the phosphorus-containing compound.

Here, “substantially not including the phosphorus-containing compound” represents that, in a case where the content (concentration) of the sulfur-containing compound is measured using a method (for example, a measurement method described below) capable of measuring the content of the sulfur-containing compound, the measured value is not detected (is lower than a detection limit value).

Regarding the lower limit of the content (concentration) of the phosphorus-containing compound, as described above, it is most preferable that the treatment liquid does not substantially include the sulfur-containing compound. However, in a case where a treatment such as distillation is performed as described below to reduce the content of the phosphorus-containing compound, the costs increase. In consideration of the costs for industrial use, the content of the phosphorus-containing compound may be 0.01 mmol/L or higher.

The phosphorus-containing compound denotes an organic matter containing a phosphorus atom which is originally included as an impurity in components constituting the treatment liquid, or an organic matter containing a phosphorus atom which is incorporated during handling of the treatment liquid. Examples of the phosphorus-containing compound include phosphoric acid and a phosphorus catalyst (an organic phosphine or an organic phosphine oxide) used for synthesizing the organic solvent.

The content of the compound containing a phosphorus atom in the treatment liquid according to the present invention can be determined as the total phosphorus content by absorption photometry based on a method defined in JIS K 0102:2013. In the case of an organic matter containing a phosphorus atom, the content thereof can be individually determined, for example, by gas chromatography.

In the treatment liquid according to the present invention, the content of the sulfur-containing compound or the phosphorus-containing compound can be reduced by performing distillation or filtration of an organic solvent to be used.

The treatment liquid according to the present invention is typically used as a developer or a rinsing liquid. It is preferable that the treatment liquid includes an organic solvent and further includes an antioxidant and/or a surfactant.

The organic solvent which is included in the treatment liquid, and the antioxidant and the surfactant which are optionally included in the treatment liquid will be described in detail in the description of a developer and a rinsing liquid below.

Hereinafter, the developer and the rinsing liquid will be described in this order regarding the components which are included therein and the components which may be included therein.

<Developer>

A developer which is an example of the treatment liquid according to the present invention is used in a development step described below. In addition, the developer includes an organic solvent and thus can also be called an organic developer.

(Organic Solvent)

A vapor pressure of the organic solvent (in the case of a mixed solvent, the total vapor pressure) at 20° C. is preferably 5 kPa or lower, more preferably 3 kPa or lower, still more preferably 2 kPa or lower.

By adjusting the vapor pressure of the organic solvent to be 5 kPa or lower, evaporation of developer on a substrate or in a developing cup suppressed, and uniformity in the temperature in a wafer surface is improved. As a result, uniformity in the dimension in a wafer surface is improved.

As the organic solvent used in the developer, various organic solvents can be widely used, and examples thereof include an ester solvent, a ketone solvent, an alcohol solvent, an amide solvent, an ether solvent, and a hydrocarbon solvent.

In the present invention, the ester solvent denotes a solvent having an ester group in a molecule, the ketone solvent denotes a solvent having a ketone group in a molecule, the alcohol solvent denotes a solvent having an alcoholic hydroxyl group in a molecule, the amide solvent denotes a solvent having an amido group in a molecule, and the ether solvent denotes a solvent having an ether bond in a molecule. In a case where a solvent has a plurality of groups among the functional groups in one molecule, this solvent belongs to all the solvents having the functional groups. For example, diethylene glycol monomethyl ether belongs to both the alcohol solvent and the ether solvent in the above-described classification.

In particular, it is preferable that the developer includes at least one solvent selected from the group consisting of the ketone solvent, the ester solvent, the alcohol solvent, and the ether solvent.

Examples of the ester solvent include methyl acetate, ethyl acetate, butyl acetate, isobutyl acetate, propyl acetate, isopropyl acetate, amyl acetate (pentyl acetate), isoamyl acetate (isopentyl acetate, 3-methylbutyl acetate), 2-methylbutyl acetate, 1-methylbutyl acetate, hexyl acetate, isohexyl acetate, heptyl acetate, octyl acetate, ethyl methoxyacetate, ethyl ethoxyacetate, propylene glycol monomethyl ether acetate (PGMEA; synonym: 1-methoxy-2-acetoxy propane), ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, 2-methoxy butyl acetate, 3-methoxy butyl acetate, 4-methoxy butyl acetate, 3-methyl-3-methoxy butyl acetate, 3-ethyl-3-methoxy butyl acetate, propylene glycol monoethyl ether acetate, propylene glycol propyl ether acetate, 2-ethoxy butyl acetate, 4-ethoxy butyl acetate, 4-propoxy butyl acetate, 2-methoxy pentyl acetate, 3-methoxy pentyl acetate, 4-methoxy pentyl acetate, 2-methyl-3-methoxy pentyl acetate, 3-methyl-3-methoxy pentyl acetate, 3-methyl-4-methoxy pentyl acetate, 4-methyl-4-methoxy pentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, butyl propionate, pentyl propionate, hexyl propionate, heptyl propionate, butyl butanoate, isobutyl butanoate, pentyl butanoate, hexyl butanoate, isobutyl isobutanoate, propyl pentanoate, isopropyl pentanoate, butyl pentanoate, pentyl pentanoate, ethyl hexanoate, propyl hexanoate, butyl hexanoate, isobutyl hexanoate, methyl heptanoate, ethyl heptanoate, propyl heptanoate, cyclohexyl acetate, cycloheptyl acetate, 2-ethylhexyl acetate, cyclopentyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Among these, butyl acetate, amyl acetate, isoamyl acetate, 2-methylbutyl acetate, 1-methylbutyl acetate, hexyl acetate, pentyl propionate, hexyl propionate, heptyl propionate, or butyl butanoate is preferably used, and isoamyl acetate is more preferably used.

Examples of the ketone solvent include 1-octanone, 2-octanone, 1-nonanone, 2-nonanone, acetone, 2-heptanone, 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonyl alcohol, acetyl carbinol, acetophenone, methyl naphthyl ketone, isophorone, propylene carbonate, and γ-butyrolactone. Among these, 2-heptanone is preferable.

Examples of the alcohol solvent include: an alcohol (monovalent alcohol) such as methanol, ethanol, 1-propanol, isopropanol, 1-butanol, 2-butanol, 3-methyl-1-butanol, tert-butyl alcohol, 1-pentanol, 2-pentanol, 1-hexanol, 1-heptanol, 1-octanol, 1-decanol, 2-hexanol, 2-heptanol, 2-octanol, 3-hexanol, 3-heptanol, 3-octanol, 4-octanol, 3-methyl-3-pentanol, cyclopentanol, 2,3-dimethyl-2-butanol, 3,3-dimethyl-2-butanol, 2-methyl-2-pentanol, 2-methyl-3-pentanol, 3-methyl-2-pentanol, 4-methyl-2-pentanol, 4-methyl-3-pentanol, cyclohexanol, 5-methyl-2-hexanol, 4-methyl-2-hexanol, 4,5-dimethyl-2-hexanol, 6-methyl-2-heptanol, 7-methyl-2-octanol, 8-methyl-2-nonanol, 9-methyl-2-decanol, 3-methoxy-1-butanol; a glycol solvent such as ethylene glycol, diethylene glycol, or triethylene glycol; and an glycol ether solvent having a hydroxyl group such as ethylene glycol monomethyl ether, propylene glycol monomethyl ether (PGME; synonym: 1-methoxy-2-propanol), diethylene glycol monomethyl ether, triethylene glycol monoethyl ether, methoxy methyl butanol, ethylene glycol monoethyl ether, ethylene glycol monopropyl ether, ethylene glycol monobutyl ether, propylene glycol monoethyl ether, propylene glycol monopropyl ether, propylene glycol monobutyl ether, or propylene glycol monophenyl ether. Among these, a glycol ether solvent is preferably used.

Examples of the ether solvent include: the above-described glycol ether solvent having a hydroxyl group; an glycol ether solvent having no hydroxyl group such as propylene glycol dimethyl ether, propylene glycol diethyl ether, diethylene glycol dimethyl ether, or diethylene glycol diethyl ether; an aromatic ether solvent such as anisole or phenetole; and dioxane, tetrahydrofuran, tetrahydropyran, perfluoro-2-butyl tetrahydrofuran, perfluoro tetrahydrofuran, 1,4-dioxane, and isopropyl ether. Preferably, a glycol ether solvent, or an aromatic ether solvent such as anisole is used.

Examples of the amide solvent include N-methyl-2-pyrrolidone, N,N-dimethylacetamide, N,N-dimethylformamide, hexamethylphosphoric amide, and 1,3-dimethyl-2-imidazolidinone.

Examples of the hydrocarbon solvent include: an aliphatic hydrocarbon solvent such as pentane, hexane, octane, nonane, decane, dodecane, undecane, hexadecane, 2,2,4-trimethylpentane, 2,2,3-trimethylhexane, perfluorohexane, or perfluoroheptane; and an aromatic hydrocarbon solvent such as toluene, xylene, ethylbenzene, propylbenzene, 1-methylpropylbenzene, 2-methylpropylbenzene, dimethylbenzene, diethylbenzene, ethylmethylbenzene, trimethylbenzene, ethyldimethylbenzene, or dipropylbenzene. In addition, as the hydrocarbon solvent, an unsaturated hydrocarbon solvent can be used, and examples thereof include octene, nonene, decene, undecene, dodecene, and hexadecene. The number of double bonds or triple bonds in the unsaturated hydrocarbon solvent is not particularly limited, and a hydrocarbon chain may be present at an arbitrary position. In addition, in a case where the unsaturated hydrocarbon solvent has a double bond, a cis-form and a trans-form may be present together.

The aliphatic hydrocarbon solvent, which is the hydrocarbon solvent, may be a mixture of compounds having the same carbon atoms and different structures. For example, in a case where decane is used as the aliphatic hydrocarbon solvent, the aliphatic hydrocarbon solvent may include compounds having the same carbon atoms and different structures such as 2-methylnonane, 2,2-dimethyloctane, 4-ethyloctane, and isooctane.

In addition, as the compounds having the same carbon atoms and different structures, one kind may be included, and a plurality of kinds may be included.

In the developer, in a case where an extreme ultraviolet (EUV) ray or an electron beam (EB) is used in an exposure step described below, it is preferable that an ester solvent having 7 or more carbon atoms (preferably 7 to 14 carbon atoms, more preferably 7 to 12 carbon atoms, and still more preferably 7 to 10 carbon atoms) and having 2 or less heteroatoms is used from the viewpoint of suppressing swelling of a resist film.

The heteroatom of the ester solvent is an atom other than a carbon atom and a hydrogen atom, and examples thereof include an oxygen atom, a nitrogen atom, and a sulfur atom. The number of heteroatoms is preferably 2 or less.

Preferable examples of the ester solvent having 7 or more carbon atoms and 2 or less heteroatom include amyl acetate, isoamyl acetate, 2-methylbutyl acetate, 1-methylbutyl acetate, hexyl acetate, pentyl propionate, hexyl propionate, heptyl propionate, and butyl butanoate. In particular, isoamyl acetate is preferably used.

In the developer, in a case where an extreme ultraviolet (EUV) ray or an electron beam (EB) is used in an exposure step described below, a mixed solvent of the ester solvent and the hydrocarbon solvent or a mixed solvent of the ketone solvent and the hydrocarbon solvent may be used instead of the ester solvent having 7 or more carbon atoms and having 2 or less heteroatoms. Even in this case, swelling of a resist film can be effectively suppressed.

In a case where the ester solvent and the hydrocarbon solvent are used in combination, it is preferable that isoamyl acetate is used as the ester solvent. In addition, it is preferable that a saturated hydrocarbon solvent (for example, octane, nonane, decane, dodecane, undecane, or hexadecane) is used as the hydrocarbon solvent from the viewpoint of adjusting the solubility of a resist film.

In a case where the ketone solvent and the hydrocarbon solvent are used in combination, it is preferable that 2-heptanone is used as the ketone solvent. In addition, it is preferable that a saturated hydrocarbon solvent (for example, octane, nonane, decane, dodecane, undecane, or hexadecane) is used as the hydrocarbon solvent from the viewpoint of adjusting the solubility of a resist film.

In addition, in a case where the ester solvent and the hydrocarbon solvent are used in combination, or in a case where the ketone solvent and the hydrocarbon solvent are used in combination, an unsaturated hydrocarbon solvent can be used as the hydrocarbon solvent, and examples thereof include octene, nonene, decene, undecene, dodecene, and hexadecene. The number of double bonds or triple bonds in the unsaturated hydrocarbon solvent is not particularly limited, and a hydrocarbon chain may be present at an arbitrary position. In addition, in a case where the unsaturated hydrocarbon solvent has a double bond, a cis-form and a trans-form may be present together.

In a case where the mixed solvent is used, the content of the hydrocarbon solvent depends on the solvent solubility of a resist film. Therefore, the content of the hydrocarbon solvent is not particularly limited and may be appropriately adjusted to be a necessary value.

A mixture of a plurality of kinds among the organic solvents may be used, or a mixture of one of the organic solvent and a solvent other than the organic solvents and water may be used. However, in order to sufficiently exhibit the effects of the present invention, it is preferable that the moisture content is lower than 10 mass % with respect to the total mass of the developer, and it is more preferable that the developer does not include water.

The concentration (in the case of a mixture of a plurality of solvents) of the organic solvent in the developer is preferably 50 mass % or higher, more preferably 50 to 100 mass %, still more preferably 85 to 90 mass %, and even still more preferably 95 to 100 mass %. It is most preferable that the developer includes substantially only the organic solvent. Substantially including only the organic solvent also represents a case where the developer includes a small amount of a surfactant, an antioxidant, a stabilizer, an antifoaming agent, or the like in addition to the organic solvent.

Preferable examples of the organic solvent used in the developer include an ester solvent.

As the ester solvent, a solvent represented by Formula (S1) described below or a solvent represented by Formula (S2) is more preferably used, a solvent represented by Formula (S1) is still more preferably used, alkyl acetate is even still more preferably used, butyl acetate, amyl acetate (pentyl acetate), or isoamyl acetate (isopentyl acetate) is most preferably used.

R—C(═O)—O—R′ Formula (S1)

In Formula (S1), R and R′ each independently represent a hydrogen atom, an alkyl group, a cycloalkyl group, an alkoxyl group, an alkoxycarbonyl group, a carboxyl group, a hydroxyl group, a cyano group, or a halogen atom. R and R′ may be bonded to each other to form a ring.

The number of carbon atoms in the alkyl group, the alkoxyl group, and the alkoxycarbonyl group represented by R and R′ is preferably 1 to 15, and the number of carbon atoms in the cycloalkyl group represented by R and R′ is preferably 3 to 15.

R and R′ represent preferably a hydrogen atom or an alkyl group. The alkyl group, the cycloalkyl group, the alkoxyl group, and the alkoxycarbonyl group represented by R and R′, and a ring which is formed by R and R′ being bonded to each other may be substituted with a hydroxyl group, a group (for example, an acyl group, an aldehyde group, or an alkoxycarbonyl group) including a carbonyl group, or a cyano group.

Examples of the solvent represented by Formula (S1) include methyl acetate, butyl acetate, ethyl acetate, isopropyl acetate, amyl acetate, isoamyl acetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, and ethyl 2-hydroxypropionate.

In particular, it is preferable that R and R′ represent an unsubstituted alkyl group. As the solvent represented by Formula (S1), alkyl acetate is preferable, butyl acetate, amyl acetate (pentyl acetate), or isoamyl acetate (isopentyl acetate) is more preferable, and isoamyl acetate is still more preferable.

The solvent represented by Formula (S1) may be used in combination with one or more other organic solvents. The combination solvent is not particularly limited as long as it can be mixed with the solvent represented by Formula (S1) without being separated therefrom. A combination of the solvents represented by Formula (S1) may be used, or a mixture of the solvent represented by Formula (S1) and a solvent selected from the group consisting of another ester solvent, a ketone solvent, an alcohol solvent, an amide solvent, an ether solvent, and a hydrocarbon solvent may be used. As the combination solvent, one or more kinds may be used, but one kind is preferably used from the viewpoint of obtaining stable performance. In a case where a mixture of the solvent represented by Formula (S1) and one combination solvent is used, a mixing ratio of the solvent represented by Formula (S1) to the combination solvent is typically 20:80 to 99:1, preferably 50:50 to 97:3, more preferably 60:40 to 95:5, and most preferably 60:40 to 90:10 by mass.

As the organic solvent used in the developer, a glycol ether solvent may be used. As the glycol ether solvent, a solvent represented by the following Formula (S2) may be used.

R″—C(═O)—O—R′″—O—R″″ Formula (S2)

In Formula (S2),

R″ and R″″ each independently represent a hydrogen atom, an alkyl group, a cycloalkyl group, an alkoxyl group, an alkoxycarbonyl group, a carboxyl group, a hydroxyl group, a cyano group, or a halogen atom. R″ and R″″ may be bonded to each other to form a ring.

It is preferable that R″ and R″″ each independently represent a hydrogen atom or an alkyl group. The number of carbon atoms in the alkyl group, the alkoxyl group, and the alkoxycarbonyl group represented by R″ and R″″ is preferably 1 to 15, and the number of carbon atoms in the cycloalkyl group represented by R″ and R″″ is preferably 3 to 15. R′″ represents an alkylene group or a cycloalkylene group. It is preferable that R′″ represents an alkylene group. The number of carbon atoms in the alkylene group represented by R′″ is preferably 1 to 10. The number of carbon atoms in the cycloalkylene group represented by R′″ is preferably 3 to 10.

The alkyl group, the cycloalkyl group, the alkoxyl group, and the alkoxycarbonyl group represented by R″ and R″″, the alkylene group and the cycloalkylene group represented by R′″, and a ring which is formed by R″ and R″″ being bonded to each other may be substituted with a hydroxyl group, a group (for example, an acyl group, an aldehyde group, or an alkoxycarbonyl group) including a carbonyl group, or a cyano group.

In Formula (S2), the alkylene group represented by R′″ may have an ether bond in an alkylene chain.

Examples of the solvent represented by Formula (S2) include propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monophenyl ether acetate, diethylene glycol monobutyl ether acetate, diethylene glycol monoethyl ether acetate, propylene glycol monoethyl ether acetate, propylene glycol propyl ether acetate, methyl-3-methoxypropionate, ethyl-3-methoxypropionate, ethyl-3-ethoxypropionate, propyl-3-methoxypropionate, ethyl methoxyacetate, ethyl ethoxyacetate, 2-methoxy butyl acetate, 3-methoxy butyl acetate, 4-methoxy butyl acetate, 3-methyl-3-methoxy butyl acetate, 3-ethyl-3-methoxy butyl acetate, 2-ethoxy butyl acetate, 4-ethoxy butyl acetate, 4-propoxy butyl acetate, 2-methoxy pentyl acetate, 3-methoxy pentyl acetate, 4-methoxy pentyl acetate, 2-methyl-3-methoxy pentyl acetate, 3-methyl-3-methoxy pentyl acetate, 3-methyl-4-methoxy pentyl acetate, and 4-methyl-4-methoxy pentyl acetate. Among these, propylene glycol monomethyl ether acetate is preferable.

In particular, it is preferable that R″ and R″″ represent an unsubstituted alkyl group and R′″ represents an unsubstituted alkylene group, it is more preferable that R″ and R″″ represent a methyl group or an ethyl group, and it is still more preferable that R″ and R″″ represent a methyl group.

The solvent represented by Formula (S2) may be used in combination with one or more other organic solvents. The combination solvent is not particularly limited as long as it can be mixed with the solvent represented by Formula (S2) without being separated therefrom. A combination of the solvents represented by Formula (S2) may be used, or a mixture of the solvent represented by Formula (S2) and a solvent selected from the group consisting of another ester solvent, a ketone solvent, an alcohol solvent, an amide solvent, an ether solvent, and a hydrocarbon solvent may be used. As the combination solvent, one or more kinds may be used, but one kind is preferably used from the viewpoint of obtaining stable performance. In a case where a mixture of the solvent represented by Formula (S2) and one combination solvent is used, a mixing ratio of the solvent represented by Formula (S2) to the combination solvent is typically 20:80 to 99:1, preferably 50:50 to 97:3, more preferably 60:40 to 95:5, and most preferably 60:40 to 90:10 by mass.

In addition, preferable examples of the organic solvent used in the developer include an ether solvent.

Examples of the ether solvent include the above-described ether solvents. Among these, an ether solvent having one or more aromatic rings is preferable, a solvent represented by the following Formula (S3) is more preferable, and anisole is most preferable.

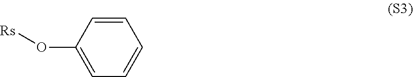

In Formula (S3), R_{S} represents an alkyl group.

As the alkyl group, an alkyl group having 1 to 4 carbon atoms is preferable, a methyl group or an ethyl group is more preferable, and a methyl group is most preferable.

As the organic solvent included in the developer according to the present invention, an organic solvent used in an actinic ray-sensitive or radiation-sensitive composition described below can be used.

(Surfactant)

It is preferable that the developer includes a surfactant. As a result, wettability on a resist film is improved, and development is more effectively carried out.

As the surfactant, the same surfactant as that used in an actinic ray-sensitive or radiation-sensitive composition described below can be used.

The content of the surfactant is typically 0.001 to 5 mass %, preferably 0.005 to 2 mass %, and more preferably 0.01 to 0.5 mass % with respect to the total mass of the developer.

(Antioxidant) It is preferable that the developer includes an antioxidant. As a result, formation of an oxidant over time can be suppressed, and the content of an oxidant can be further reduced.

As the antioxidant, a well-known antioxidant can be used. For use in a semiconductor, an amine antioxidant or a phenol antioxidant is preferably used.

Examples of the amine antioxidant include: a naphthylamine antioxidant such as 1-naphthylamine, phenyl-1-naphthylamine, p-octylphenyl-1-naphthylamine, p-nonylphenyl-1-naphthylamine, p-dodecylphenyl-1-naphthylamine, or phenyl-2-naphthylamine; a phenylenediamine antioxidant such as N,N′-diisopropyl-p-phenylenediamine, N,N′-diisobutyl-p-phenylenediamine, N,N′-diphenyl-p-phenylenediamine, N,N′-di-3-naphthyl-p-phenylenediamine, N-phenyl-N′-isopropyl-p-phenylenediamine, N-cyclohexyl-N′-phenyl-p-phenylenediamine, N-1,3-dimethylbutyl-N′-phenyl-p-phenylenediamine, dioctyl-p-phenylenediamine, phenylhexyl-p-phenylenediamine, or phenyloctyl-p-phenylenediamine; a diphenylamine antioxidant such as dipyridylamine, diphenylamine, p,p′-di-n-butyldiphenylamine, p,p′-di-t-butyldiphenylamine, p,p′-di-t-pentyldiphenylamine, p,p′-dioctyldiphenylamine, p,p′-dinon-t-butyldiphenylamine, p,p′-di-t-pentyldiphenylamine, p,p′-dioctyldiphenylamine, p,p′-dinonyldiphenylamine, p,p′-didecyldiphenylamine, p,p′-didodecyldiphenylamine, p,p′-distyryldiphenylamine, p,p′-dimethoxydiphenylamine, 4,4′-bis(4-α,α-dimethylbenzyl)diphenylamine, p-isopropoxydiphenylamine, or dipyridylamine; and a phenothiazine antioxidant such as phenothiazine, N-methylphenothiazine, N-ethylphenothiazine, 3,7-dioctylphenothiazine, phenothiazine carboxylate, or phenoselenazine.

Examples of the phenol antioxidant include 2,6-di-tertiary butylphenol (hereinafter, tertiary butyl will be abbreviated as t-butyl), 2,6-di-t-butyl-p-cresol, 2,6-di-t-butyl-4-methylphenol, 2,6-di-t-butyl-4-ethylphenol, 2,4-dimethyl-6-t-butylphenol, 4,4′-methylenebis(2,6-di-t-butylphenol), 4,4′-bis(2,6-di-t-butylphenol), 4,4′-bis(2-methyl-6-t-butylphenol), 2,2′-methylenebis(4-methyl-6-t-butylphenol), 2,2′-methylenebis(4-ethyl-6-t-butylphenol), 4,4′-butylidenebis(3-methyl-6-t-butylphenol), 4,4′-isopropylidenebis(2,6-di-t-butylphenol), 2,2′-methylenebis(4-methyl-6-cyclohexylphenol), 2,2′-methylenebis(4-methyl-6-nonylphenol), 2,2′-isobutylidenebis(4,6-dimethylphenol), 2,6-bis(2′-hydroxy-3′-t-butyl-5′-methylbenzyl)-4-methylphenol, 3-t-butyl-4-hydroxyanisole, 2-t-butyl-4-hydroxyanisole, octyl 3-(4-hydroxy-3,5-di-t-butylphenyl)propionate, stearyl 3-(4-hydroxy-3,5-di-t-butylphenyl)propionate, oleyl 3-(4-hydroxy-3,5-di-t-butylphenyl)propionate, dodecyl 3-(4-hydroxy-3,5-di-t-butylphenyl)propionate, decyl 3-(4-hydroxy-3,5-di-t-butylphenyl)propionate, tetrakis {3-(4-hydroxy-3,5-di-t-butylphenyl)propionyl oxymethyl}methane, 3-(4-hydroxy-3,5-di-t-butylphenyl)propionic acid glycerin monoester, an ester of 3-(4-hydroxy-3,5-di-t-butylphenyl)propionic acid and glycerin monooleyl ether, 3-(4-hydroxy-3,5-di-t-butylphenyl)propionic acid butylene glycol diester, 2,6-di-t-butyl-α-dimethylamino-p-cresol, 2,6-di-t-butyl-4-(N,N′-dimethylaminomethylphenol), tris {(3,5-di-t-butyl-4-hydroxyphenyl)propionyl-oxyethyl} isocyanurate, tris(3,5-di-t-butyl-4-hydroxyphenyl) isocyanurate, 1,3,5-tris(3,5-di-t-butyl-4-hydroxybenzyl) isocyanurate, 1,3,5-tris(4-t-butyl-3-hydroxy-2,6-dimethylbenzyl) isocyanurate, N,N′-hexamethylenebis(3,5-di-t-butyl-4-hydroxy-hydrocinnamate), 3,9-bis[1,1-dimethyl-2-{β-(3-t-butyl-4-hydroxy-5-methylphenyl) propionyloxy} ethyl]-2,4,8,10-tetraoxaspiro[5,5]undecane, 1,1,3-tris(2-methyl-4-hydroxy-5-t-butylphenyl)butane, 1,3,5-trimethyl-2,4,6-tris(3,5-di-t-butyl-4-hydroxybenzyl) benzene, and bis {3,3′-bis-(4′-hydroxy-3′-t-butylphenyl)butyric acid} glycolester.

The content of the antioxidant is not particularly limited and is preferably 0.0001 to 1 mass %, more preferably 0.0001 to 0.1 mass %, still more preferably 0.0001 to 0.01 mass % with respect to the total mass of the developer. In a case where the content of the antioxidant is 0.0001 mass % or higher, a higher antioxidant effect can be obtained. In a case where the content of the antioxidant is 1 mass % or higher, a development residue tends to be suppressed.

(Basic Compound)

It is preferable that the developer according to the present invention includes a basic compound. Specific examples of the basic compound include compounds described as examples of a basic compound (E) which may be included in an actinic ray-sensitive or radiation-sensitive composition described below.

Among the basic compounds which may be included in the developer according to the present invention, the following nitrogen-containing compound can be preferably used.

In a case where the nitrogen-containing compound is included in the developer, the nitrogen-containing compound interacts with a polar group in a resist film due to the action of an acid such that insolubility of an exposed portion in an organic solvent can be further improved. Here, the interaction between the nitrogen-containing compound and the polar group denotes an action of forming a salt, an ionic bond, or the like through the reaction between the nitrogen-containing compound and the polar group.

As the nitrogen-containing compound, a compound represented by Formula (1) is preferable.

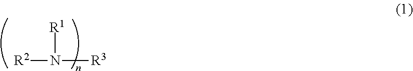

In Formula (1), R¹ and R² each independently represent a hydrogen atom, a hydroxyl group, a formyl group, an alkoxy group, an alkoxycarbonyl group, a branched hydrocarbon group having 1 to 30 carbon atoms, an alicyclic hydrocarbon group having 3 to 30 carbon atoms, an aromatic hydrocarbon group having 6 to 14 carbon atoms, or a group including a combination of two or more kinds of the above-described groups. R³ represents a hydrogen atom, a hydroxyl group, a formyl group, an alkoxy group, an alkoxycarbonyl group, a n-valent branched hydrocarbon group having 1 to 30 carbon atoms, a n-valent alicyclic hydrocarbon group having 3 to 30 carbon atoms, a n-valent aromatic hydrocarbon group having 6 to 14 carbon atoms, or a n-valent group including a combination of two or more kinds of the above-described groups. n represents an integer of 1 or more. In a case where n represents 2 or more, a plurality of R¹'s and R²'s may be the same as or different from each other, respectively. In addition, two of R¹ to R³ may be bonded to each other to form a ring structure together with a nitrogen atom.

Examples of the branched hydrocarbon group having 1 to 30 carbon atoms represented by R¹ and R² include a methyl group, an ethyl group, a n-propyl group, an i-propyl group, a n-butyl group, a 2-methylpropyl group, a 1-methylpropyl group, and a t-butyl group.

Examples of the alicyclic hydrocarbon group having 3 to 30 carbon atoms represented by R¹ and R² include a cyclopropyl group, a cyclopentyl group, a cyclohexyl group, an adamantyl group, and a norbomyl group.

Examples of the aromatic hydrocarbon group having 6 to 14 carbon atoms represented by R¹ and R² include a phenyl group, a tolyl group, and a naphthyl group.

Examples of a group including a combination of two or more kinds of the above-described groups represented by R¹ and R² include an aralkyl group having 6 to 12 carbon atoms such as a benzyl group, a phenethyl group, a naphthylmethyl group, or a naphthylethyl group.

Examples of the n-valent branched hydrocarbon group having 1 to 30 carbon atoms represented by R³ include groups obtained by removing (n−1) hydrogen atoms from the groups described as the examples of the branched hydrocarbon group having 1 to 30 carbon atoms represented by R¹ and R².

Examples of the alicyclic hydrocarbon group having 3 to 30 carbon atoms represented by R³ include groups obtained by removing (n−1) hydrogen atoms from the groups described as the examples of the cyclic hydrocarbon group having 3 to 30 carbon atoms represented by R¹ and R².

Examples of the aromatic hydrocarbon group having 6 to 14 carbon atoms represented by R³ include groups obtained by removing (n−1) hydrogen atoms from the groups described as the examples of the aromatic hydrocarbon group having 6 to 14 carbon atoms represented by R¹ and R².

Examples of the group including a combination of two or more kinds of the above-described groups represented by R³ include groups obtained by removing (n−1) hydrogen atoms from the groups described as the examples of the group including a combination of two or more kinds of the above-described groups represented by R¹ and R².

The groups represented by R¹ to R³ may have a substituent. Specific examples of the substituent include a methyl group, an ethyl group, a propyl group, a n-butyl group, a t-butyl group, a hydroxyl group, a carboxy group, a halogen atom, and an alkoxy group. Examples of the halogen atom include a fluorine atom, a chlorine atom, and a bromine atom. In addition, examples of the alkoxy group include a methoxy group, an ethoxy group, a propoxy group, and a butoxy group.

Examples of the compound represented by Formula (1) include a (cyclo)alkyl amine compound, a nitrogen-containing heterocyclic compound, an amido group-containing compound, and an urea compound.

Examples of the (cyclo)alkyl amine compound include a compound having one nitrogen atom, a compound having two nitrogen atoms, and a compound having three nitrogen atoms.

Examples of the (cyclo)alkyl amine compound having one nitrogen atom include: a mono(cyclo)alkyl amine such as n-hexylamine, n-heptylamine, n-octylamine, n-nonylamine, 1-aminodecane, or cyclohexylamine; a di(cyclo)alkyl amine such as di-n-butylamine, di-n-heptylamine, di-n-hexylamine, di-n-heptylamine, di-n-octylamine, di-n-nonylamine, di-n-decylamine, cyclohexylmethylamine, or dicyclohexylamine; a tri(cyclo)alkyl amine such as triethylamine, tri-n-propylamine, tri-n-butylamine, tri-n-pentylamine, tri-n-hexylamine, tri-n-heptylamine, tri-n-octylamine, tri-n-nonylamine, tri-n-decylamine, cyclohexyldimethylamine, methyldicyclohexylamine, or tricyclohexylamine; a substituted alkylamine such as triethanolamine; and an aromatic amine such as aniline, N-methylaniline, N,N-dimethylaniline, 2-methylaniline, 3-methylaniline, 4-methylaniline, N,N-dibutylaniline, 4-nitroaniline, diphenylamine, triphenylamine, naphthylamine, 2,4,6-tri-tert-butyl-N-methylaniline, N-phenyldiethanolamine, 2,6-diisopropylaniline, 2-(4-aminophenyl)-2-(3-hydroxyphenyl)propane, or 2-(4-aminophenyl)-2-(4-hydroxyphenyl)propane.

Examples of the (cyclo)alkyl amine compound having two nitrogen atoms include ethylenediamine, tetramethylethylenediamine, tetramethylenediamine, hexamethylenediamine, 4,4′-diaminodiphenylmethane, 4,4′-diaminodiphenylether, 4,4′-diaminobenzophenone, 4,4′-diaminodiphenylamine, 2,2-bis(4-aminophenyl)propane, 2-(3-aminophenyl)-2-(4-aminophenyl)propane, 1,4-bis[1-(4-aminophenyl)-1-methylethyl]benzene, 1,3-bis[1-(4-aminophenyl)-1-methylethyl]benzene, bis(2-dimethylaminoethyl)ether, bis(2-diethylaminoethyl)ether, 1-(2-hydroxyethyl)-2-imidazolidinone, 2-quinoxalinol, and N,N,N′,N′-tetrakis(2-hydroxypropyl)ethylenediamine.

Examples of the (cyclo)alkyl amine compound having three nitrogen atoms include a polymer such as polyethyleneimine, polyallylamine, or 2-dimethylaminoethyl acrylamide.

Examples of the nitrogen-containing heterocyclic compound include a nitrogen-containing aromatic heterocyclic compound and a nitrogen-containing aliphatic heterocyclic compound.

Examples of the nitrogen-containing aromatic heterocyclic compound include: an imidazole such as imidazole, 4-methylimidazole, 4-methyl-2-phenylimidazole, benzimidazole, 2-phenylbenzimidazole, 1-benzyl-2-methylimidazole, or 1-benzyl-2-methyl-1H-imidazole; and a pyridine such as pyridine, 2-methylpyridine, 4-methylpyridine, 2-ethylpyridine, 4-ethylpyridine, 2-phenylpyridine, 4-phenylpyridine, 2-methyl-4-phenylpyridine, nicotine, nicotinic acid, nicotinic acid amide, quinoline, 4-hyroxyquinoline, 8-oxyquinoline, acridine, or 2,2′:6′,2″-terpyridine.

Examples of the nitrogen-containing aliphatic heterocyclic compound include a piperazine such as piperazine or 1-(2-hydroxyethy)piperazine; and pyrazine, pyrazole, pyridazine, quinozarin, purine, pyrrolidine, proline, piperidine, piperidine ethanol, 3-piperidino-1,2-propanediol, morpholine, 4-methylmorpholine, 1-(4-morpholinyl)ethanol, 4-acetylmorpholine, 3-(N-morpholino)-1,2-propanediol, 1,4-dimethylpiperazine, and 1,4-diazabicyclo[2.2.2]octane.

Examples of the amido group-containing compound include: an N-t-butoxycarbonyl group-containing amino compound such as N-t-butoxycarbonyldi-n-octylamine, N-t-butoxycarbonyldi-n-nonylamine, N-t-butoxycarbonyldi-n-decylamine, N-t-butoxycarbonyldicylcohexylamine, N-t-butoxycarbonyl-1-adamantylamine, N-t-butoxycarbonyl-2-adamantylamine, N-t-butoxycarbonyl-N-methyl-1-adamantylamine, (S)-(−)-1-(t-butoxycarbonyl)-2-pyrrolidinemethanol, (R)-(+)-1-(t-butoxycarbonyl)-2-pyrrolidinemethanol, N-t-butoxycarbonyl-4-hydroxypiperidine, N-t-butoxycarbonylpyrrolidine, N-t-butoxycarbonylpiperazine, N,N-di-t-butoxycarbonyl-1-adamantylamine, N,N-di-t-butoxycarbonyl-N-methyl-1-adamantylamine, N-t-butoxycarbonyl-4,4′-diaminodiphenylmethane, N,N-di-t-butoxycarbonylhexamethylenediamine, N,N,N′,N′-tetra-t-butoxy carbonylhexamethylenediamine, N,N′-di-t-butoxycarbonyl-1,7-diaminoheptane, N,N′-di-t-butoxycarbonyl-1,8-diaminooctane, N,N′-di-t-butoxycarbonyl-1,9-diaminononane, N,N′-di-t-butoxycarbonyl-1,10-diaminodecane, N,N′-di-t-butoxy carbonyl-1,12-diaminododecane, N,N′-t-butoxycarbonyl-4,4′-diaminodiphenylmethane, N-t-butoxycarbonylbenzimidazole, N-t-butoxycarbonyl-2-methylbenzimidazole, or N-t-butoxycarbonyl-2-phenylbenzimidazole; and formamide, N-methyl formamide, N,N-dimethylformamide, acetamide, N-methylacetamide, N,N-dimethylacetamide, propionamide, benzamide, pyrrolidone, N-methyl pyrrolidone, N-acetyl-1-adamantylamine, and tris(2-hydroxyethyl) isocyanurate.

Examples of the urea compound include urea, methylurea, 1,1-dimethylurea, 1,3-dimethylurea, 1,1,3,3-tetramethylurea, and 1,3-diphenylurea.

Among the nitrogen-containing compounds, a nitrogen-containing compound having an SP value of 18 or lower is preferably used from the viewpoint of suppressing a development defect. The reason for this is that the nitrogen-containing compound having an SP value of 18 or lower has excellent affinity to a rinsing liquid used in a rinsing process described below and can suppress occurrence of a development defect such as precipitation.

The SP value of the nitrogen-containing compound used in the present invention is a value calculated using the Fedors method described in “Properties of Polymers” (second edition, 1976). The calculation expression used and parameters of respective substituents are as follows.

SP Value (Fedors Method)=[(Total Cohesive Energy of Respective Substituents)/(Total Volume of Respective Substituents)]0.5

TABLE 1

| | Cohesive | | | Cohesive | |
|---|---|---|---|---|---|
| | Energy | Volume | | Energy | Volume |
| Substituent | (J/mol) | (cm³/mol) | Substituent | (J/mol) | (cm³/mol) |
| CH₃ | 4710 | 33.5 | CN | 25530 | 24 |
| CH₂ | 4940 | 16.1 | OH | 29800 | 10 |
| CH | 3430 | −1 | CHO | 21350 | 22.3 |
| C | 1470 | −19.2 | COOH | 27630 | 28.5 |
| CH₂═ | 4310 | 28.5 | —O— | 3350 | 3.8 |
| ═CH— | 4310 | 13.5 | CO | 17370 | 10.8 |
| ═C< | 4310 | −5.5 | COO | 18000 | 18 |
| Ph | 31940 | 71.4 | 5- or more membered ring | 1050 | 16 |
| NH₂ | 12560 | 19.2 | | | |
| NH | 8370 | 4.5 | | | |
| N< | 4190 | −9 | | | |

Substituent Constant Table of Fedors Method (Properties of Polymers, Second Edition, pp. 138 to140)

A (cyclo)alkyl amine compound or a nitrogen-containing aliphatic heterocyclic compound satisfying the above-described conditions (SP value) is preferable, and 1-aminodecane, di-n-octylamine, tri-n-octylamine, and tetramethylethylenediamine, is more preferable. The following table shows SP values and the like of the nitrogen-containing aliphatic heterocyclic compounds.

TABLE 2

| | | | | | | SP |
|---|---|---|---|---|---|---|
| | CH₃ | CH₂ | NH₂ | NH | N | Value |
| 1-Aminodecane | 1 | 9 | 1 | | | 17.7 |
| Di-n-Octylamine | 2 | 14 | | 1 | | 17.1 |
| Tri-n-Octylamine | 3 | 21 | | | 1 | 16.9 |
| Tetramethylethylenediamine | 4 | 2 | | | 2 | 15.8 |

The content of the basic compound (preferably the nitrogen-containing compound) in the developer is not particularly limited. From the viewpoint of obtaining the effects of the present invention, the content of the basic compound is preferably 10 mass % or lower and more preferably 0.5 to 5 mass % with respect to the total mass of the developer. In the present invention, as the nitrogen-containing compound, one kind may be used alone, or two or more kinds having different chemical structures may be used in combination.

<Rinsing Liquid>

A rinsing liquid which is an example of the treatment liquid according to the present invention is used in a rinsing step described below. In addition, the rinsing liquid includes an organic solvent and thus can also be called an organic rinsing liquid. In order to “rinse” a resist film using the treatment liquid according to the present invention, the above-described rinsing liquid is used.

A vapor pressure of the rinsing liquid (in the case of a mixed solvent, the total vapor pressure) at 20° C. is preferably 0.05 kPa or higher and 5 kPa or lower, more preferably 0.1 kPa or higher and 5 kPa or lower, and most preferably 0.12 kPa or higher and 3 kPa or lower. By adjusting the vapor pressure of the rinsing liquid to be 0.05 kPa or higher and 5 kPa or lower, uniformity in the temperature in a wafer surface is improved. Swelling of the resist film caused by permeation of the rinsing liquid is suppressed, and uniformity in the dimension in a wafer surface is improved.

(Organic Solvent)

As the organic solvent included in the rinsing liquid according to the present invention, various organic solvents may be used, and at least one organic solvent selected from the group consisting of a hydrocarbon solvent, a ketone solvent, an ester solvent, an alcohol solvent, an amide solvent, and an ether solvent is preferably used.

Specific examples of the organic solvents are the same as those of the organic solvent described above regarding the developer.

In a case where an extreme ultraviolet (EUV) ray or an electron beam (EB) is used in an exposure step described below, as the organic solvent included in the rinsing liquid, a hydrocarbon solvent is preferably used, and an aliphatic hydrocarbon solvent is more preferably used. As the aliphatic hydrocarbon solvent used in the rinsing liquid, from the viewpoint of further improving the effects, an aliphatic hydrocarbon solvent having 5 or more carbon atoms (for example, pentane, hexane, octane, decane, undecane, dodecane, or hexadecane) is preferable, an aliphatic hydrocarbon solvent having 8 or more carbon atoms is more preferable, and an aliphatic hydrocarbon solvent having 10 or more carbon atoms is still more preferable.

The upper limit value of the number of carbon atoms in the aliphatic hydrocarbon solvent is not particularly limited and, for example, is 16 or less, preferably 14 or less, and more preferably 12 or less.

Among the aliphatic hydrocarbon solvents, decane, undecane, or dodecane is still more preferable, and undecane is most preferable.

In addition, as the hydrocarbon solvent included in the rinsing liquid, an unsaturated hydrocarbon solvent can be used, and examples thereof include octene, nonene, decene, undecene, dodecene, and hexadecene. The number of double bonds or triple bonds in the unsaturated hydrocarbon solvent is not particularly limited, and a hydrocarbon chain may be present at an arbitrary position. In addition, in a case where the unsaturated hydrocarbon solvent has a double bond, a cis-form and a trans-form may be present together.

By using the hydrocarbon solvent (in particular, the aliphatic hydrocarbon solvent) as the organic solvent included in the rinsing liquid, a small amount of the developer permeating into the developed resist film is rinsed. Therefore, swelling is further suppressed, and an effect of suppressing pattern collapse is further exhibited.

In addition, as the organic solvent included in the rinsing liquid, a mixed solvent of the ester solvent and the hydrocarbon solvent or a mixed solvent of the ketone solvent and the hydrocarbon solvent may be used. It is preferable that the mixed solvent includes a hydrocarbon solvent as a major component.

In a case where the ester solvent and the hydrocarbon solvent are used in combination, it is preferable that butyl acetate or isoamyl acetate is used as the ester solvent. In addition, it is preferable that a saturated hydrocarbon solvent (for example, decane, dodecane, undecane, or hexadecane) is used as the hydrocarbon solvent from the viewpoint of further exhibiting the effects.

In a case where the ketone solvent and the hydrocarbon solvent are used in combination, it is preferable that 2-heptanone is used as the ketone solvent. In addition, it is preferable that a saturated hydrocarbon solvent (for example, decane, dodecane, undecane, or hexadecane) is used as the hydrocarbon solvent from the viewpoint of further exhibiting the effects.

In addition, in a case where the ester solvent and the hydrocarbon solvent are used in combination, or in a case where the ketone solvent and the hydrocarbon solvent are used in combination, an unsaturated hydrocarbon solvent can be used as the hydrocarbon solvent, and examples thereof include octene, nonene, decene, undecene, dodecene, and hexadecene. The number of double bonds or triple bonds in the unsaturated hydrocarbon solvent is not particularly limited, and a hydrocarbon chain may be present at an arbitrary position.

In addition, in a case where the unsaturated hydrocarbon solvent has a double bond, a cis-form and a trans-form may be present together.

Further, as the organic solvent included in the rinsing liquid, at least one selected from the group consisting of the ester solvent and the ketone solvent may be used from the viewpoint that the ester solvent and the ketone solvent are particularly effective for reducing a residue after development.

In a case where the rinsing liquid includes at least one selected from the group consisting of the ester solvent and the ketone solvent, it is preferable that the rinsing liquid includes at least one solvent selected from the group consisting of butyl acetate, isopentyl acetate (isoamyl acetate), n-pentyl acetate, ethyl 3-ethoxypropionate (EEP), and 2-heptanone as a major component, and it is more preferable that the rinsing liquid includes at least one solvent selected from the group consisting of butyl acetate and 2-heptanone as a major component.

In addition, in a case where the rinsing liquid includes at least one selected from the group consisting of the ester solvent and the ketone solvent, it is preferable that the rinsing liquid includes a solvent selected from the group consisting of an ester solvent, a glycol ether solvent, a ketone solvent, and an alcohol solvent as a subcomponent, and it is more preferable that the rinsing liquid includes a solvent selected from the group consisting of propylene glycol monomethyl ether acetate (PGMEA), propylene glycol monomethyl ether (PGME), ethyl acetate, ethyl lactate, 3-methyl methoxypropionate, cyclohexanone, methyl ethyl ketone, γ-butyrolactone, propanol, 3-methoxy-1-butanol, N-methylpyrrolidone, and propylene carbonate a subcomponent.

In particular, in a case where an ester solvent is used as the organic solvent, it is preferable that two or more ester solvents are used from the viewpoint of further exhibiting the effects. Specific examples of the above-described case include a case where an ester solvent (preferably butyl acetate) is used as major component and another ester solvent having a different chemical structure (preferably propylene glycol monomethyl ether acetate (PGMEA)) is used as a subcomponent.

In a case where an ester solvent is used as the organic solvent, not only an ester solvent (one kind or two or more kinds) but also a glycol ether solvent may be used from the viewpoint of further exhibiting the effects. Specific examples of the above-described case include a case where an ester solvent (preferably butyl acetate) is used as major component and a glycol ether solvent (preferably propylene glycol monomethyl ether (PGME)) is used as a subcomponent.

In a case where a ketone solvent is used as the organic solvent, not only a (one kind or two or more kinds) but also an ester solvent and/or a glycol ether solvent may be used from the viewpoint of further exhibiting the effects. Specific examples of the above-described case include a case where a ketone solvent (preferably 2-heptanone) is used as major component and an ester solvent (preferably, propylene glycol monomethyl ether acetate (PGMEA)) and/or a glycol ether solvent (preferably propylene glycol monomethyl ether (PGME)) is used as a subcomponent.

Here, “major component” described above represents that the content of the major component is 50 to 100 mass %, preferably 70 to 100 mass %, more preferably 80 to 100 mass %, still more preferably 90 to 100 mass %, and even still more preferably 95 to 100 mass % with respect to the total mass of the organic solvent.

In addition, “subcomponent” described above represents that the content of the subcomponent is preferably 0.1 to 20 mass %, more preferably 0.5 to 10 mass %, and still more preferably 1 to 5 mass % with respect to the total mass (100 mass %) of the major component.

A mixture of a plurality of kinds among the organic solvents may be used, or a mixture of one of the organic solvent and a solvent other than the organic solvents and water may be used. The solvent may be mixed with water. In this case, the moisture content in the rinsing liquid is typically 60 mass % or lower, preferably 30 mass % or lower, more preferably 10 mass % or lower, and most preferably 5 mass % or lower. By adjusting the moisture content to be 60 mass % or lower, excellent rinsing properties can be obtained.

It is preferable that the rinsing liquid includes a surfactant. As a result, wettability on a resist film is improved, and a rinsing effect tends to be further improved.

As the surfactant, the same surfactant as that used in an actinic ray-sensitive or radiation-sensitive composition described below can be used.

The content of the surfactant is typically 0.001 to 5 mass %, preferably 0.005 to 2 mass %, and more preferably 0.01 to 0.5 mass % with respect to the total mass of the rinsing liquid.

It is preferable that the rinsing liquid includes an antioxidant. As a result, formation of an oxidant over time can be suppressed, and the content of an oxidant can be further reduced. Specific examples and the content of the antioxidant are as described above regarding the developer.

The developer and the rinsing liquid are also suitably applicable to a non-chemically amplified resist.

Examples of the non-chemically amplified resist are as follows.

(1) A resist material in which a main chain is cut, the molecular weight decreases, and the solubility changes when irradiated with a g-line, a h-line, an i-line, KrF, ArF, EB, EUV, or the like (for example, a resist material including a copolymer of an α-chloroacrylate compound and an α-methylstyrene compound as a major component, which is described in paragraphs “0025” to “0029” and “0056” of JP2013-210411A and “0032” to “0036” and “0063” US2015/0008211A)

(2) A resist material such as a hydrogen silsesquioxane resist (HSQ) or a chlorine-substituted calixarene in which a silanol condensation reaction occurs when irradiated with ag-line, a h-line, an i-line, KrF, ArF, EB, EUV, or the like

(3) a resist that includes a metal complex (a complex of magnesium, chromium, manganese, iron, cobalt, nickel, copper, zinc, silver, cadmium, indium, tin, antimony, cesium, zirconium, hafnium or the like; titanium, zirconium, or hafnium is preferable from the viewpoint of pattern formability) having an absorption to a g-line, a h-line, an h-line, KrF, ArF, EB, EUV, or the like and in which ligand disengagement or ligand exchange occurs when used in combination with a photoacid generator (for example, a resist material described in “0017” to “0033” and “0037” to “0047” of JP2015-075500A, in paragraphs “0017” to “0032” and “0043” to “0044” of JP2012-185485A, and paragraphs “0042” to “0051” and “0066” of US2012/0208125A)

The developer and the rinsing liquid are also suitably applicable to a silicon amplified resist.

Examples of the silicon resist include a resist material described in paragraphs “0010” to “0062” and paragraphs “0129” to “0165” of JP2008-83384A.

[Pattern Forming Method]

A pattern forming method according to the present invention includes: a resist film forming step of forming a resist film using an actinic ray-sensitive or radiation-sensitive composition (hereinafter, also referred to as “resist composition”); an exposure step of exposing the resist film; and a treatment step of treating the exposed resist film with the above-described treatment liquid (the treatment liquid in which the content of the sulfur-containing compound is 10 mmol/L or lower).

In the pattern forming method according to the present invention, the treatment liquid is used. Therefore, occurrence of a defect on a resist pattern can be suppressed.

Hereinafter, each of the steps of the pattern forming method according to the present invention will be described. In addition, as an example of the treatment step, a development step and a rinsing step will be described.

<Resist Film Forming Step>

The resist film forming step is forming a resist film using an actinic ray-sensitive or radiation-sensitive composition and, for example, can be performed using the following method.

In order to form the resist film (actinic ray-sensitive or radiation-sensitive composition film) on the substrate using the actinic ray-sensitive or radiation-sensitive composition, respective components described below are dissolved in a solvent to prepare an actinic ray-sensitive or radiation-sensitive composition, the actinic ray-sensitive or radiation-sensitive composition is optionally filtered through a filter and applied to the substrate. As the filter, a filter formed of polytetrafluoroethylene, polyethylene, or nylon and having a pore size of preferably 0.1 microns or less, more preferably 0.05 microns or less, and still more preferably 0.03 microns or less is preferable.

The actinic ray-sensitive or radiation-sensitive composition is applied to the substrate (for example, a silicon dioxide coating), which is used for manufacturing an integrated circuit element, using an appropriate coating method such as a method using a spinner. Next, the actinic ray-sensitive or radiation-sensitive composition is dried to form a resist film. Optionally, various undercoating layers (an inorganic layer, an organic layer, or an antireflection film) may be formed below the resist film.

As the drying method, a method of drying heating the composition is generally used. Heating may be performed using means provided in a typical exposure or developing device, and may be performed using a hot plate or the like.

The heating temperature is preferably 80° C. to 150° C., more preferably 80° C. to 140° C., and still more preferably 80° C. to 130° C. The heating time is preferably 30 to 1000 seconds, more preferably 60 to 800 seconds, and still more preferably 60 to 600 seconds.

The thickness of the resist film is generally 200 nm or less and preferably 100 nm or less.

For example, in order to resolve a 1:1 line-and-space pattern having a size of 30 nm or less, the thickness of a resist film to be formed is preferably 50 nm or less. In a case where a resist film having a thickness of 50 nm or less is applied to a development step described below, pattern collapse is not likely to occur, and higher resolution performance can be obtained.

The thickness is more preferably in a range of 15 nm to 45 nm. In a case where the thickness is 15 nm or more, sufficient etching resistance can be obtained. The thickness is still more preferably is in a range of 15 nm to 40 nm. In a case where the thickness is in the above-described range, etching resistance and higher resolution performance can be simultaneously satisfied.

In the pattern forming method according to the present invention, a top coat may be formed over the resist film. It is preferable that the top coat is not mixed with the resist film and is uniformly formed above the resist film.

The top coat is not particularly limited, and well-known top coat of the related art can be formed using a well-known method of the related art. For example, the top coat can be formed based on the description of paragraphs “0072” to “0082” of JP2014-059543A.

In a case where the developer including the organic solvent is used in the development step, it is preferable that, for example, a top coat including a basic compound described in JP2013-61648A is formed on the resist film. Specific examples of the basic compound which may be included in the top coat include a basic compound (E) described below.

In addition, it is preferable that the top coat includes a compound which includes at least one group or one bond selected from the group consisting of an ether bond, a thioether bond, a hydroxyl group, a thiol group, a carbonyl bond, and an ester bond.

<Exposure Step>

The exposure step is exposing the resist film and, for example, can be performed using the following method.

The resist film formed as described above is irradiated with an actinic ray or radiation through a predetermined mask. For irradiation of an electron beam, drawing (direct drawing) not using a mask is generally used.

The actinic ray or radiation is not particularly limited, and examples thereof include KrF excimer laser light, ArF excimer laser light, extreme ultraviolet (EUV) light, and an electron beam (EB). The exposure may be immersion exposure.

<Baking>

In the pattern forming method according to the present invention, it is preferable that baking (heating) is performed before development after exposure. Due to the baking, a reaction of an exposed portion is promoted, and sensitivity and a pattern shape are further improved.

The heating temperature is preferably 80° C. to 150° C., more preferably 80° C. to 140° C., and still more preferably 80° C. to 130° C.

The heating time is preferably 30 to 1000 seconds, more preferably 60 to 800 seconds, and still more preferably 60 to 600 seconds.

Heating may be performed using means provided in a typical exposure or developing device, and may be performed using a hot plate or the like.

<Development Step>

The development step is developing the exposed resist film with the developer.

Examples of the developing method include: a method (dipping method) of dipping the substrate in a container filled with the developer for a given period of time; a method (puddle method) of causing the developer to accumulate on a surface of the substrate with a surface tension and maintaining this state for a given period of time; a method (spraying method) of spraying the developer to a surface of the substrate; and a method (dynamic dispense method) of continuously jetting the developer to the substrate, which is rotating at a given speed, while scanning a developer jetting nozzle on the substrate at a given speed.

In addition, a step of stopping development while replacing the solvent with another solvent may be performed after the development step

The developing time is not particularly limited as long as it is a period of time where a non-exposed portion of a resin is sufficiently dissolved. The development time is typically 10 to 300 seconds and preferably 20 to 120 seconds.

The temperature of the developer is preferably 0° C. to 50° C. and more preferably 15° C. to 35° C.

As the developer used in the development step, the above-described treatment liquid is preferably used. The developer is as described above. In addition to the development using the treatment liquid, development using an alkali developer may be further performed (so-called double development).

<Rinsing Step>

The rinsing step is performing rinsing with the rinsing liquid after the development step.

In the rinsing step, a developed wafer is rinsed with the above-described rinsing liquid.

A rinsing method is not particularly limited, and examples thereof include: a method (rotation jetting method) of continuously jetting the rinsing liquid to the substrate which is rotating at a given speed; a method (dipping method) of dipping the substrate in a container filled with the rinsing liquid for a given period of time; and a method (spraying method) of spraying the rinsing liquid to a surface of the substrate. In particular, it is preferable that the rinsing step is performed using the rotation jetting method such that the rinsed substrate is rotated at a rotation speed of 2000 rpm to 4000 rpm to remove the rinsing liquid from the substrate.

The rinsing time is not particularly limited, and is typically 10 seconds to 300 seconds, preferably 10 seconds to 180 seconds, and most preferably 20 seconds to 120 seconds.

The temperature of the rinsing liquid is preferably 0° C. to 50° C. and more preferably 15° C. to 35° C.

In addition, after the development or the rising, a treatment of removing the developer or the rinsing liquid, which is attached to the pattern, with supercritical fluid may be performed.

Further, after the development, the rinsing, or the treatment using the supercritical fluid, heating may be performed to remove the solvent remaining in the pattern. The heating temperature is not particularly limited as long as an excellent resist pattern can be obtained, and is typically 40° C. to 160° C. The heating temperature is preferably 50° C. to 150° C. and most preferably 50° C. to 110° C. The heating time is not particularly limited as long as an excellent resist pattern can be obtained, and is typically 15 to 300 seconds and preferably 15 to 180 seconds.

As the rinsing liquid, the above-described treatment liquid is preferably used. The description of the rinsing liquid is as described above.

In the pattern forming method according to the present invention, it is preferable that at least either or both of the developer and the rinsing liquid are the above-described treatment liquid.

In general, the developer and the rinsing liquid is stored in a waste liquid tank through a pipe after use. At this time, in a case where the hydrocarbon solvent is used as the rinsing liquid, the resist dissolved in the developer precipitates, is attached to side and back surfaces of a wafer or a side surface of the pipe, and contaminates a device.

In order to solve the problem, a method of introducing a solvent for dissolving the resist into the pipe may be used. Examples of the method of introducing the solvent into the pipe include: a method of rinsing a side surface or a back surface of the substrate, which is rinsed with the rinsing liquid, with the solvent for dissolving the resist; and a method of introducing the solvent for dissolving the resist into the pipe without contact with the resist.

The solvent which is introduced into the pipe is not particularly limited as long as it can dissolve the resist, and examples thereof include the above-described organic solvents, for example, propylene glycol monomethyl ether acetate (PGMEA), propylene glycol monoethyl ether acetate, propylene glycol monopropyl ether acetate, propylene glycol monobutyl ether acetate, propylene glycol monomethyl ether propionate, propylene glycol monoethyl ether propionate, ethylene glycol monomethyl ether acetate, ethylene glycol monoethyl ether acetate, propylene glycol monomethyl ether (PGME), propylene glycol monoethyl ether, propylene glycol monopropyl ether, propylene glycol monobutyl ether, ethylene glycol monomethyl ether, ethylene glycol monoethyl ether, 2-heptanone, ethyl lactate, and 1-propanol, acetone. Among these, PGMEA, PGME, cyclohexanone can be preferably used.

[Actinic Ray-Sensitive or Radiation-Sensitive Composition (Resist Composition)]

Next, the actinic ray-sensitive or radiation-sensitive composition which is preferably used in combination with the treatment liquid according to the present invention will be described in detail.

(A) Resin

<Resin (A)>

It is preferable that a resin (A) is included as the actinic ray-sensitive or radiation-sensitive composition which is preferably used in combination with the treatment liquid according to the present invention. The resin (A) includes at least (i) a repeating unit having a group which is decomposed by the action of an acid to produce a carboxyl group (may further include a repeating unit having a phenolic hydroxyl group), or includes may at least (ii) a repeating unit having a phenolic hydroxyl group.

In a case where the resin (A) includes the repeating unit which is decomposed by the action of an acid to produce a carboxyl group, the solubility in an alkali developer increases and the solubility in the organic solvent increases due to the action of an acid.

Examples of the repeating unit having a phenolic hydroxyl group included in the resin (A) include a repeating unit represented by the following Formula (I).

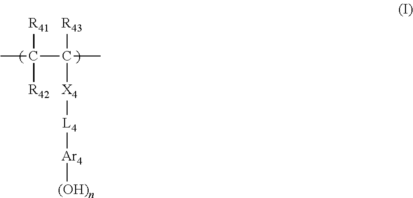

In the formula, R₄₁, R₄₂, and R₄₃ each independently represent a hydrogen atom, an alkyl group, a halogen atom, a cyano group, or an alkoxycarbonyl group. R₄₂ may be bonded to Ar₄ to form a ring. In this case, R₄₂ represents a single bond or an alkylene group.

X₄ represents a single bond, —COO—, or —CONR₆₄—, and R₆₄ represents a hydrogen atom or an alkyl group.

L₄ represents a single bond or an alkylene group.

Ar₄ represents a (n+1)-valent aromatic ring group, and in a case where Ar₄ is bonded to R₄₂ to form a ring, Ar₄ represents a (n+2)-valent aromatic ring group.

n represents an integer of 1 to 5.

As the alkyl group represented by R₄₁, R₄₂, and R₄₃ in Formula (I), an alkyl group having 20 or less carbon atoms which may have a substituent such as a methyl group, an ethyl group, a propyl group, an isopropyl group, a n-butyl group, a sec-butyl group, a hexyl group, a 2-ethylhexyl group, an octyl group, or a dodecyl group is preferable, an alkyl group having 8 or less carbon atoms is more preferable, and an alkyl group having 3 or less carbon atoms is still more preferable.

In Formula (I), the cycloalkyl group represented by R₄₁, R₄₂, and R₄₃ may be monocyclic or polycyclic. In particular, a monocycloalkyl group having 3 to 8 carbon atoms which may have a substituent such as a cyclopropyl group, a cyclopentyl group, or a cyclohexyl group is preferable.

Examples of the halogen atom represented by R₄₁, R₄₂, and R₄₃ in Formula (I) include a fluorine atom, a chlorine atom, a bromine atom, and an iodine atom. In particular, a fluorine atom is preferable.

As the alkyl group included in the alkoxycarbonyl group represented by R₄₁, R₄₂, and R₄₃ in Formula (I), the same alkyl groups as described above regarding R₄₁, R₄₂, and R₄₃ are preferable.

Preferable examples of a substituent of each of the groups include an alkyl group, a cycloalkyl group, an aryl group, an amino group, an amido group, an ureido group, a urethane group, a hydroxyl group, a carboxyl group, a halogen atom, an alkoxy group, a thioether group, an acyl group, an acyloxy group, an alkoxycarbonyl group, a cyano group, and a nitro group. The number of carbon atoms in the substituent is preferably 8 or less.

Ar₄ represents an (n+1)-valent aromatic ring group. In a case where n represents 1, a divalent aromatic ring group may have a substituent, and preferable examples thereof include an arylene group having 6 to 18 carbon atoms such as a phenylene group, a tolylene group, a naphthylene group, or an anthracenylene group; and an aromatic ring group having a heterocycle such as thiophene, furan, pyrrole, benzothiophene, benzofuran, benzopyrrole, triazine, imidazole, benzoimidazole, triazole, thiadiazole, or thiazole.

In a case where n represents an integer of 2 or more, preferable specific examples of the (n+1)-valent aromatic ring group include groups obtained by removing arbitrary (n−1) hydrogen atoms from the specific examples of the above-described divalent aromatic ring groups.

The (n+1)-valent aromatic ring group may further have a substituent.

Examples of a substituent which may be included in the alkyl group, the cycloalkyl group, the alkoxycarbonyl group, the alkylene group, and the (n+1)-valent aromatic ring group include: the alkoxy groups represented by R₄₁, R₄₂, and R₄₃ in Formula (I), such as an alkyl group, a methoxy group, an ethoxy group, a hydroxyethoxy group, a propoxy group, a hydroxypropoxy group, or a butoxy group; and an aryl group such as a phenyl group.

As an alkyl group represented by R₆₄ in —CONR₆₄—(R₆₄ represents a hydrogen atom or an alkyl group) represented by X₄, an alkyl group having 20 or less carbon atoms which may have a substituent such as a methyl group, an ethyl group, a propyl group, an isopropyl group, a n-butyl group, a sec-butyl group, a hexyl group, a 2-ethylhexyl group, an octyl group, or a dodecyl group is preferable, and an alkyl group having 8 or less carbon atoms is more preferable.

As X₄, a single bond, —COO—, or —CONH— is preferable, and a single bond or —COO— is more preferable.

Preferable examples of the alkylene group represented by L₄ include an alkylene group having 1 to 8 carbon atoms which may have a substituent such as a methylene group, an ethylene group, a propylene group, a butylene group, a hexylene group, or an octylene group.

As Ar₄, an aromatic ring group having 6 to 18 carbon atoms which may have a substituent is more preferable, and a benzene ring group, a naphthalene ring group, or a biphenylene ring group is still more preferable.

It is preferable that the repeating unit represented by Formula (I) includes a hydroxystyrene structure. That is, it is preferable that Ar₄ represents a benzene ring group.

Preferable examples of the repeating unit having a phenolic hydroxyl group included in the resin (A) include a repeating unit represented by the following Formula (p1).

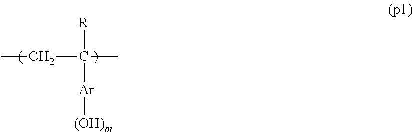

In Formula (p1), R represents a hydrogen atom or a linear or branched alkyl group having a halogen atom or 1 to 4 carbon atoms. A plurality of R¹'s may be the same as or different from each other. As R in Formula (p1), a hydrogen atom is preferable.

Ar in Formula (p1) represents an aromatic ring, and examples thereof include: an aromatic hydrocarbon ring having 6 to 18 carbon atoms which may have a substituent such as a benzene ring, a naphthalene ring, an anthracene ring, a fluorene ring, or a phenanthrene ring; and an aromatic heterocycle having a heterocycle such as a thiophene ring, a furan ring, a pyrrole ring, a benzothiophene ring, a benzofuran ring, a benzopyrrole ring, a triazine ring, an imidazole ring, a benzoimidazole ring, a triazole ring, a thiadiazole ring, or a thiazole ring. Among these, a benzene ring is most preferable.

In Formula (p1), m represents an integer of 1 to 5 and preferably 1.

Hereinafter, specific examples of the repeating unit having a phenolic hydroxyl group included in the resin (A) will be shown, but the present invention is not limited thereto. In the formulae, a represents 1 or 2.

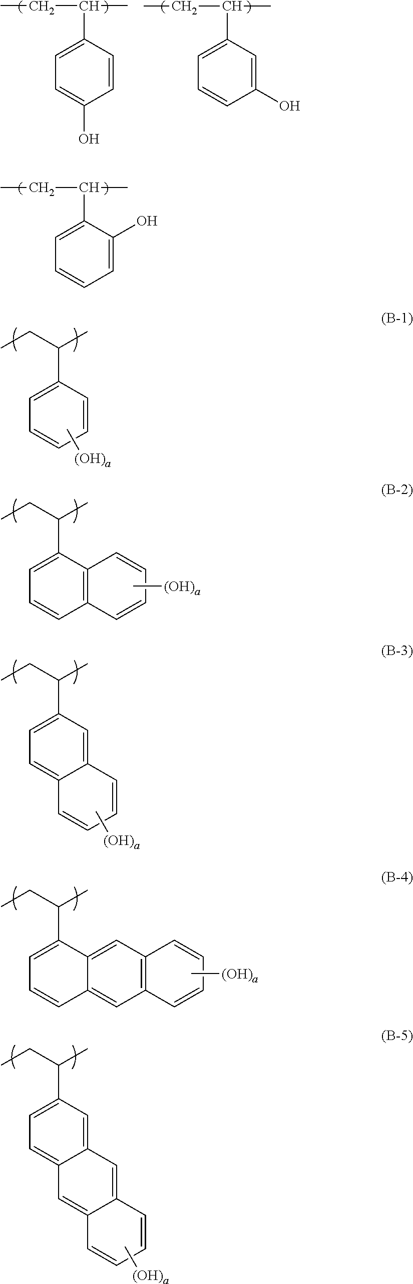

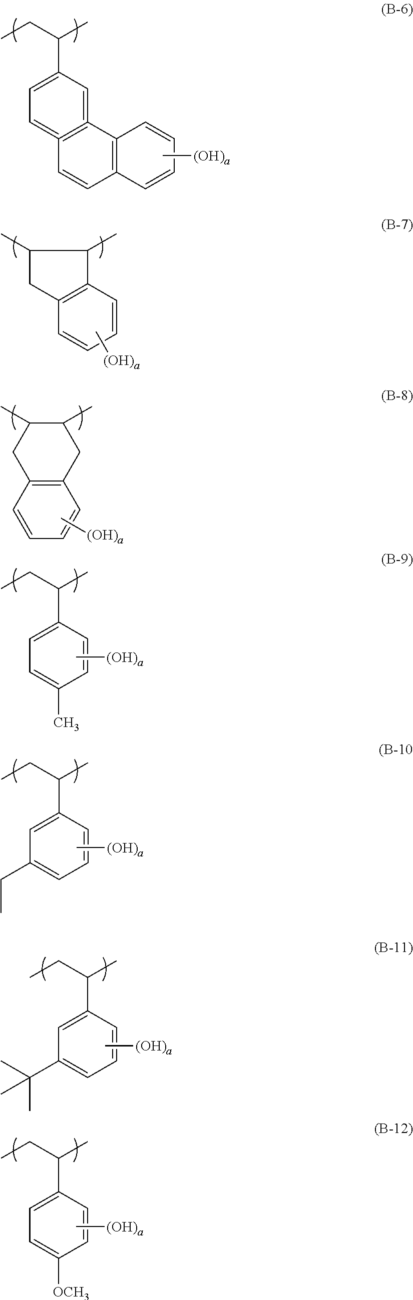

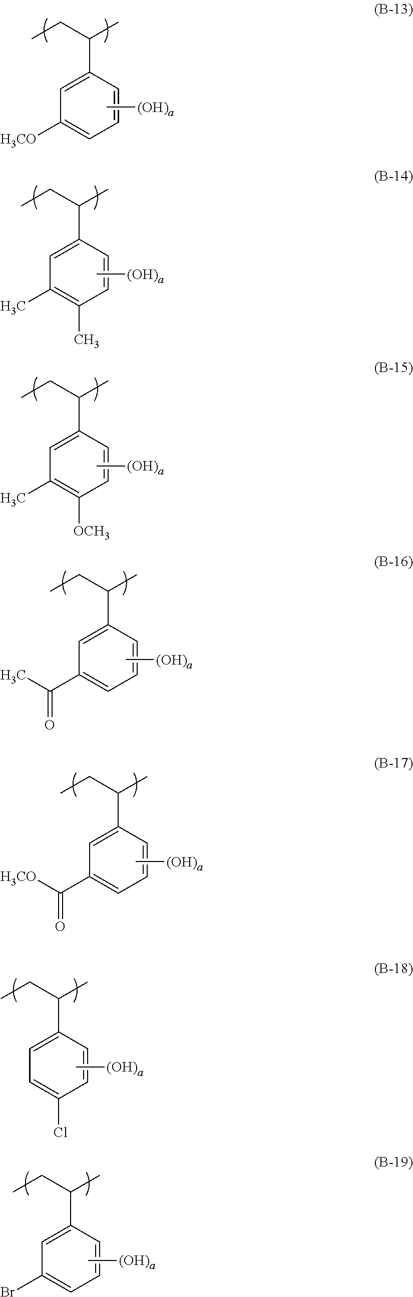

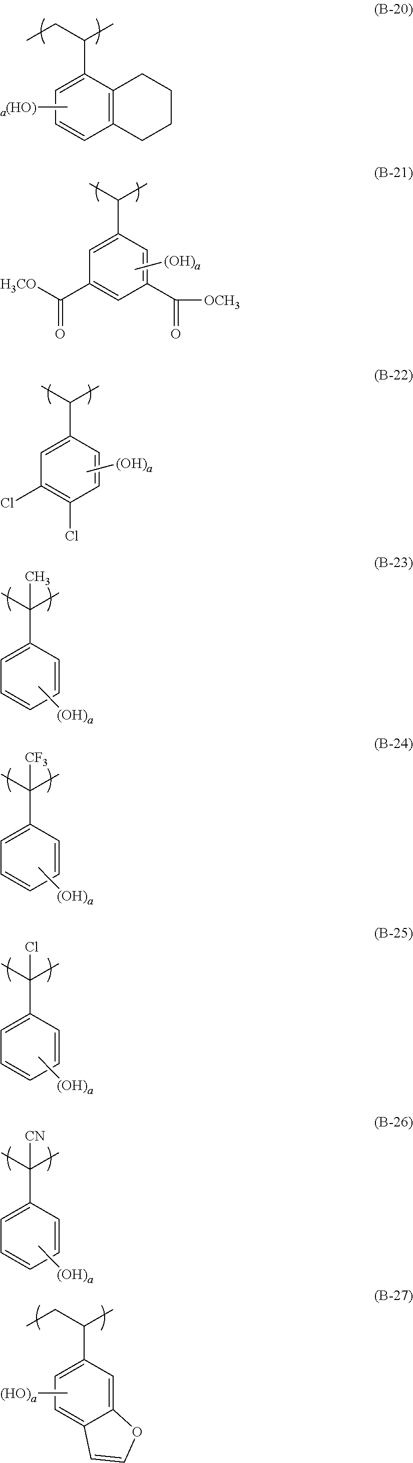

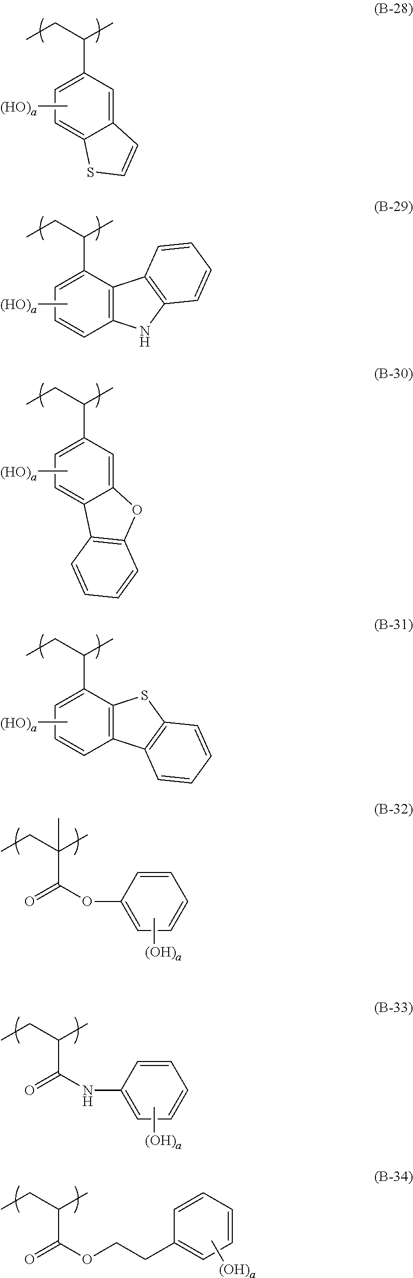

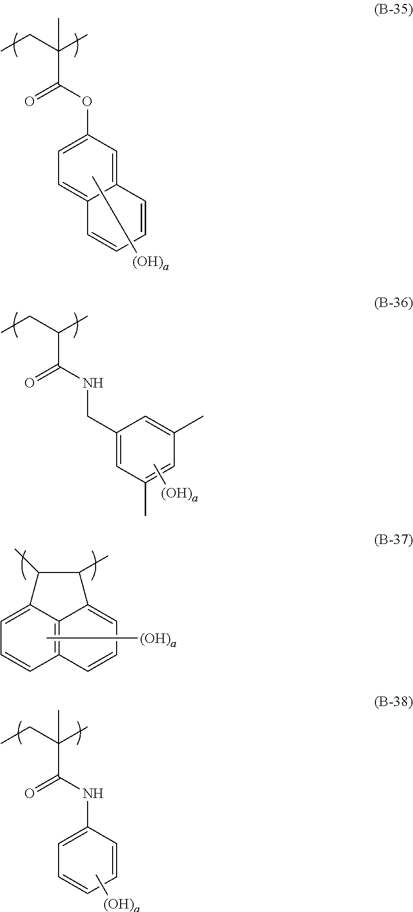

50 mol %, more preferably 0 to 45 mol %, and still more preferably 0 to 40 mol % with respect to all the repeating units of the resin (A).

The repeating unit having a group which is decomposed by the action of an acid to produce a carboxyl group included in the resin (A) is a repeating unit having a group which is substituted with a group obtained by a hydrogen atom being removed from a carboxyl group due to decomposition caused by the action of an acid.

Examples of the group which is removed by an acid include —C(R₃₆)(R₃₇)(R₃₈), —C(R₃₆)(R₃₇)(OR₃₉), and —C(R₀₁)(R₀₂)(OR₃₉).

In the formulae, R₃₆ to R₃₉ each independently represent an alkyl group, a cycloalkyl group, an aryl group, an aralkyl group, or an alkenyl group. R₃₆ and R₃₇ may be bonded to each other to form a ring.

R₀₁ to R₀₂ each independently represent a hydrogen atom, an alkyl group, a cycloalkyl group, an aryl group, an aralkyl group, or an alkenyl group.

As the repeating unit having a group which is decomposed by the action of an acid to produce a carboxyl group included in the resin (A), a repeating unit represented by the following Formula (AI) is preferable.

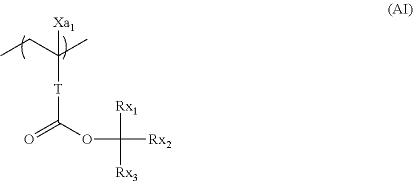

In Formula (AI), Xa₁ represents a hydrogen atom or an alkyl group which may have a substituent.

T represents a single bond or a divalent linking group.

Rx₁ to Rx₃ each independently represent an alkyl group (linear or branched) or a cycloalkyl group (monocyclic or polycyclic). In a case where all of Rx₁ to Rx₃ represent an alkyl group (linear or branched), it is preferable that at least two of Rx₁ to Rx₃ represent a methyl group.

Two of Rx₁ to Rx₃ may be bonded to each other to form a cycloalkyl group (monocyclic or polycyclic).

Examples of the alkyl group which may have a substituent represented by Xa₁ include a methyl group or a group represented by —CH₂—R₁₁. R₁₁ represents a halogen atom (for example, a fluorine atom), a hydroxyl group, or a monovalent organic group, and examples thereof include an alkyl group having 5 or less carbon atoms and an acyl group having 5 or less carbon atoms. In particular, an alkyl group having 3 or less carbon atoms is preferable, and a methyl group is more preferable. In one aspect, Xa₁ represent preferably a hydrogen atom, a methyl group, a trifluoromethyl group, or a hydroxymethyl group.

Examples of the divalent linking group represented by T include an alkylene group, a —COO—Rₜ— group, and a —O—Rₜ— group. In the formula, Rₜ represents an alkylene group or a cycloalkylene group.

T represents a single bond or a —COO—Rₜ— group. Rₜ represents preferably an alkylene group having 1 to 5 carbon atoms and more preferably a —CH₂— group, a —(CH₂)₂— group, or a —(CH₂)₃— group.

As the alkyl group represented by Rx₁ to Rx₃, an alkyl group having 1 to 4 carbon atoms such as a methyl group, an ethyl group, a n-propyl group, an isopropyl group, a n-butyl group, an isobutyl group, or a t-butyl group is preferable.

As the cycloalkyl group represented by Rx₁ to Rx₃, a monocycloalkyl group such as a cyclopentyl group or a cyclohexyl group, or a polycycloalkyl group such as a norbomyl group, a tetracyclodecanyl group, a tetracyclododecanyl group, or an adamantyl group is preferable.

As the cycloalkyl group which is formed by two of Rx₁ to Rx₃ being bonded to each other, a monocycloalkyl group such as a cyclopentyl group or a cyclohexyl group, or a polycycloalkyl group such as a norbomyl group, a tetracyclodecanyl group, a tetracyclododecanyl group, or an adamantyl group is preferable. In particular, a monocycloalkyl group having 5 or 6 carbon atoms is preferable.

In the cycloalkyl group which is formed by two of Rx₁ to Rx₃ being bonded to each other, for example, one methylene group constituting the ring may be substituted with a heteroatom such as an oxygen atom or a group having a heteroatom such as a carbonyl group.

In the repeating unit represented by Formula (AI), for example, it is preferable that Rx₁ represents a methyl group or an ethyl group and that Rx₂ and Rx₃ are bonded to each other to form the cycloalkyl group.

Each of the groups may have a substituent, and examples of the substituent include an alkyl group (having 1 to 4 carbon atoms), a halogen atom, a hydroxyl group, an alkoxy group (having 1 to 4 carbon atoms), a carboxyl group, and an alkoxycarbonyl group (having 2 to 6 carbon atoms), in which the number of carbon atoms is preferably 8 or less.

As the repeating unit represented by Formula (AI), an acid-decomposable tertiary alkyl (meth)acrylate repeating unit (a repeating unit in which Xa₁ represents a hydrogen atom or a methyl group, and T represents a single bond) is preferable. A repeating unit in which Rx₁ to Rx₃ each independently represent a linear or branched alkyl group is more preferable, and a repeating unit in which Rₓ to Rx₃ each independently represent a linear alkyl group is still more preferable.

Hereinafter, specific examples of the repeating unit having a group which is decomposed by the action of an acid to produce a carboxyl group included in the resin (A) will be shown, but the present invention is not limited thereto.

In the specific examples, Rx and Xa₁ represent a hydrogen atom, CH₃, CF₃, or CH₂OH. Rxa and Rxb each independently represent an alkyl group having 1 to 4 carbon atoms. Z represents a substituent having a polar group. In a case where a plurality of Z's are present, Z's each independently represent a substituent having a polar group. p represents 0 or a positive integer. Examples of the substituent having a polar group represented by Z include a linear or branched alkyl group having a hydroxyl group, a cyano group, an amino group, an alkylamido group, or a sulfonamide group, or a cycloalkyl group. In particular, an alkyl group having a hydroxyl group is preferable. As the branched alkyl group, an isopropyl group is preferable.

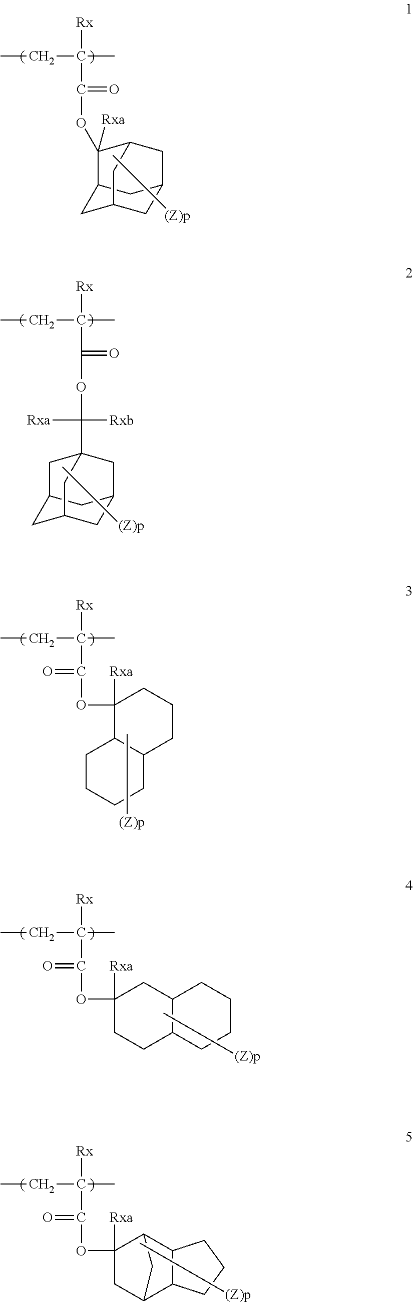

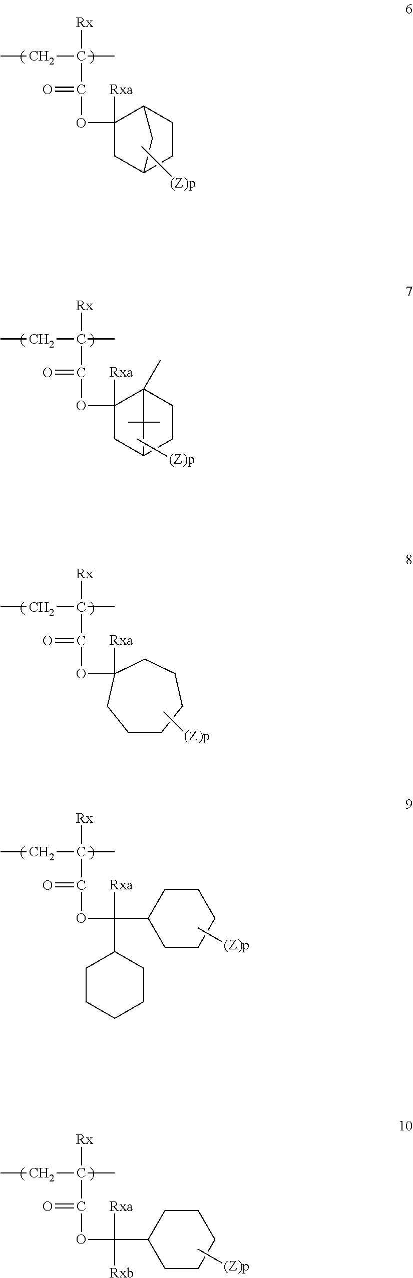

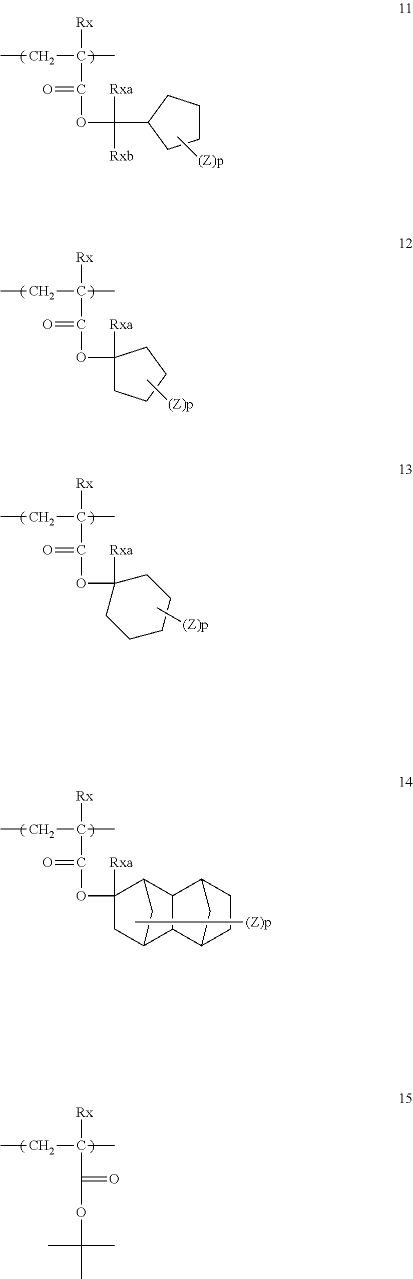

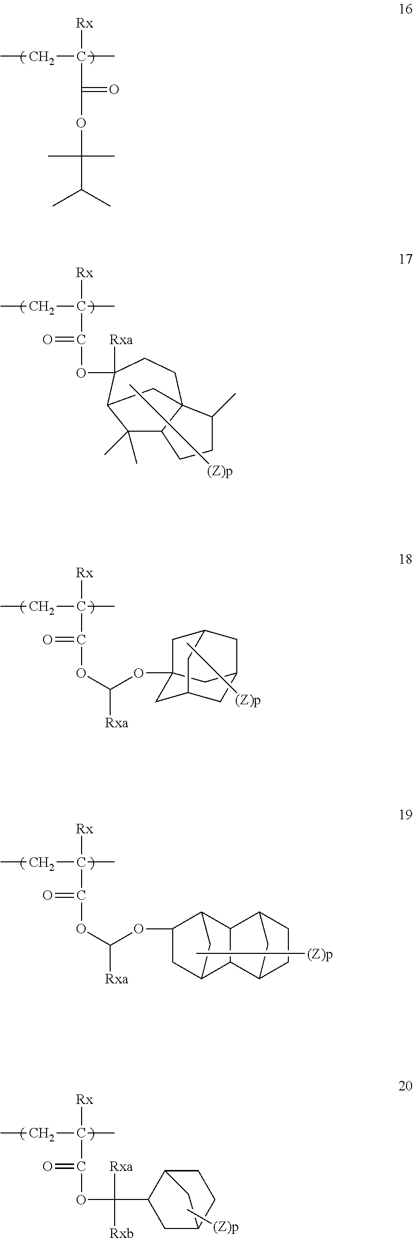

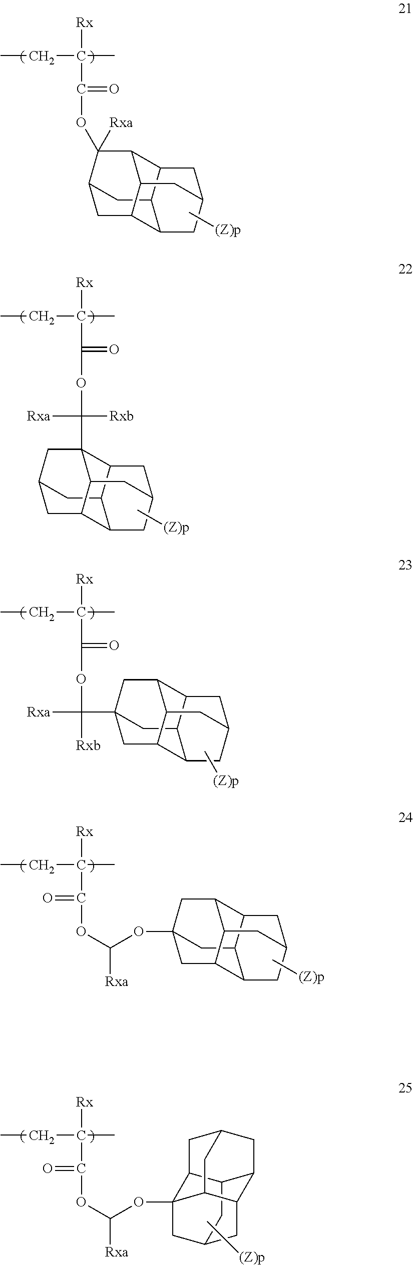

The content of the repeating unit having a group which is decomposed by the action of an acid to produce a carboxyl group is preferably 20 to 90 mol %, more preferably 25 to 80 mol %, and still more preferably 30 to 70 mol % with respect to all the repeating units of the resin (A).

It is preferable that the resin (A) further includes a repeating unit having a lactone group.

As the lactone group, any group having a lactone structure can be used. In particular, a group having a 5- to 7-membered lactone structure is preferable. In this case, it is preferable that another ring structure may be fused to group having a 5- to 7-membered lactone structure to form a bicyclo structure or a spiro structure.

It is preferable that the resin (A) further includes a repeating unit which has a group having with a lactone structure represented by any one of the following Formulae (LC1-1) to (LC1-16). In addition, the group having a lactone structure may be directly bonded to a main chain. As the lactone structure, a group represented by Formula (LC1-1), (LC1-4), (LC1-5), (LC1-6), (LC1-13), or (LC1-14) is preferable.

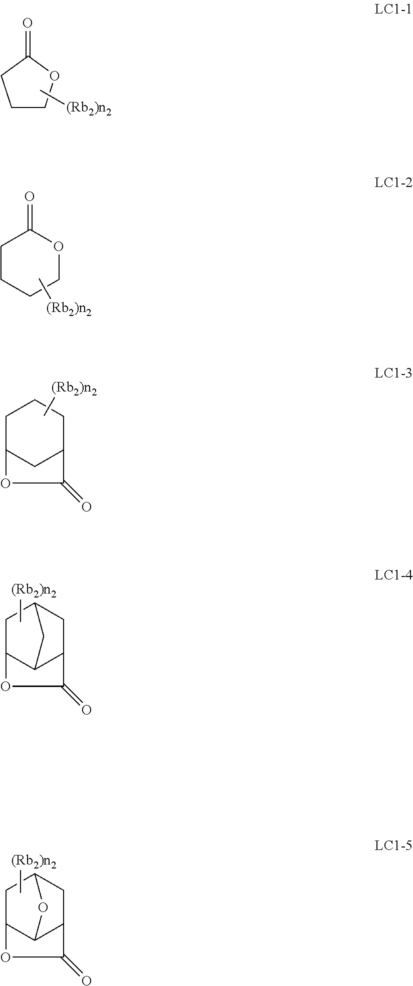

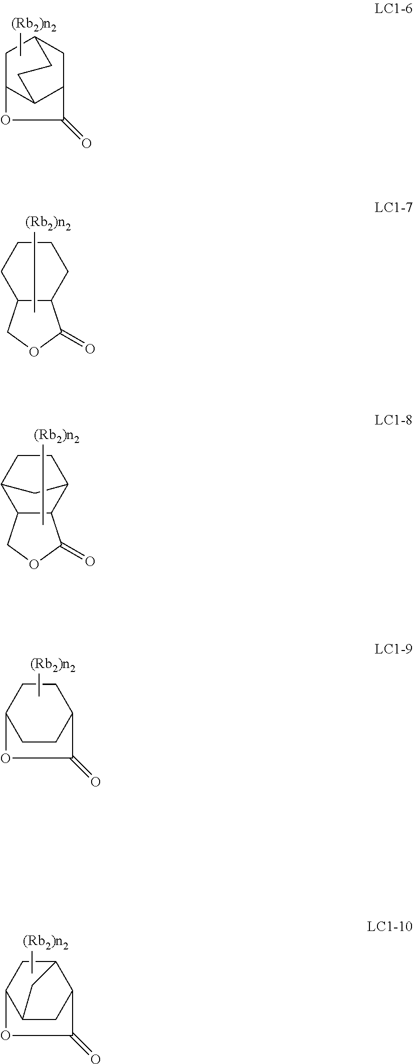

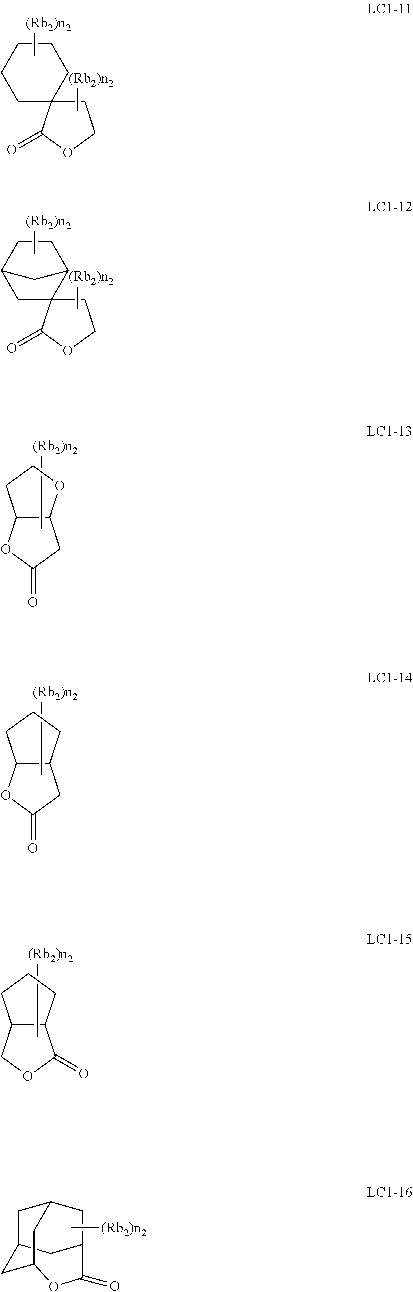

The lactone structure portion may or may not have a substituent (Rb₂). Preferable examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 1 to 8 carbon atoms, a carboxyl group, a halogen atom, a hydroxyl group, a cyano group, and an acid-decomposable group. n₂ represents an integer of 0 to 4. In a case where n₂ represents 2 or more, a plurality of Rb₂'s may be the same as or different from each other or may be bonded to each other to form a ring.

Examples of the repeating unit which has a group having a lactone structure represented by any one of Formulae (LC1-1) to (LC1-16) include a repeating unit represented by the following Formula (AI).

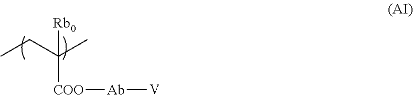

In Formula (AI), Rb₀ represents a hydrogen atom, a halogen atom, or an alkyl group having 1 to 4 carbon atoms.

Preferable examples of a substituent which may be included in the alkyl group represented by Rb₀ include a hydroxyl group and a halogen atom.

Examples of the halogen atom represented by Rb₀ include a fluorine atom, a chlorine atom, a bromine atom, and an iodine atom. Rb₀ represents preferably a hydrogen atom or a methyl group.

Ab represents a single bond, an alkylene group, a divalent linking group having a monocyclic or polycyclic alicyclic hydrocarbon structure, an ether group, an ester group, a carbonyl group, a carboxyl group, or a divalent group including a combination thereof. In particular, a single bond or a linking group represented by -Ab₁-CO₂— is preferable. Ab₁ represents a linear or branched alkylene group or a monocyclic or polycyclic cycloalkylene group and preferably a methylene group, an ethylene group, a cyclohexylene group, an adamantylene group, or a norbomylene group.

V represents a group represented by any one of Formulae (LC1-1) to (LC1-16).

In the repeating unit which has a group having a lactone structure, an optical isomer is present, and any optical isomer may be used. In addition, one optical isomer may be used alone, or a mixture of a plurality of optical isomers may be used. In a case where one optical isomer is mainly used, the optical purity (ee) thereof is preferably 90 or higher and more preferably 95 or higher.

Hereinafter, specific examples of the repeating unit which has a group having a lactone structure will be shown, but the present invention is not limited thereto.

(In the formula, Rx represents H, CH₃, CH₂OH, or CF₃)

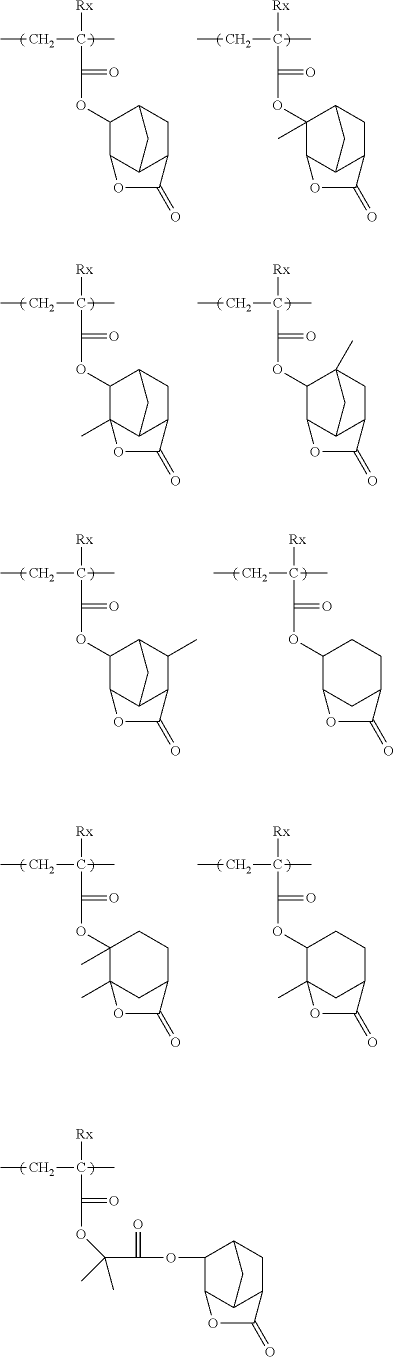

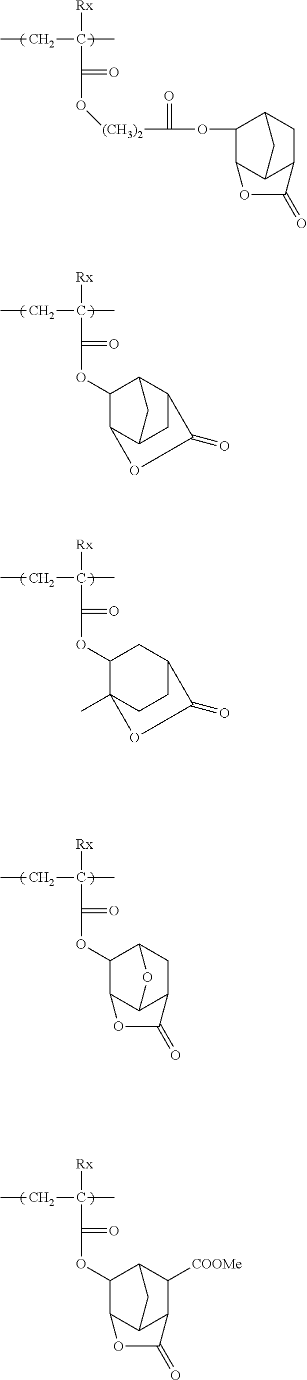

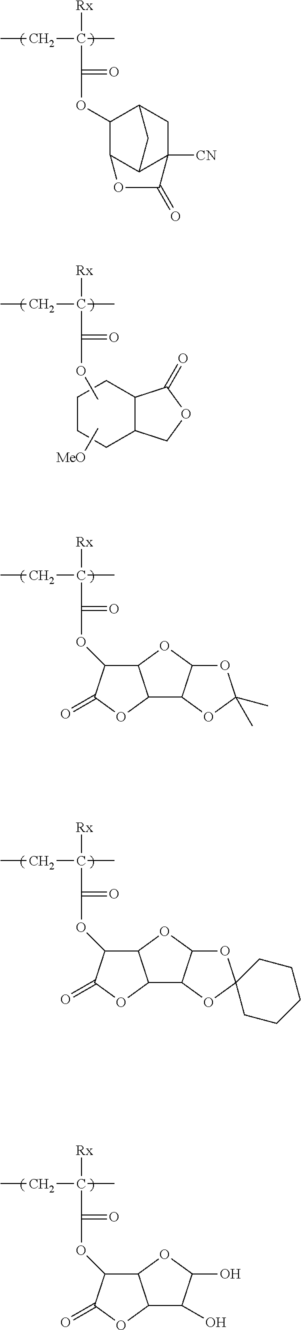

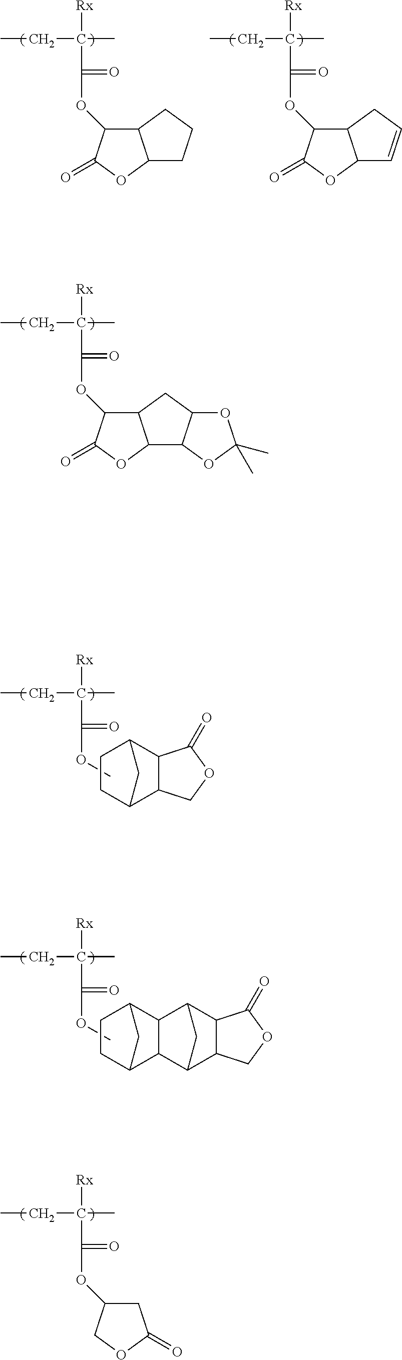

The content of the repeating unit having a lactone group is preferably 1 to 30 mol %, more preferably 5 to 25 mol %, and still more preferably 5 to 20 mol % with respect to all the repeating units of the resin (A).

The resin (A) may further include a repeating unit which has an organic group having a polar group, in particular, a repeating unit which has an alicyclic hydrocarbon structure substituted with a polar group.

As a result, substrate adhesiveness and/or developer affinity are improved. As the alicyclic hydrocarbon structure of the alicyclic hydrocarbon structure substituted with a polar group, an adamantyl group, a diamantyl group, or a norbornane group is preferable. As the polar group, a hydroxyl group or a cyano group is preferable.

Hereinafter, specific examples of the repeating unit having a polar group will be shown, but the present invention is not limited thereto.

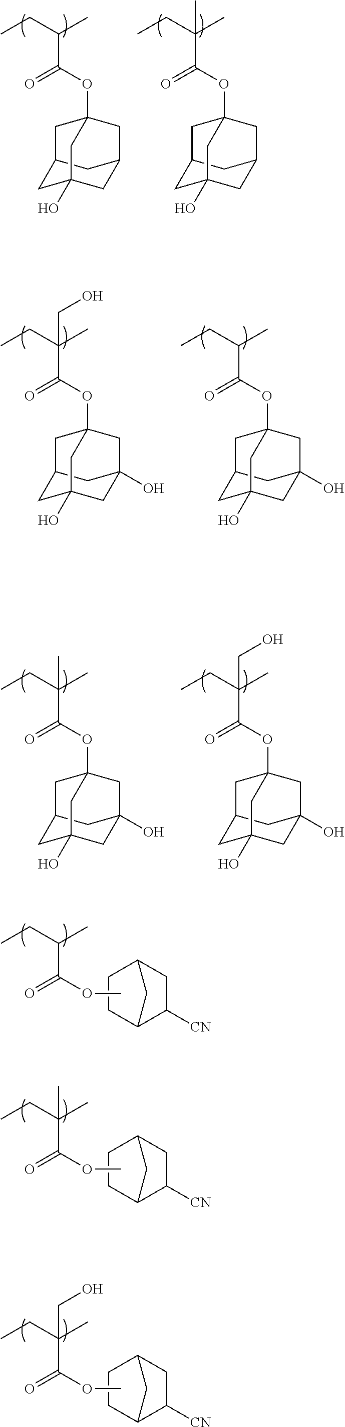

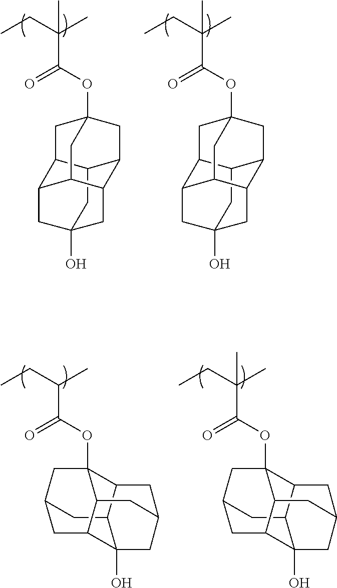

In a case where the resin (A) includes the repeating unit which has an organic group having a polar group, the content thereof is preferably 1 to 30 mol %, more preferably 5 to 25 mol %, and still more preferably 5 to 20 mol % with respect to all the repeating units of the resin (A).

Further, as a repeating unit other than the above-described repeating units, the resin (A) may include a repeating unit having a group (photoacid generating group) which generates an acid when irradiated with an actinic ray or radiation. In this case, it can be considered that the repeating unit having a photoacid generating group corresponds to a compound (B) described below that generates an acid when irradiated with an actinic ray or radiation.

Examples of the repeating unit include a repeating unit represented by the following Formula (4).

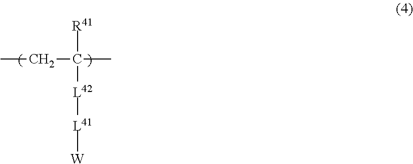

R⁴¹ represents a hydrogen atom or a methyl group. L⁴¹ represents a single bond or a divalent linking group. L⁴² represents a divalent linking group. W represents a structural unit which is decomposed to generate an acid at a side chain when irradiated with an actinic ray or radiation.

Hereinafter, specific examples of the repeating unit represented by Formula (4) will be shown, but the present invention is not limited thereto.

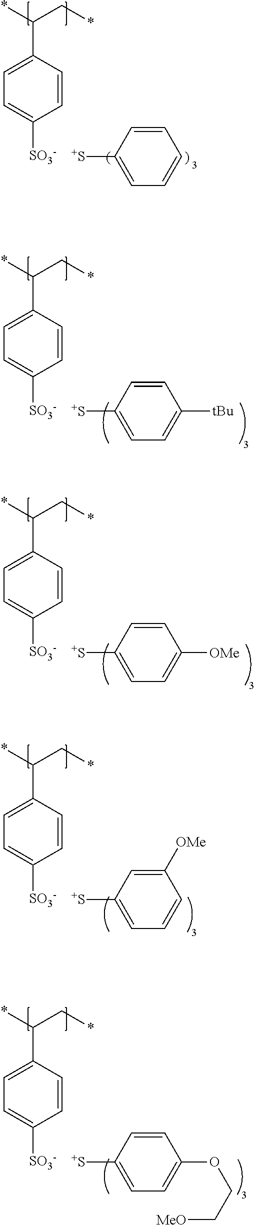

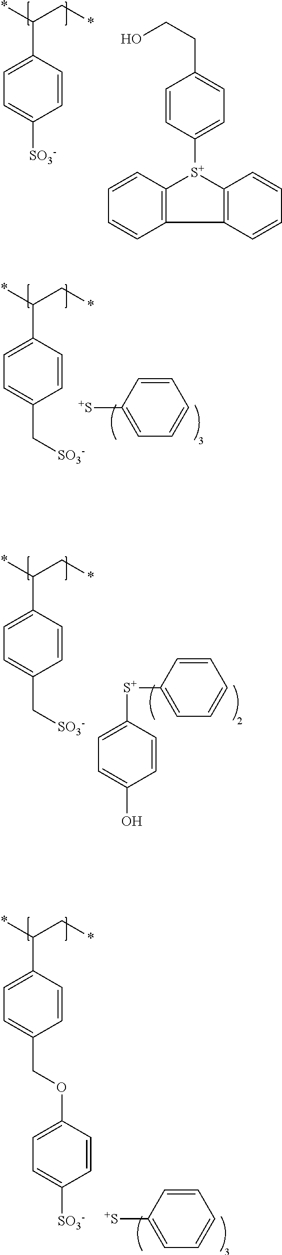

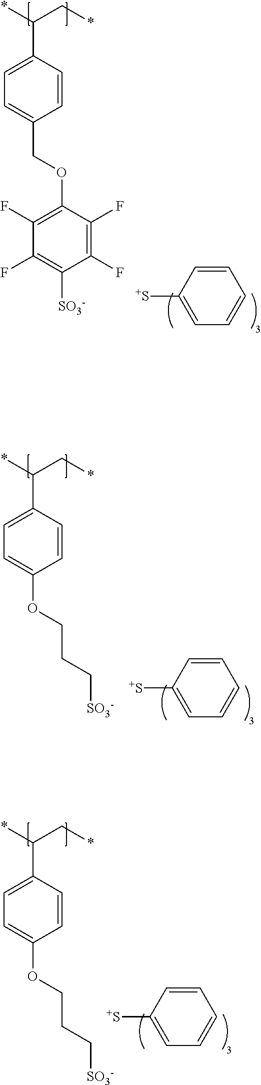

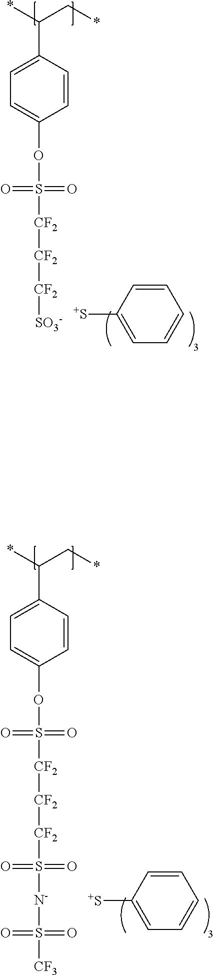

Other examples of the repeating unit represented by Formula (4) include repeating units described in paragraphs “0094” to “0105” of JP2014-041327A.

In a case where the resin (A) includes the repeating unit having a photoacid generating group, the content of the repeating unit having a photoacid generating group is preferably 1 to 40 mol %, more preferably 5 to 35 mol %, and still more preferably 5 to 30 mol % with respect to all the repeating units of the resin (A).

The resin (A) can be synthesized using an ordinary method (for example, radical polymerization). Examples of the general synthesis method include: a batch polymerization method of dissolving a monomer species and an initiator in a solvent and heating the solution for polymerization; and a dropping polymerization method of dropping a solution of a monomer species and an initiator dropwise to a heated solvent for 1 to 10 hours. Among these, a dropping polymerization method is preferable.

Examples of the reaction solvent include: an ether such as tetrahydrofuran, 1,4-dioxane, or diisopropyl ether; a ketone such as methyl ethyl ketone or methyl isobutyl ketone; an ester solvent such as ethyl acetate; an amide solvent such as dimethyl formamide or dimethylacetamide; and a solvent for dissolving an actinic ray-sensitive or radiation-sensitive composition described below such as propylene glycol monomethyl ether acetate, propylene glycol monomethyl ether, or cyclohexanone. It is preferable that the same solvent as that used in the actinic ray-sensitive or radiation-sensitive composition is used for polymerization. As a result, particle generation during storage can be suppressed.

It is preferable that the polymerization reaction is performed in an inert gas atmosphere such as nitrogen or argon. In order to initiate the polymerization, a commercially available radical initiator (for example, an azo initiator or peroxide) is used as the polymerization initiator. As the radical initiator, an azo initiator is preferable, and examples thereof include an azo initiator having an ester group, a cyano group, or a carboxyl group. Preferable examples of the initiator include azobisisobutyronitrile, azobisdimethylvaleronitrile, and dimethyl 2,2′-azobis(2-methylpropionate). If desired, the initiator is added additionally or dividedly. After completion of the reaction, the reaction product is put into a solvent, and a desired polymer is collected using a powder or solid collecting method or the like. The reaction concentration is 5 to 50 mass % and preferably 10 to 30 mass %.

The reaction temperature is typically 10° C. to 150° C., preferably 30° C. to 120° C., and still more preferably 60° C. to 100° C.

Examples of a method which can be used for purification include a typical method such as: a liquid-liquid extraction method in which a residual monomer or an oligomer component is removed using a combination of water washing and an appropriate solvent; a purification method in a solid state such as ultrafiltration in which substances having a specific molecular weight or lower are removed by filtration; a redispersion method in which a residual monomer is removed by dropping a resin solution over a poor solvent to solidify the resin in the poor solvent; and a purification method in a solid state in which a resin slurry separated by filtration is washed with a poor solvent.

The weight-average molecular weight of the resin (A) is preferably 1000 to 200000, more preferably 3000 to 20000, and most preferably 5000 to 15000 in terms of polystyrene by GPC. By adjusting the weight-average molecular weight to be 1000 to 200000, deterioration in heat resistance and dry etching resistance can be prevented. In addition, deterioration in developability and deterioration in film forming properties caused by an increase in viscosity can be prevented.

It is still more preferable that the weight-average molecular weight of the resin (A) is 3000 to 9500 in terms of polystyrene by GPC. By adjusting the weight-average molecular weight to be 3000 to 9500, in particular, a resist residue (hereinafter also referred to as “scum”) is suppressed, and a more satisfactory pattern can be formed. The dispersity (molecular weight distribution) is typically 1 to 5, preferably 1 to 3, more preferably 1.2 to 3.0, and still more preferably 1.2 to 2.0. As the dispersity decreases, the resolution and a resist shape are improved. In addition, a side wall of a resist pattern is smooth, and roughness properties are excellent.

In the actinic ray-sensitive or radiation-sensitive composition, the content of the resin (A) is preferably 50 to 99.9 mass % and more preferably 60 to 99.0 mass % with respect to the total solid content of the actinic ray-sensitive or radiation-sensitive composition.

In addition, in the actinic ray-sensitive or radiation-sensitive composition, one resin (A) may be used alone, or a plurality of resins (A) may be used in combination.

In addition, the resin (A) may include a repeating unit represented by the following Formula (VI) as a repeating unit (a).

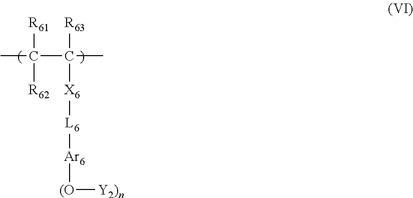

In Formula (VI), R₆₁, R₆₂, and R₆₃ each independently represent a hydrogen atom, an alkyl group, a cycloalkyl group, a halogen atom, a cyano group, or an alkoxycarbonyl group. R₆₂ may be bonded to Ar₆ to form a ring. In this case, R₆₂ represents a single bond or an alkylene group.

X₆ represents a single bond, —COO—, or —CONR₆₄—. R₆₄ represents a hydrogen atom or an alkyl group.

L₆ represents a single bond or an alkylene group.

Ar₆ represents a (n+1)-valent aromatic ring group, and in a case where Ar₆ is bonded to R₆₂ to form a ring, Ar₆ represents a (n+2)-valent aromatic ring group.

In a case where n represents 2 or more, Y₂'s each independently represent a hydrogen atom or a group which is removed by the action of an acid. At least one of Y₂'s represents a group which is removed by the action of an acid.

n represents an integer of 1 to 4.

As the group which is removed by the action of an acid represented by Y₂, a structure represented by Formula (VI-A) is more preferable.

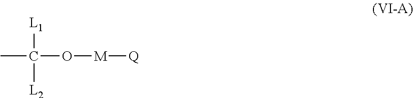

Here, L₁ and L₂ each independently represent a hydrogen atom, an alkyl group, a cycloalkyl group, an aryl group, or a group including a combination of an alkylene group and an aryl group.

M represents a single bond or a divalent linking group.

Q represents an alkyl group, a cycloalkyl group which may have a heteroatom, an aryl group which may have a heteroatom, an amino group, an ammonium group, a mercapto group, a cyano group, or an aldehyde group.

At least two of Q, M, or L₁ may be bonded to each other to form a ring (preferably a 5- or 6-membered ring).

It is preferable that the repeating unit represented by the formula (VI) is a repeating unit represented by the following Formula (3).

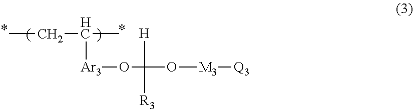

In Formula (3), Ar₃ represents an aromatic ring group.

R₃ represents a hydrogen atom, an alkyl group, a cycloalkyl group, an aryl group, an aralkyl group, an alkoxy group, an acyl group, or a heterocyclic group.

M₃ represents a single bond or a divalent linking group.

Q₃ represents an alkyl group, a cycloalkyl group, an aryl group, or a heterocyclic group.

At least two of Q₃, M₃, and R₃ are bonded to each other to form a ring.

The aromatic ring group represented by Ar₃ is the same as Ar₆ in Formula (VI) in a case where n in Formula (VI) represents 1. In this case, a phenylene group or a naphthylene group is more preferable, and a phenylene group is still more preferable.

Hereinafter, specific examples of the repeating unit represented by Formula (VI) will be shown as specific examples of the repeating unit (a), but the present invention is not limited thereto.

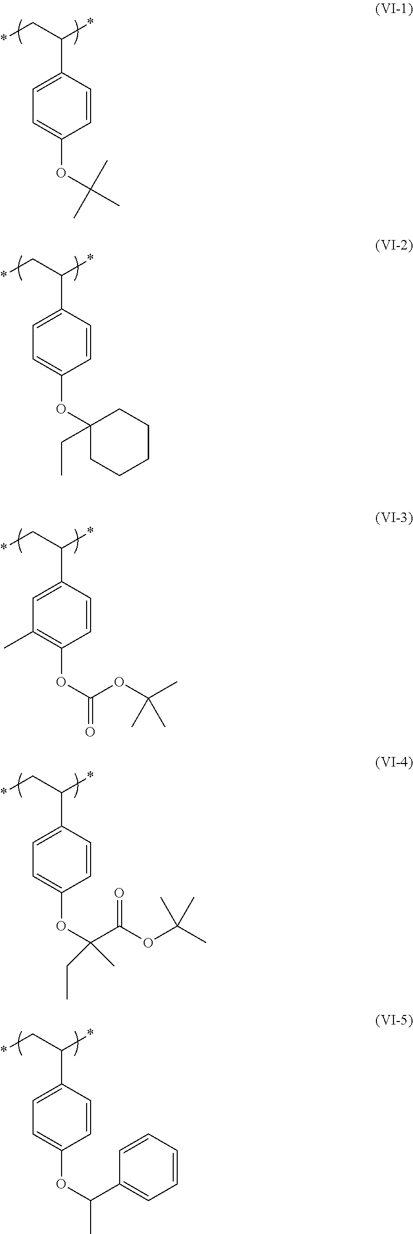

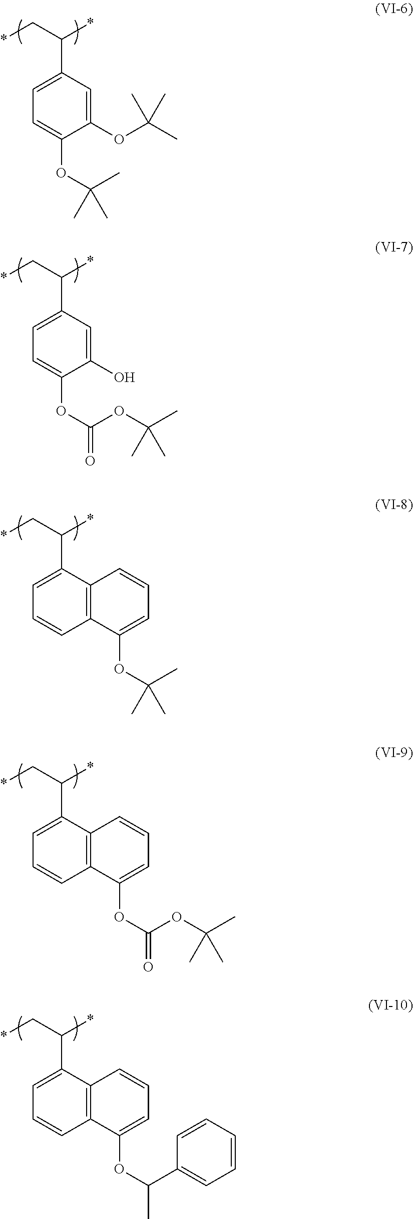

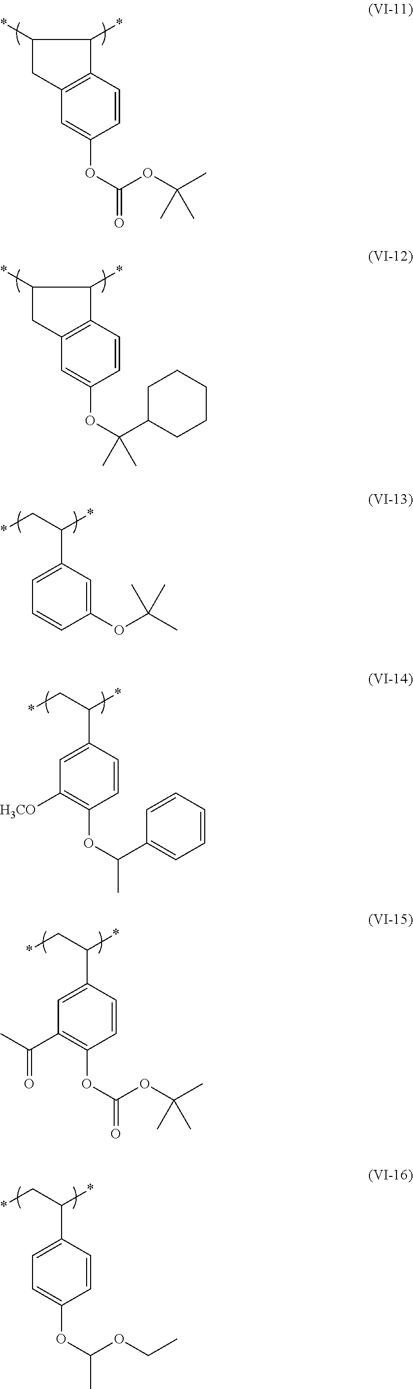

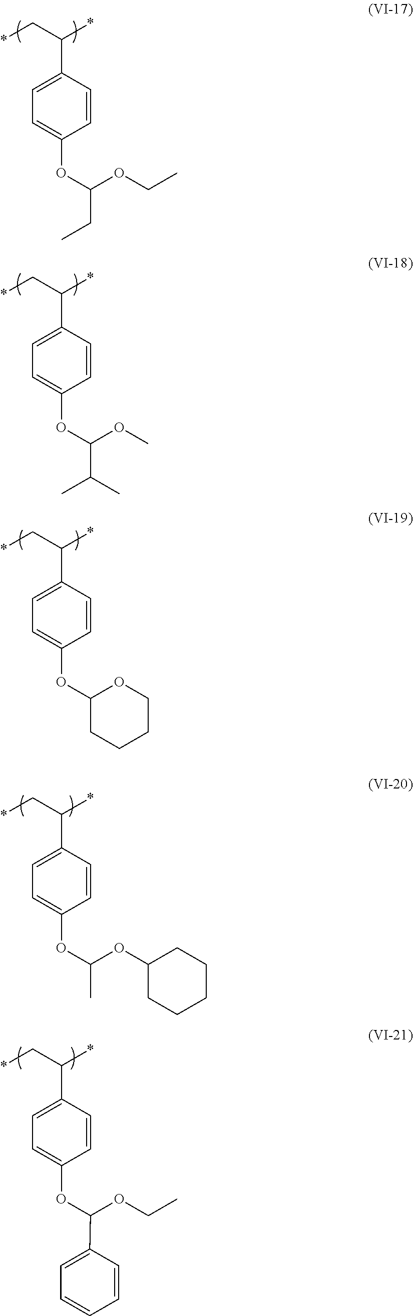

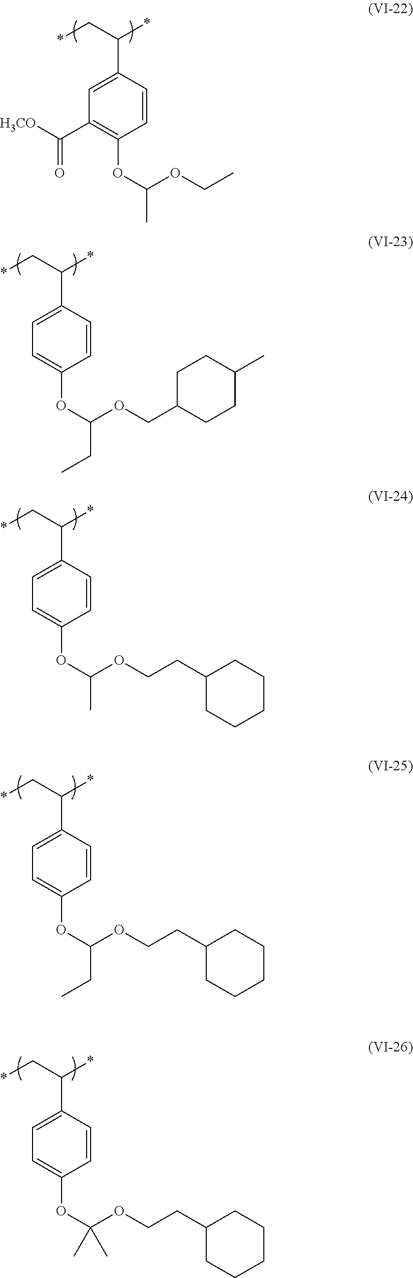

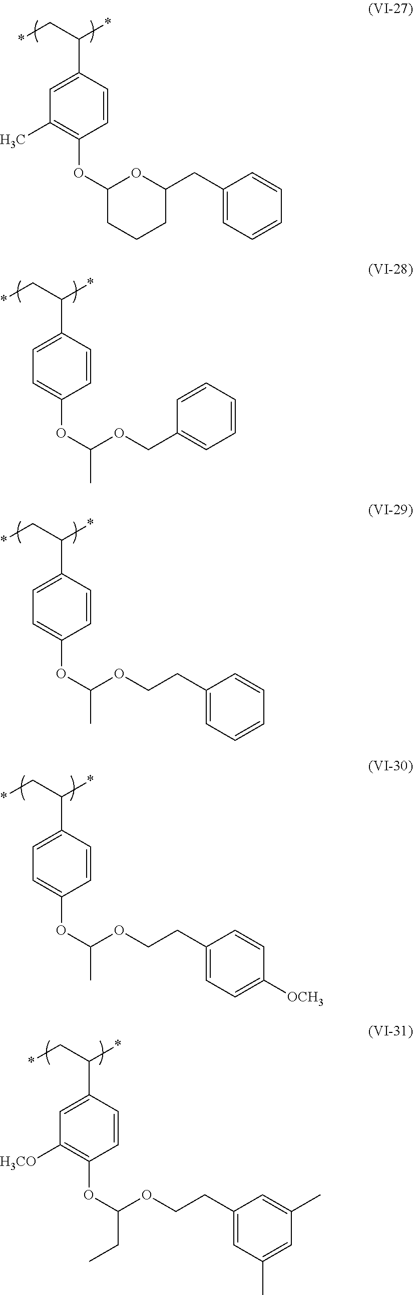

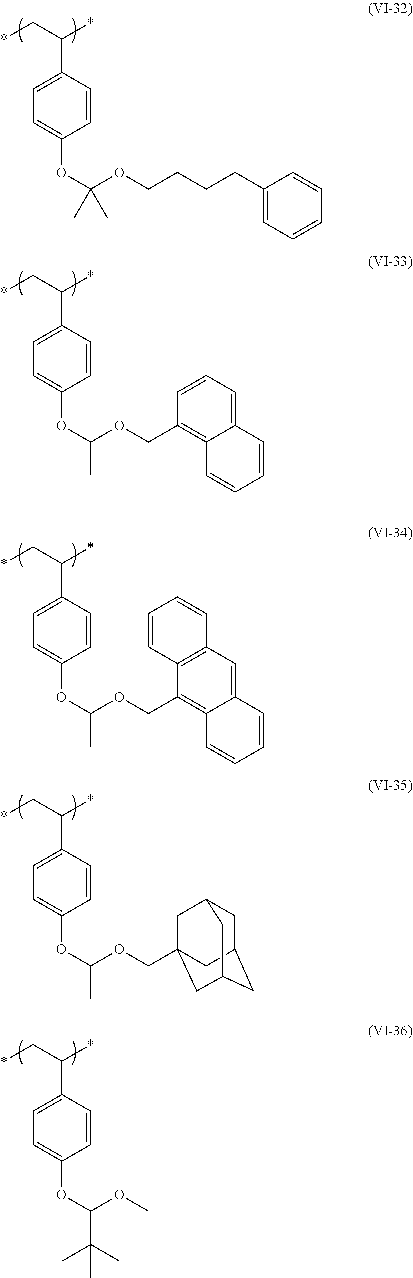

It is also preferable that the resin (A) includes a repeating unit represented by the following Formula (4).

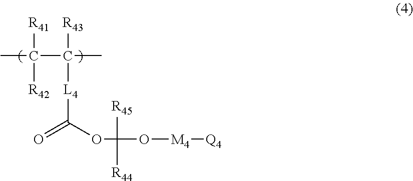

In Formula (4), R₄₁, R₄₂, and R₄₃ each independently represent a hydrogen atom, an alkyl group, a cycloalkyl group, a halogen atom, a cyano group, or an alkoxycarbonyl group. R₄₂ may be bonded to L₄ to form a ring. In this case, R₄₂ represents an alkylene group.

L₄ represents a single bond or a divalent linking group. In a case where L₄ and R₄₂ form a ring, L₄ represents a trivalent linking group.

R₄₄ and R₄₅ represent a hydrogen atom, an alkyl group, a cycloalkyl group, an aryl group, an aralkyl group, an alkoxy group, an acyl group, or a heterocyclic group.

M₄ represents a single bond or a divalent linking group.

Q₄ represents an alkyl group, a cycloalkyl group, an aryl group, or a heterocyclic group.

At least two of Q₄, M₄, and R₄₄ are bonded to each other to form a ring.

R₄₁, R₄₂, and R₄₃ have the same definitions and the same preferable ranges as R₅₁, R₅₂, and R₅₃ in Formula (V).

L₄ has the same definition and the same preferable range as L₅ in Formula (V).

R₄₄ and R₄₅ have the same definition and the same preferable range as R₃ in Formula (3).

M₄ has the same definition and the same preferable range as M₃ in Formula (3).

Q₄ has the same definition and the same preferable range as Q₃ in Formula (3).

Examples of a ring which is formed by at least two of Q₄, M₄, and R₄₄ being bonded to each other include the ring which is formed by at least two of Q₃, M₃, and R₃ being bonded to each other, and preferable ranges thereof are also the same.

Hereinafter, specific examples of the repeating unit represented by Formula (4) will be shown, but the present invention is not limited thereto.

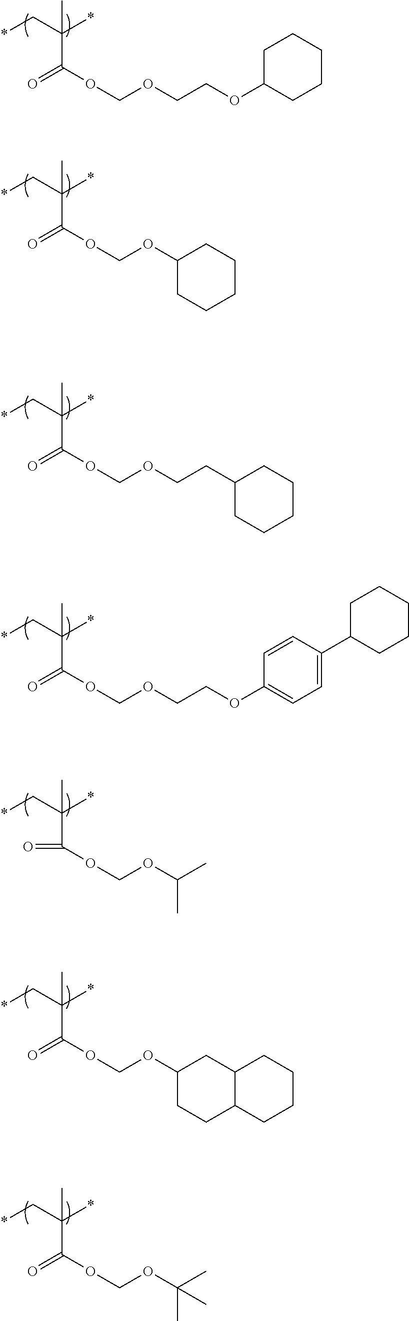

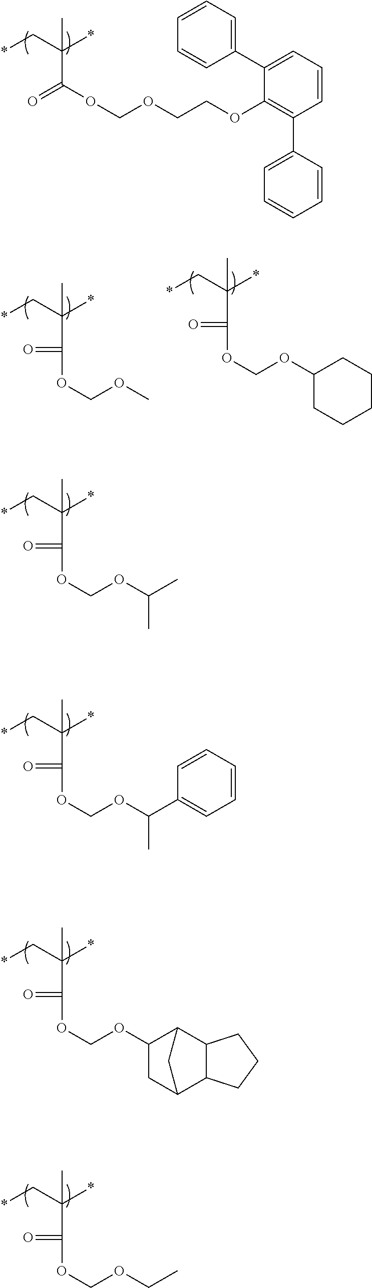

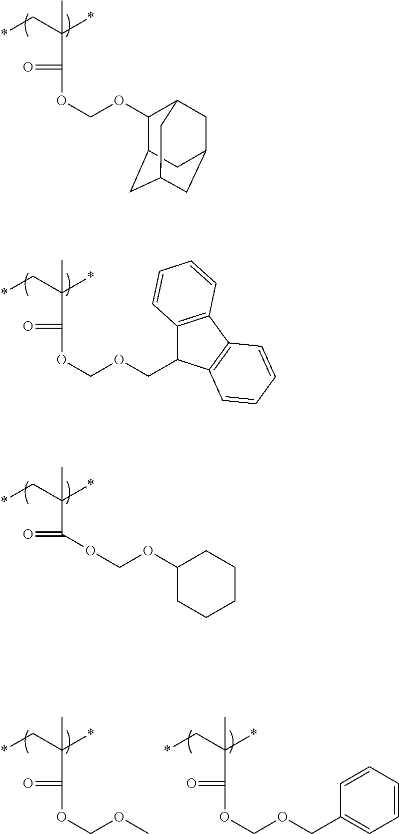

In addition, the resin (A) may include a repeating unit represented by the following Formula (BZ) as the repeating unit (a).

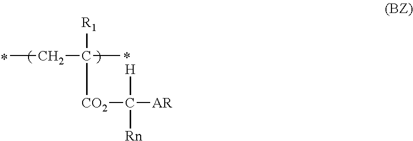

In Formula (BZ), AR represents an aryl group. Rn represents an alkyl group, a cycloalkyl group, or an aryl group. Rn and AR may be bonded to each other to form a nonaromatic ring.

R₁ represents a hydrogen atom, an alkyl group, a cycloalkyl group, a halogen atom, a cyano group, or an alkyloxycarbonyl group.

Hereinafter, specific examples of the repeating unit (a) represented by the formula (BZ) will be shown, but the present invention is not limited thereto.

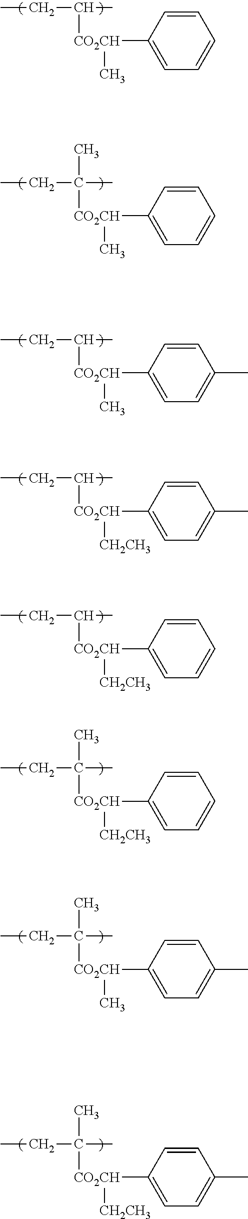

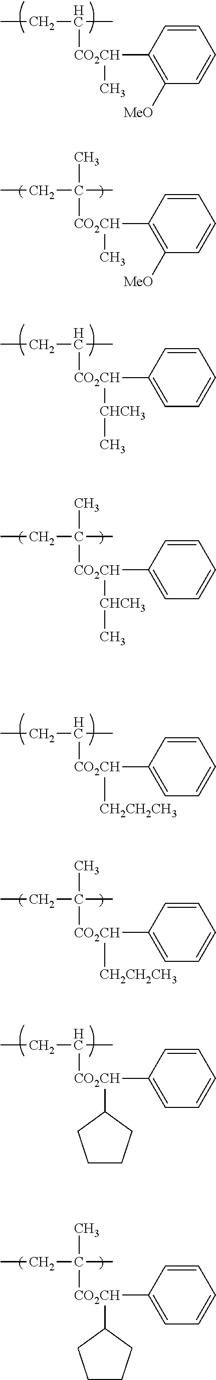

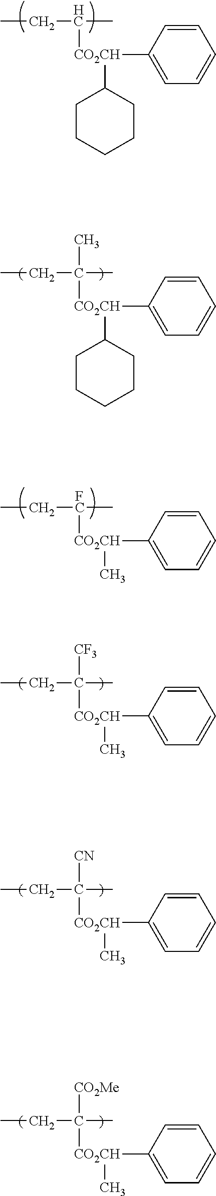

As the repeating unit having an acid-decomposable group, one kind may be used alone, or two or more kinds may be used in combination.

The content of the repeating unit having an acid-decomposable group in the resin (A) (in a case where the resin (A) includes a plurality of repeating units having an acid-decomposable group, the total content thereof) is preferably 5 mol % or higher and 80 mol % or lower, more preferably 5 mol % or higher and 75 mol % or lower, and still more preferably 10 mol % or higher and 65 mol % or lower with respect to all the repeating units of the resin (A).

The resin (A) may include a repeating unit represented by the following Formula (V) or the following Formula (VI).

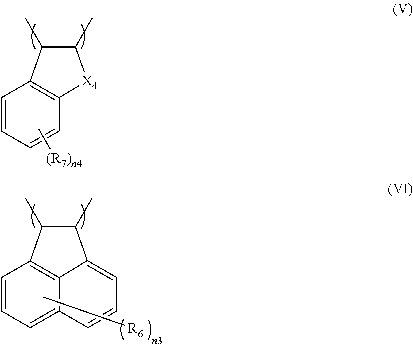

In the formula, R₆ and R₇ each independently represent a hydrogen atom, a hydroxyl group, a linear, branched, or cyclic alkyl group having 1 to 10 carbon atoms, an alkoxy group or acyloxy group, a cyano group, a nitro group, an amino group, a halogen atom, an ester group (—OCOR or —COOR: R represents an alkyl group having 1 to 6 carbon atoms or a fluorinated alkyl group), or a carboxyl group.

n₃ represents an integer of 0 to 6.

X₄ represents a methylene group, an oxygen atom, or a sulfur atom.

Hereinafter, specific examples of the repeating unit represented by Formula (V) or Formula (VI) will be shown, but the present invention is not limited thereto.

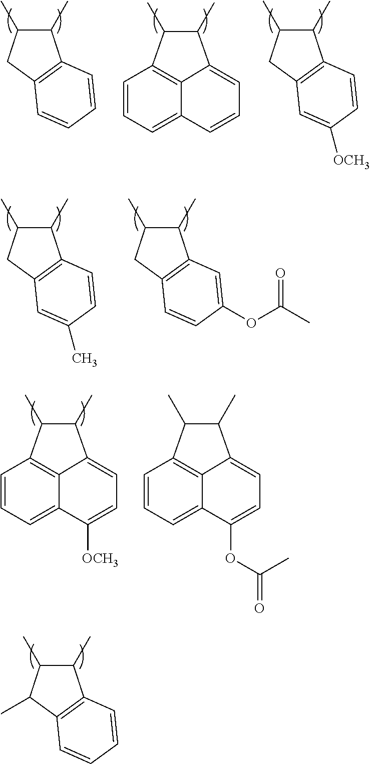

(B) Compound (Photoacid Generator) which generates Acid by Actinic Ray or Radiation

It is preferable that the actinic ray-sensitive or radiation-sensitive composition includes a compound (hereinafter, also referred to as “photoacid generator (PAG)”) which generates an acid by an actinic ray or radiation.

The photoacid generator may be a low molecular weight compound or may be incorporated into a part of a polymer. In addition, the photoacid generator may be a low molecular weight compound which is incorporated into a polymer.

In a case where the photoacid generator is a low molecular weight compound, the molecular weight is preferably 3000 or lower, more preferably 2000 or lower, and still more preferably 1000 or lower.

In a case where the photoacid generator is incorporated into a part of a polymer, the photoacid generator may be incorporated into a part of the resin (A) or another resin different from the resin (A).

In the present invention, it is preferable that the photoacid generator is a low molecular weight compound.

The photoacid generator is not particularly limited as long as it is well-known. As the photoacid generator, a compound, which generates an organic acid, for example, at least one of sulfonic acid, bis(alkylsulfonyl)imide, or tris(alkylsulfonyl)methide when irradiated with an actinic ray or radiation and preferably an electron beam or an extreme ultraviolet ray, is preferable.

A compound represented by the following Formula (ZI), (ZII) or (ZIII) is more preferable.

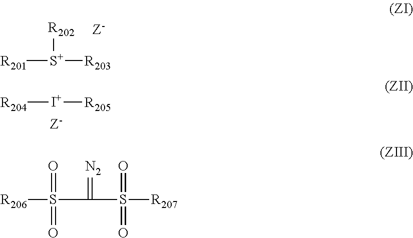

In Formula (ZI), R₂₀₁, R₂₀₂, and R₂₀₃ each independently represent an organic group.

The number of carbon atoms in the organic group represented by R₂₀₁, R₂₀₂, and R₂₀₃ is generally 1 to 30 and preferably 1 to 20.

In addition, two of R₂₀₁ to R₂₀₃ may be bonded to each other to form a ring structure, and the ring may include an oxygen atom, a sulfur atom, an ester bond, an amide bond, or a carbonyl group. Examples of the group which is formed by two of R₂₀₁ to R₂₀₃ being bonded to each other include an alkylene group (for example, a butylene group or a pentylene group).

Z⁻ represents a non-nucleophilic anion (an anion having a significantly low ability to cause a nucleophilic reaction to occur).

Examples of the non-nucleophilic anion include a sulfonate anion (for example, an aliphatic sulfonate anion, an aromatic sulfonate anion, or a camphor sulfonate anion), a carboxylate anion (for example, an aliphatic carboxylate anion, an aromatic carboxylate anion, or an araylkyl carboxylate anion), a sulfonyl imide anion, a bis(alkylsulfonyl)imide anion, and a tris(alkylsulfonyl)methide anion.

An aliphatic site in the aliphatic sulfonate anion and the aliphatic carboxylate anion may be an alkyl group or a cycloalkyl group and is preferably a linear or branched alkyl group having 1 to 30 carbon atoms or a cycloalkyl group having 3 to 30 carbon atoms.

As the aromatic group in the aromatic sulfonate anion and the aromatic carboxylate anion, an aryl group having 6 to 14 carbon atoms is preferable, and examples thereof include a phenyl group, a tolyl group, and naphthyl group.

The alkyl group, the cycloalkyl group, and the aryl group described above may have a substituent. Specific examples of the substituent include a nitro group, a halogen atom such as a fluorine atom, a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 1 to 15 carbon atoms), an aryloxysulfonyl group (preferably having 6 to 20 carbon atoms), an alkylaryloxysulfonyl group (preferably having 7 to 20 carbon atoms), a cycloalkylaryloxysulfonyl group (preferably having 10 to 20 carbon atoms), an alkyloxyalkyloxy group (preferably having 5 to 20 carbon atoms), and a cycloalkylalkyloxyalkyloxy group (preferably having 8 to 20 carbon atoms). Examples of an aryl group and a ring structure included in each of the groups include an alkyl group (preferably having 1 to 15 carbon atoms) as a substituent.

As the aralkyl group in the aralkyl carboxylate anion, an aralkyl group having 7 to 12 carbon atoms is preferable, and examples thereof include a benzyl group, a phenethyl group, a naphthylmethyl group, a naphthylethyl group, and a naphthylmethyl group.

Examples of the sulfonyl imide anion include a saccharin anion.

As the alkyl group in the bis(alkylsulfonyl)imide anion and the tris(alkylsulfonyl)methide anion, an alkyl group having 1 to 5 carbon atoms is preferable. Examples of a substituent of the alkyl group include a halogen atom, an alkyl group substituted with a halogen atom, an alkoxy group, an alkylthio group, an alkyloxysulfonyl group, an aryloxysulfonyl group, and a cycloalkylaryloxysulfonyl group. Among these, a fluorine atom or an alkyl group substituted with a fluorine atom is preferable. In addition, the alkyl groups in the bis(alkylsulfonyl)imide anions may be bonded to each other to form a ring structure. As a result, the acid strength increases.

Other examples of the non-nucleophilic anion include phosphorus fluoride (for example, PF₆⁻), boron fluoride (for example, BF₄⁻), and antimony fluoride (for example, SbF₆⁻).

As the non-nucleophilic anion, an aliphatic sulfonate anion in which at least the α-position of sulfonic acid is substituted with a fluorine atom, an aromatic sulfonate anion substituted with a fluorine atom or a group having a fluorine atom, a bis(alkylsulfonyl)imide anion in which the alkyl group is substituted with a fluorine atom, or a tris(alkylsulfonyl)methide anion in which the alkyl group is substituted with a fluorine atom is preferable. As the non-nucleophilic anion, a perfluoroaliphatic sulfonate anion (still more preferably having 4 to 8 carbon atoms) or a benzenesulfonate anion having a fluorine atom is more preferable, and a nonafluorobutanesulfonate anion, a perfluorooctanesulfonate anion, a pentafluorobenzenesulfonate anion, or a 3,5-bis(trifluoromethyl)benzenesulfonate anion is still more preferable.

From the viewpoint of the acid strength, it is preferable that the pKa of the acid generated is −1 or lower to improve sensitivity.

In addition, as the non-nucleophilic anion, for example, an anion represented by the following Formula (AN1) is preferable.

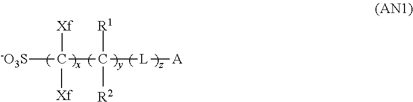

In the formula, Xf's each independently represent a fluorine atom or an alkyl group substituted with at least one fluorine atom.

R¹ and R² each independently represent a hydrogen atom, a fluorine atom, or an alkyl group. In a case where a plurality of R¹'s and a plurality of R²'s are present, R¹'s and R²'s may be the same as or different from each other.

L represents a divalent linking group. In a case where a plurality of L's are present, L's may be the same as or different from each other.

A represents a cyclic organic group.

x represents an integer of 1 to 20, y represent an integer of 0 to 10, and z represents an integer of 0 to 10.

Formula (AN1) will be described in more detail.

As the alkyl group in the alkyl group substituted with a fluorine atom represented by Xf, an alkyl group having 1 to 10 carbon atoms is preferable, and an alkyl group having 1 to 4 carbon atoms is more preferable. In addition, as the alkyl group in the alkyl group substituted with a fluorine atom represented by Xf, a perfluoroalkyl group is preferable.

Xf represents preferably a fluorine atom or a perfluoroalkyl group having or 1 to 4 carbon atoms. Specific examples of Xf include a fluorine atom, CF₃, C₂F₅, C₃F₇, C₄F₉, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉. Among these, a fluorine atom or CF₃ is preferable.

In particular, it is preferable that both Xf's represent a fluorine atom.

The alkyl group represented by R¹ and R² may have a substituent (preferably a fluorine atom), and an alkyl group having 1 to 4 carbon atoms is preferable. A perfluoroalkyl group having 1 to 4 carbon atoms is more preferable. Specific examples of the alkyl group having a substituent represented by R¹ and R² include CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉. Among these, CF₃ is preferable.

R¹ and R² represent preferably a fluorine atom or CF₃.

x represents preferably 1 to 10 and more preferably 1 to 5.

y represents preferably 0 to 4 and more preferably 0.

z represents 0 to 5 and more preferably 0 to 3.

The divalent linking group represented by L is not particularly limited, and examples thereof include —COO—, —OCO—, —CO—, —O—, —S—, —SO—, —SO₂—, an alkylene group, a cycloalkyl group, an alkenylene group, a linking group obtained by linking two or more kinds among the above-described groups linking to each other. A linking group having 12 or less carbon atoms in total is preferable. Among these, —COO—, —OCO—, —CO—, or —O— is preferable, and —COO— or —OCO— is more preferable.

The cyclic organic group represented by A is not particularly limited as long as it has a cyclic structure, and examples thereof include an alicyclic group, an aryl group, a heterocyclic group (including not only an aromatic heterocyclic group but also a nonaromatic heterocyclic group).

The alicyclic group may be monocyclic or polycyclic, and a monocycloalkyl group such as a cyclopentyl group, a cyclohexyl group, or an isooctyl group, or a polycycloalkyl group such as a norbomyl group, a tricyclodecanyl group, a tetracyclodecanyl group, a tetracyclododecanyl group, or an adamantyl group is preferable. Among these, an alicyclic group having a bulky structure which has 7 or more carbon atoms such as a norbomyl group, a tricyclodecanyl group, a tetracyclodecanyl group, a tetracyclododecanyl group, or an adamantyl group is preferable from the viewpoints of suppressing in-film diffusion in a heating step after exposure and improving a mask error enhancement factor (MEEF).

Examples of the aryl group include a benzene ring, a naphthalene ring, a phenanthrene ring, and an anthracene ring.

Examples of the heterocyclic group include a furan ring, a thiophene ring, a benzofuran ring, a benzothiophene ring, a dibenzofuran ring, a dibenzothiophene ring, and a group derived from a pyridine ring. Among these, a furan ring, a thiophene ring, or a group derived from a pyridine ring is preferable.

In addition, as the cyclic organic group, a lactone structure can be used, and specific examples thereof include lactone structures represented by the following Formulae (LC1-1) to (LC1-17).

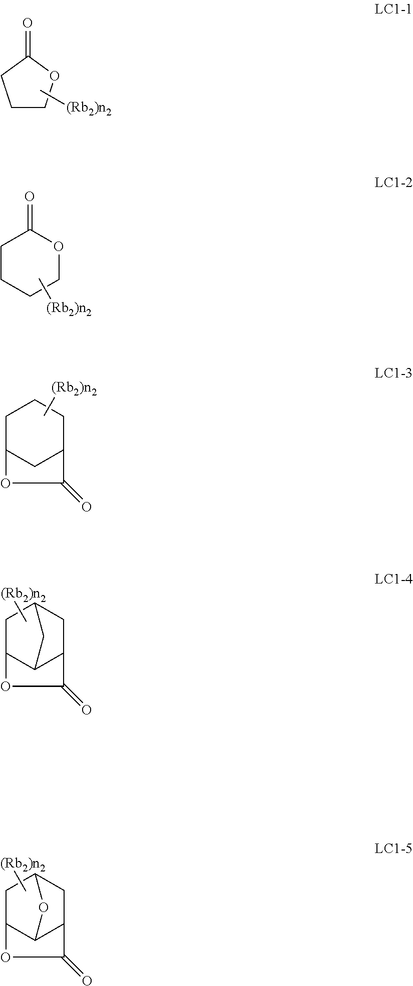

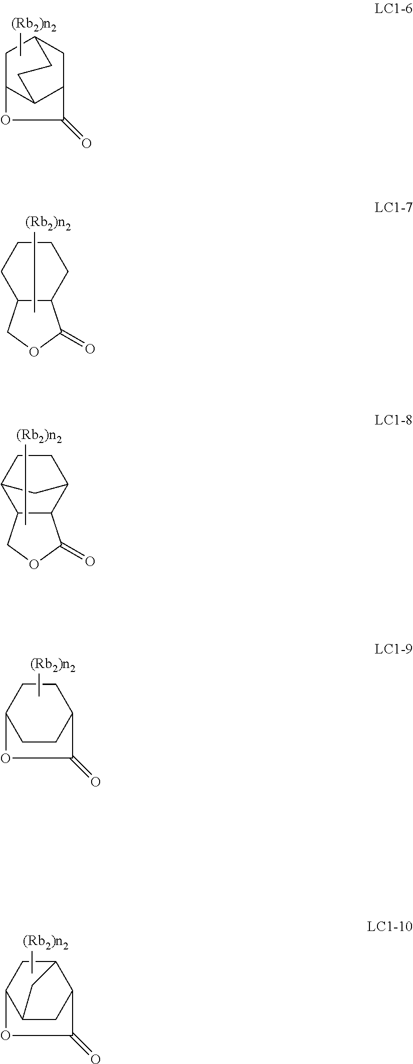

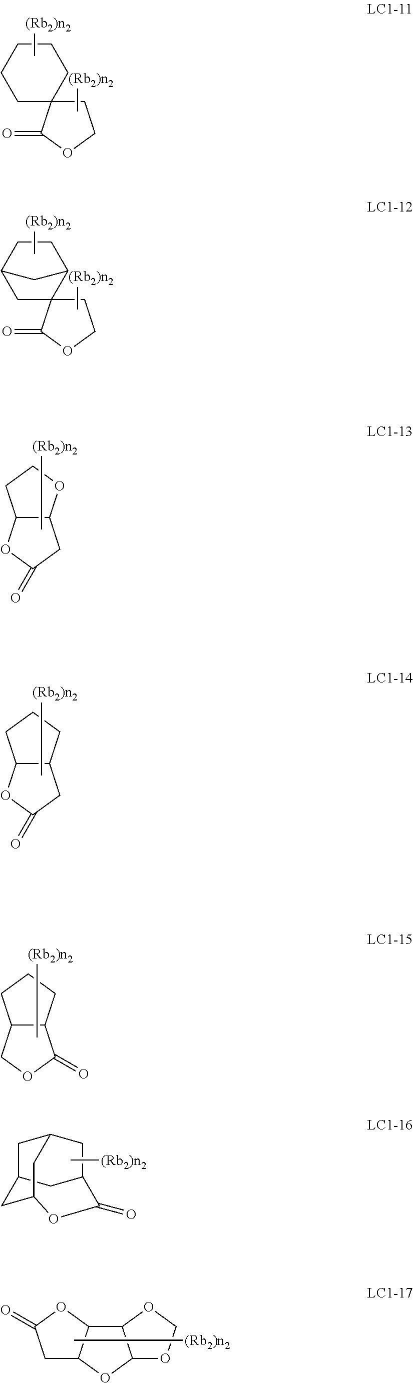

The cyclic organic group may have a substituent, and examples of the substituent include an alkyl group (a linear, branched, or cyclic alkyl group; preferably having 1 to 12 carbon atoms), a cycloalkyl group (a monocycle, a polycycle, or a spiro ring; preferably having 3 to 20 carbon atoms), an aryl group (a linear, branched, or aryl group; preferably having 6 to 14 carbon atoms), a hydroxyl group, an alkoxy group, an ester group, an amido group, a urethane group, an ureido group, a thioether group, a sulfonamide group, and a sulfonate group. Carbon (carbon contributing to ring formation) constituting the cyclic organic group may be carbonyl carbon.

Examples of the organic group represented by R₂₀₁, R₂₀₂, and R₂₀₃ include an aryl group, an alkyl group, and a cycloalkyl group.

It is preferable that at least one of R₂₀₁, R₂₀₂, or R₂₀₃ represents an aryl group, and it is more preferable that all of R₂₀₁, R₂₀₂, or R₂₀₃ represent an aryl group. As the aryl group, not only a phenyl group or a naphthyl group but also a heteroaryl group such as an indole residue or a pyrrole residue may be used. As the alkyl group and the cycloalkyl group represented by R₂₀₁ to R₂₀₃, a linear or branched alkyl group having 1 to 10 carbon atoms or a cycloalkyl group having 3 to 10 carbon atoms is preferable. As the alkyl group, a methyl group, an ethyl group, a n-propyl group, an i-propyl group, or a n-butyl group is more preferable. As the cycloalkyl group, a cyclopropyl group, a cyclobutyl group, a cyclopentyl group, a cyclohexyl group, or a cycloheptyl group is more preferable. Each of the groups may further have a substituent. Examples of the substituent include a nitro group, a halogen atom such as a fluorine atom, a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), and an alkoxycarbonyloxy group (preferably having 2 to 7 carbon atoms), but the present invention is not limited thereto.

In the present invention, from the viewpoint of suppressing diffusion of an acid generated by exposure to a non-exposed portion and improving resolution, the photoacid generator is preferably a compound which generates an acid (more preferably sulfonic acid) having a volume of 130 Å³ or higher when irradiated with an electron beam or an extreme ultraviolet ray, more preferably a compound which generates an acid (more preferably sulfonic acid) having a volume of 190 Å³ or higher, still more preferably a compound which generates an acid (more preferably sulfonic acid) having a volume of 270 Å³ or higher, and even still more preferably a compound which generates an acid (more preferably sulfonic acid) having a volume of 400 Å³ or higher. From the viewpoints of sensitivity and coating solvent solubility, the volume is preferably 2000 Å³ or lower and more preferably 1500 Å³ or lower. A value of the volume is obtained using “WinMOPAC” (manufactured by FUJITSU). That is, a chemical structure of an acid according to each example is input. Next, the most stable conformation of each acid is determined through a molecular field calculation using a MM3 method with the input chemical structure as an initial structure. Next, a molecular orbital calculation is performed on the most stable conformation using a PM3 method. As a result, “accessible volume” of each acid can be calculated.

In the present invention, the following examples of the photoacid generators which generate an acid when irradiated with an actinic ray or radiation are preferable. In some of the examples, a calculated value of the volume is added (unit: Å³). The calculated value herein denotes a value of an acid in which a proton is bonded to the anion portion.

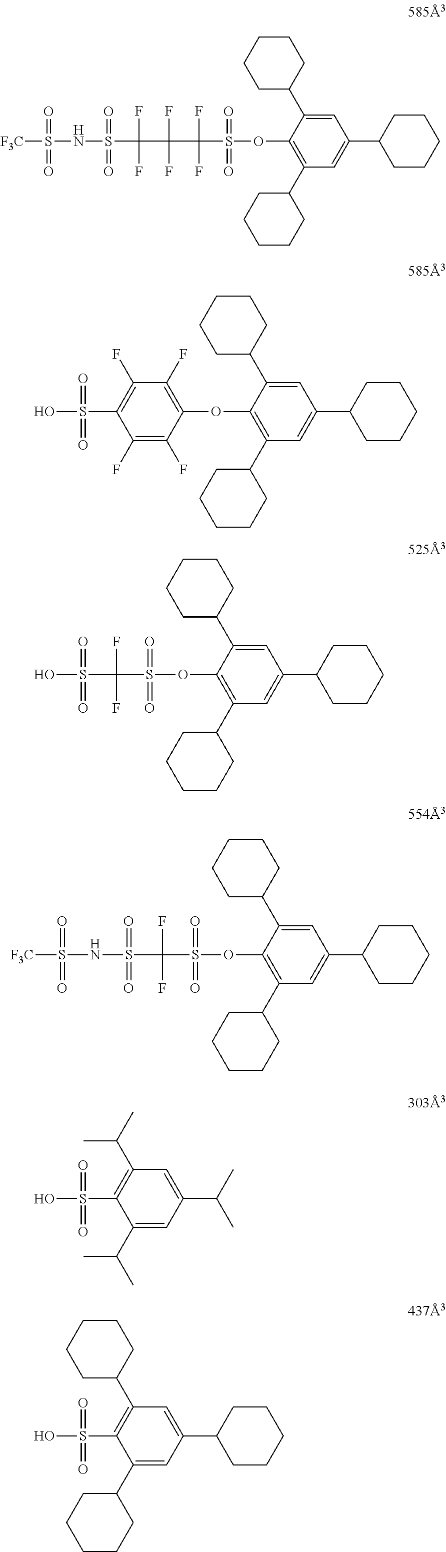

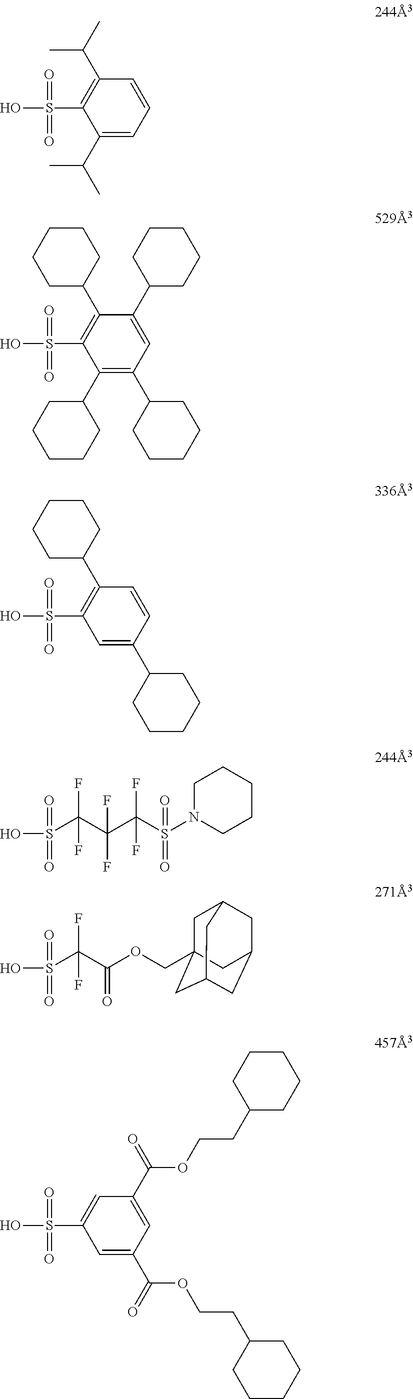

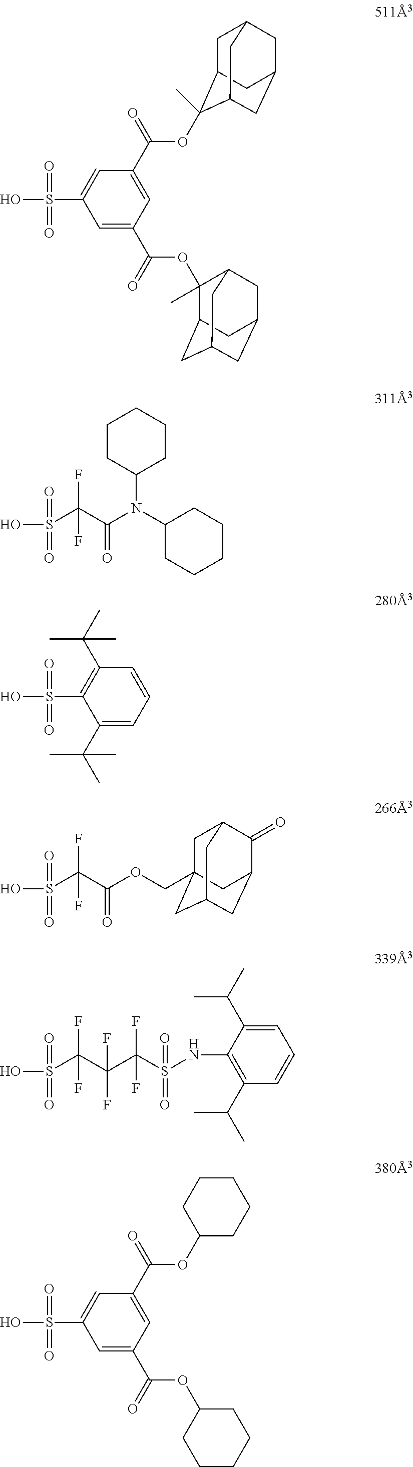

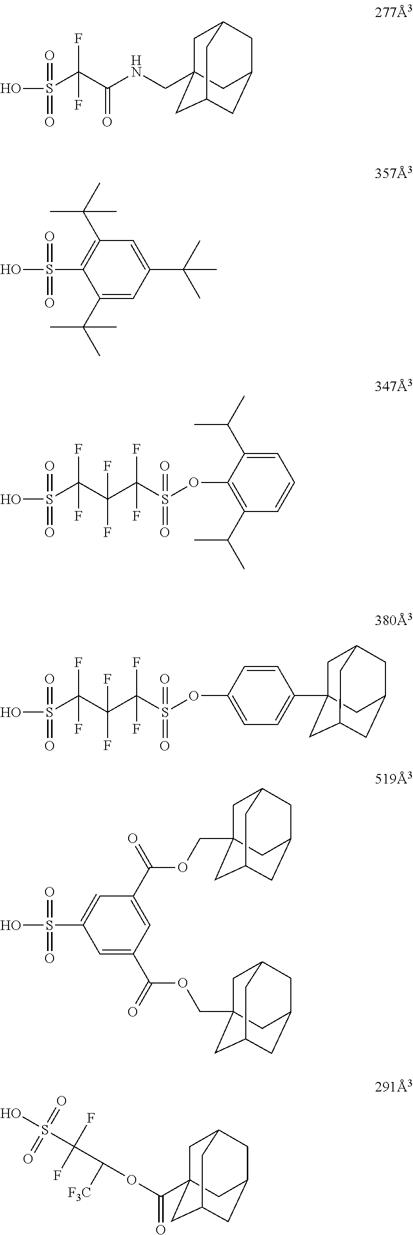 [SMILES: O=C(NCC12CC3CC(CC(C3)C1)C2)C(F)(F)S(=O)(=O)O ; CC(C)(C)c1cc(C(C)(C)C)c(S(=O)(=O)O)c(C(C)(C)C)c1 ; CC(C)c1cccc(C(C)C)c1OS(=O)(=O)C(F)(F)C(F)(F)C(F)(F)S(=O)(=O)O ; O=S(=O)(O)C(F)(F)C(F)(F)C(F)(F)S(=O)(=O)Oc1ccc(C23CC4CC(CC(C4)C2)C3)cc1 ; O=C(OCC12CC3CC(CC(C3)C1)C2)c1cc(C(=O)OCC23CC4CC(CC(C4)C2)C3)cc(S(=O)(=O)O)c1 ; O=C(OC(C(F)(F)F)C(F)(F)S(=O)(=O)O)C12CC3CC(CC(C3)C1)C2]

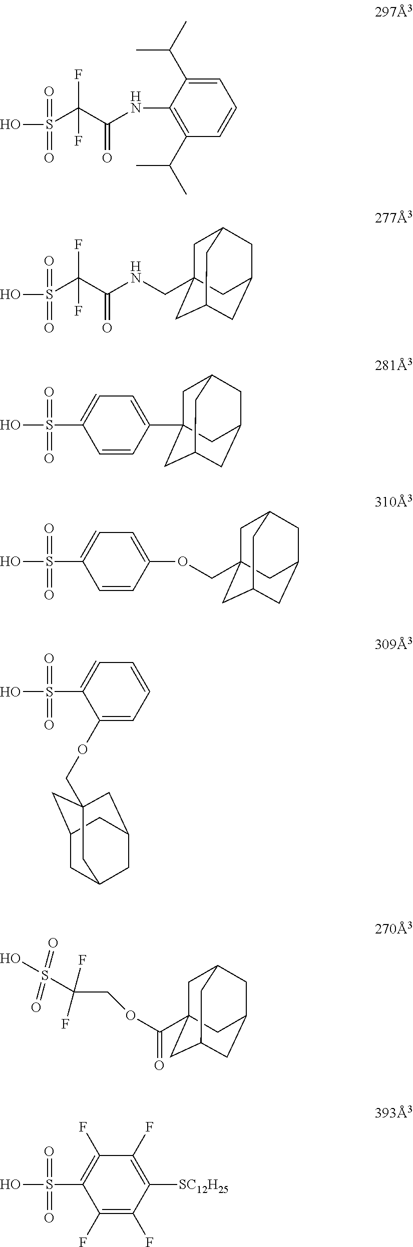

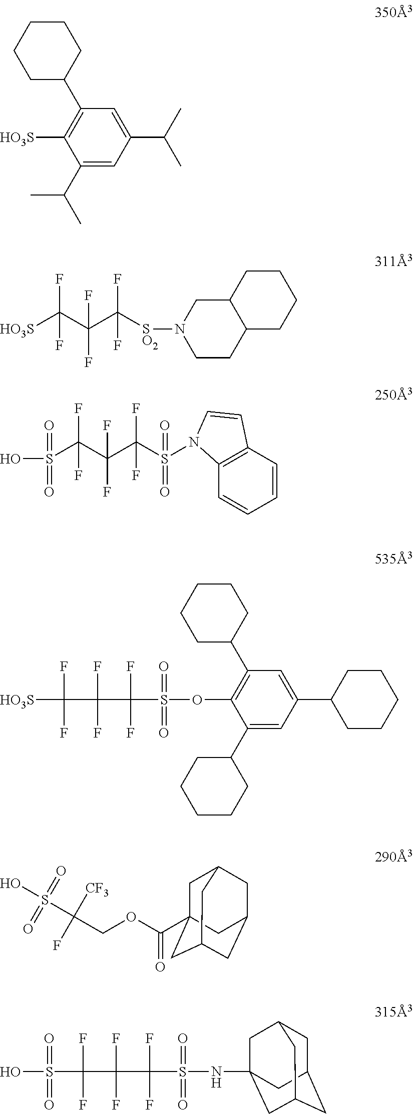 [SMILES: CC(C)c1cc(C(C)C)c(S(=O)(=O)O)c(C2CCCCC2)c1 ; O=S(=O)(O)C(F)(F)C(F)(F)C(F)(F)S(=O)(=O)N1CCC2CCCCC2C1 ; O=S(=O)(O)C(F)(F)C(F)(F)C(F)(F)S(=O)(=O)n1ccc2ccccc21 ; O=S(=O)(O)C(F)(F)C(F)(F)C(F)(F)S(=O)(=O)Oc1c(C2CCCCC2)cc(C2CCCCC2)cc1C1CCCCC1 ; O=C(OCC(F)(C(F)(F)F)S(=O)(=O)O)C12CC3CC(CC(C3)C1)C2 ; O=S(=O)(O)C(F)(F)C(F)(F)C(F)(F)S(=O)(=O)NC12CC3CC(CC(C3)C1)C2]

The details of the photoacid generator can be found in paragraphs “0368” to “0377” of JP2014-41328A and paragraphs “0240” to “0262” of JP2013-228681A (corresponding to paragraph “0339” of US2015/004533A), the content of which is incorporated herein by reference. In addition, preferable specific examples include the following compounds, but the present invention is not limited thereto.

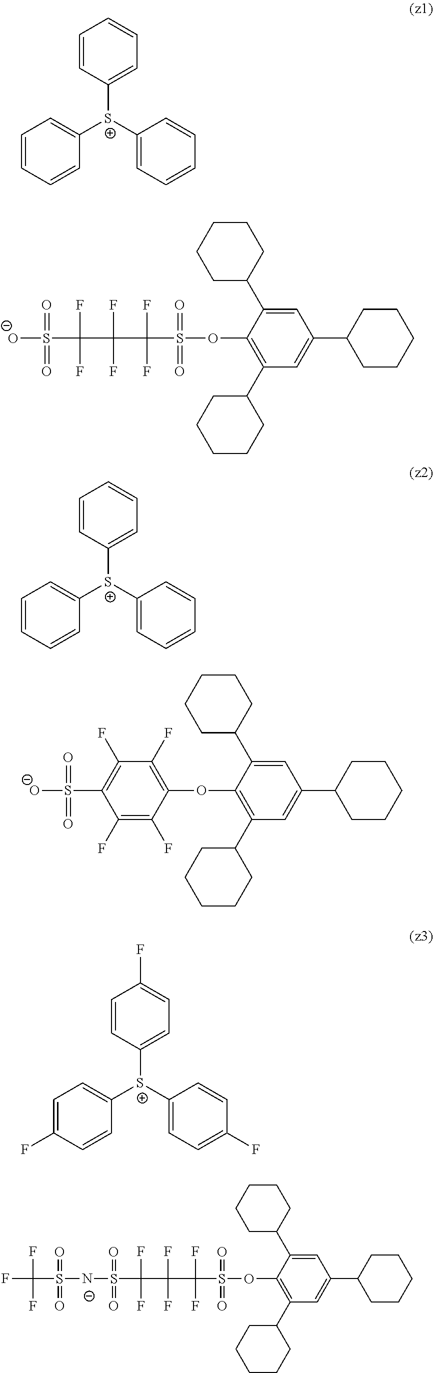 [SMILES: c1ccc([S+](c2ccccc2)c2ccccc2)cc1 ; O=S(=O)([O-])C(F)(F)C(F)(F)C(F)(F)S(=O)(=O)Oc1c(C2CCCCC2)cc(C2CCCCC2)cc1C1CCCCC1 ; c1ccc([S+](c2ccccc2)c2ccccc2)cc1 ; O=S(=O)([O-])c1c(F)c(F)c(Oc2c(C3CCCCC3)cc(C3CCCCC3)cc2C2CCCCC2)c(F)c1F ; Fc1ccc([S+](c2ccc(F)cc2)c2ccc(F)cc2)cc1 ; O=S(=O)([N-]S(=O)(=O)C(F)(F)C(F)(F)C(F)(F)S(=O)(=O)Oc1c(C2CCCCC2)cc(C2CCCCC2)cc1C1CCCCC1)C(F)(F)F]

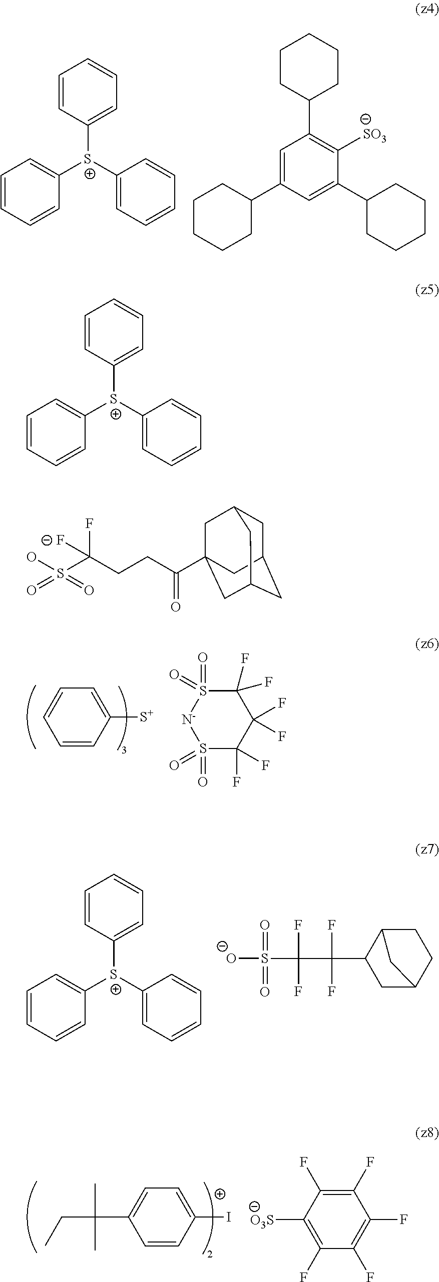

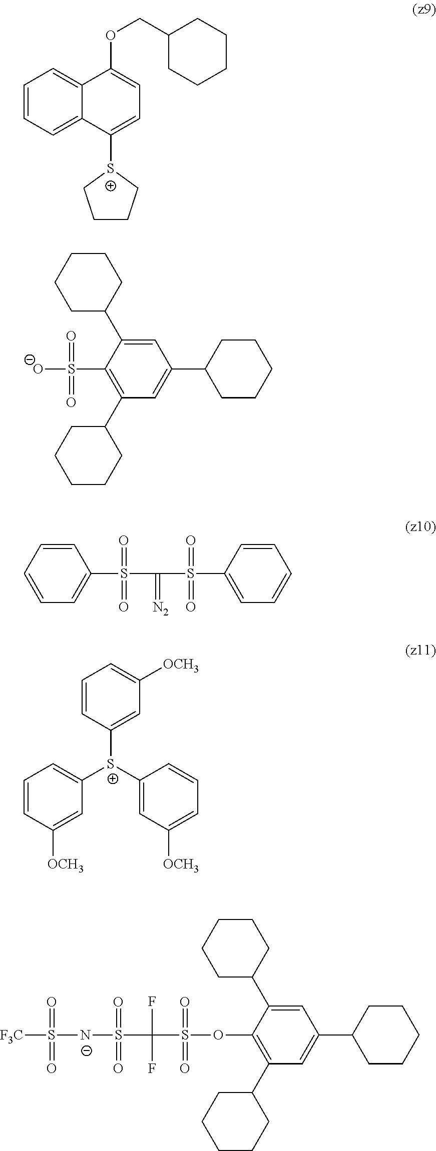

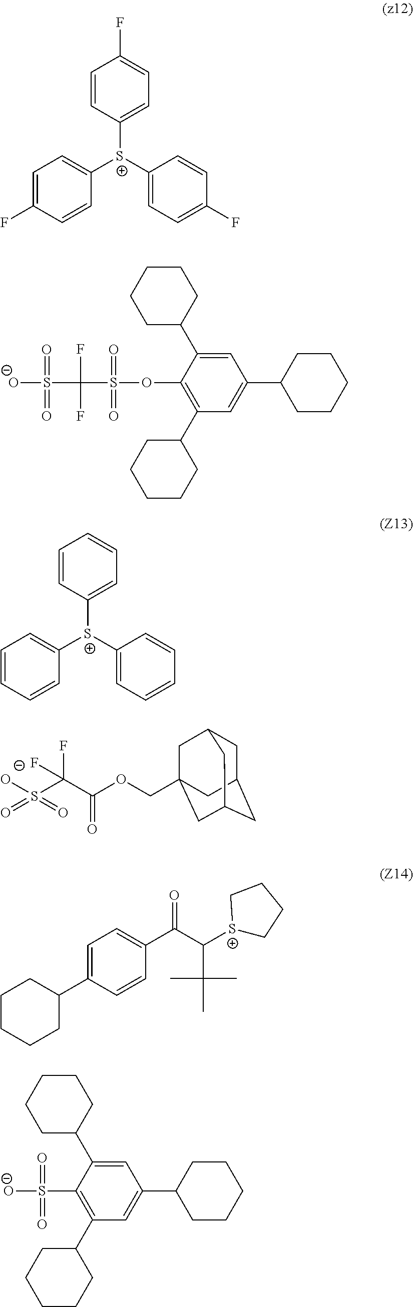 [SMILES: Fc1ccc([S+](c2ccc(F)cc2)c2ccc(F)cc2)cc1 ; O=S(=O)([O-])C(F)(F)S(=O)(=O)Oc1c(C2CCCCC2)cc(C2CCCCC2)cc1C1CCCCC1 ; c1ccc([S+](c2ccccc2)c2ccccc2)cc1 ; O=C(OCC12CC3CC(CC(C3)C1)C2)C(F)(F)S(=O)(=O)[O-] ; CC(C)(C)C(C(=O)c1ccc(C2CCCCC2)cc1)[S+]1CCCC1 ; O=S(=O)([O-])c1c(C2CCCCC2)cc(C2CCCCC2)cc1C1CCCCC1]

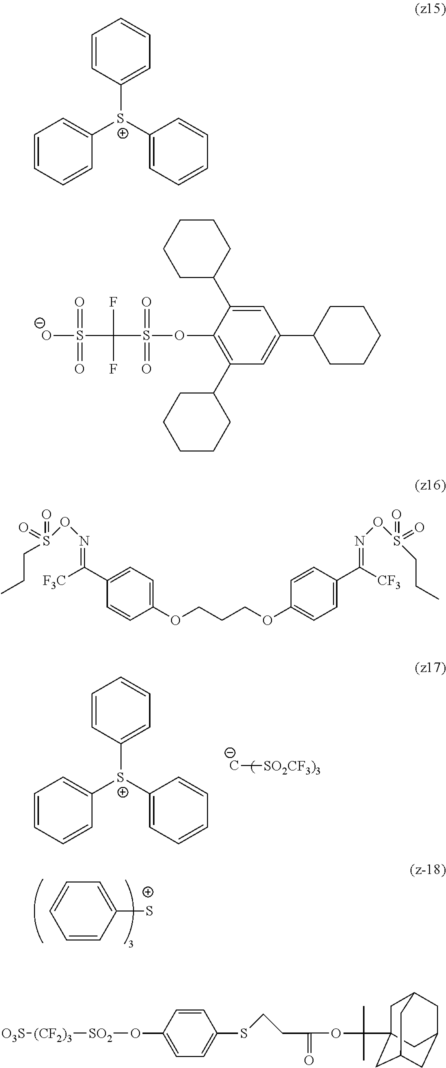

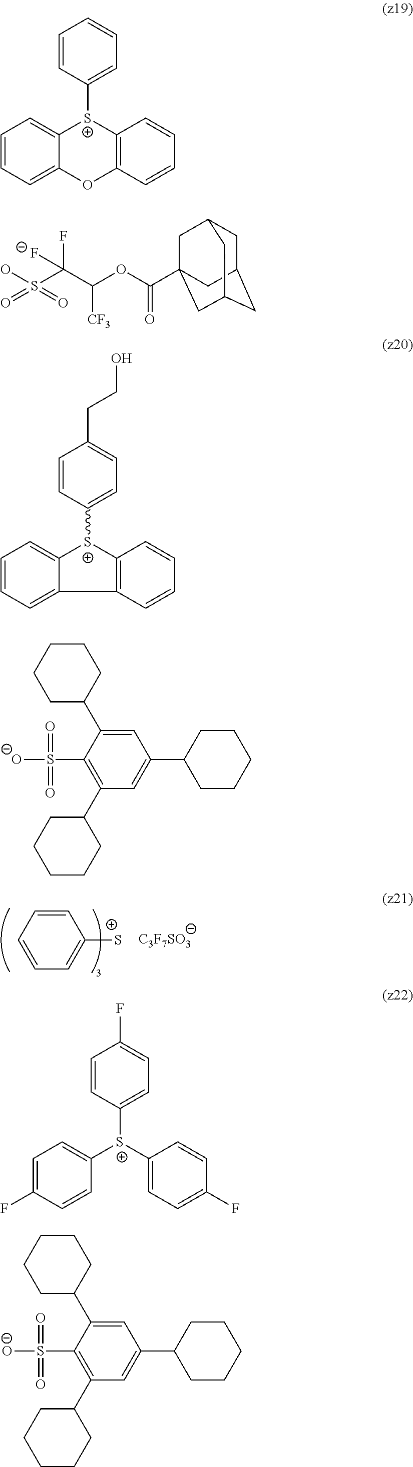

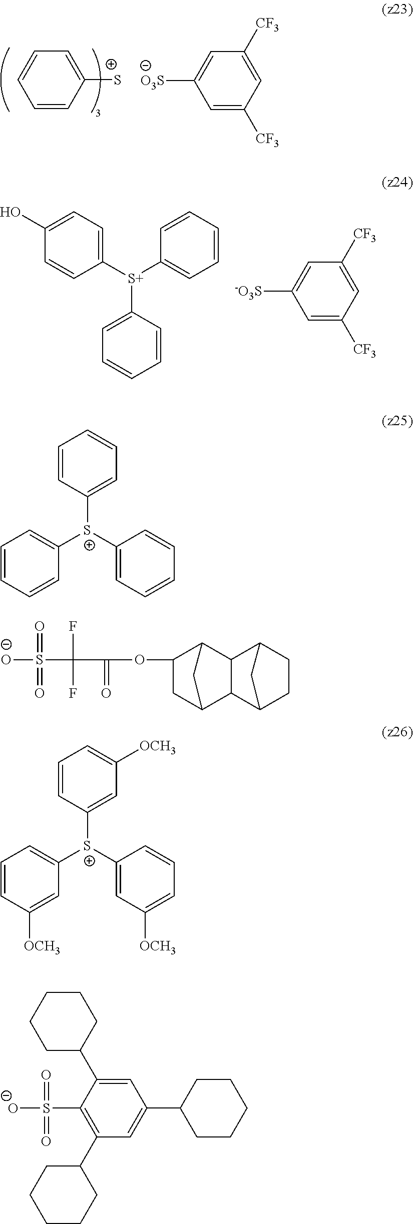

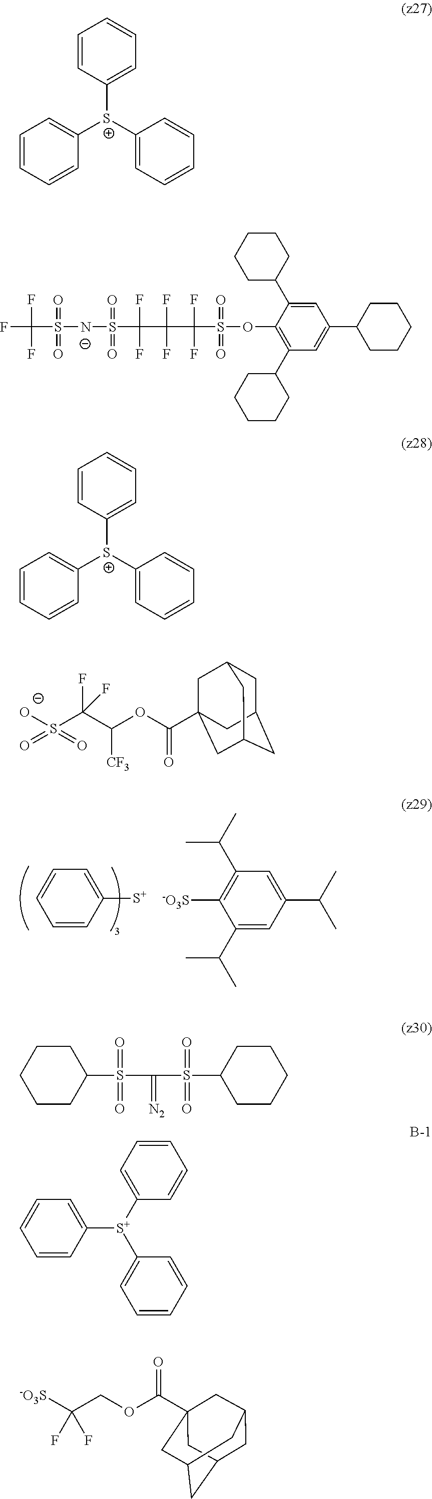

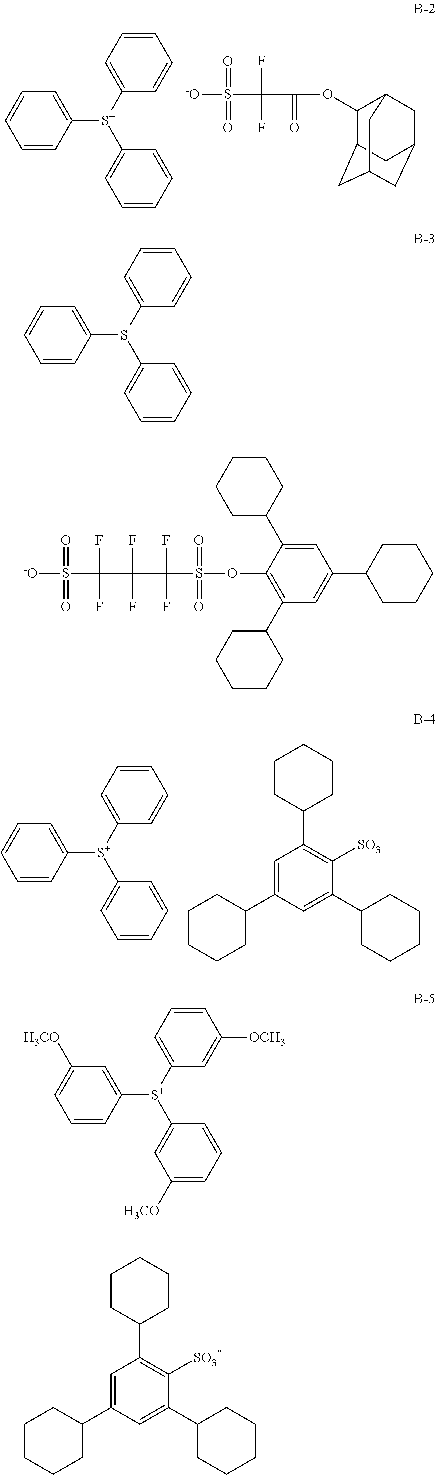

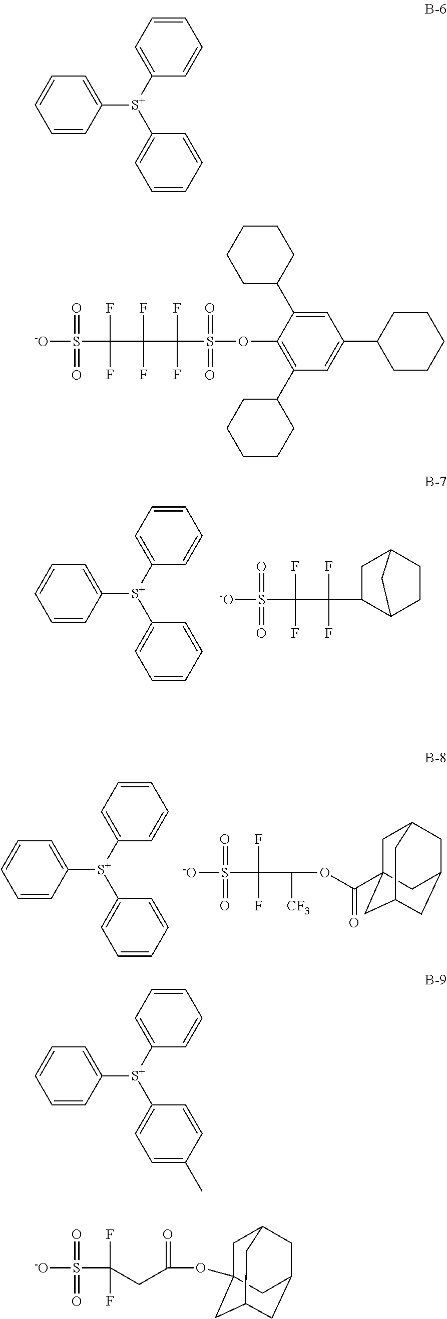

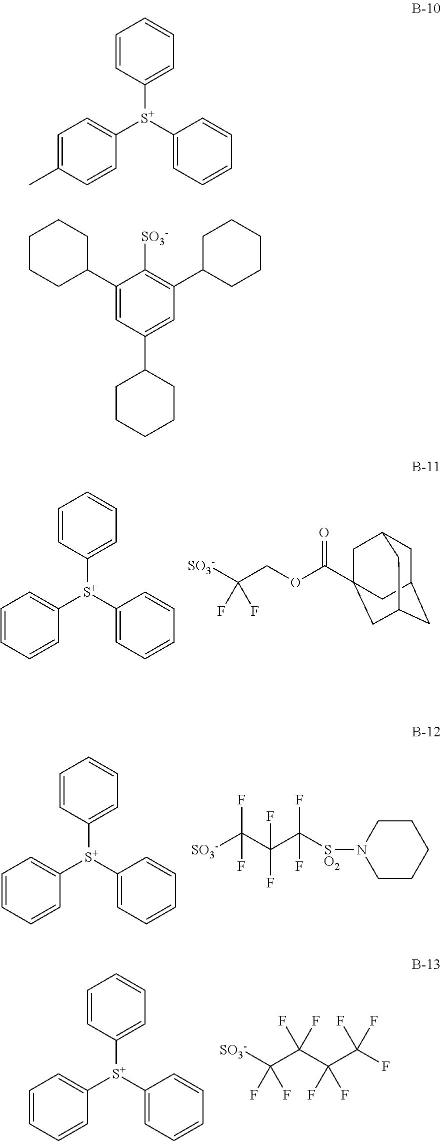

As the photoacid generator, one kind may be used alone, or two or more kinds may be used in combination.

The content of the photoacid generator in the actinic ray-sensitive or radiation-sensitive composition is preferably 0.1 to 50 mass %, more preferably 5 to 50 mass %, and still more preferably 8 to 40 mass % with respect to the total solid content of the composition. In particular, in order to simultaneously realize high sensitivity and high resolution during irradiation of an electron beam or an extreme ultraviolet ray, the content of the photoacid generator is preferably high, more preferably 10 to 40 mass %, and still more preferably 10 to 35 mass %.

(C) Solvent

In order to dissolve the respective components to prepare the actinic ray-sensitive or radiation-sensitive composition, a solvent can be used. Examples of the solvent used include an organic solvent such as alkylene glycol monoalkyl ether carboxylate, alkylene glycol monoalkyl ether, alkyl lactate, alkyl alkoxy propionate, cyclic lactone having 4 to 10 carbon atoms, a monoketone compound having 4 to 10 carbon atoms which may include a ring, alkylene carbonate, alkyl alkoxy acetate, or alkyl pyruvate,

Preferable examples of the alkylene glycol monoalkyl ether carboxylate include propylene glycol monomethyl ether acetate, propylene glycol monoethyl ether acetate, propylene glycol propyl ether acetate, propylene glycol monobutyl ether acetate, propylene glycol monomethyl ether propionate, propylene glycol monoethyl ether propionate, ethylene glycol monomethyl ether acetate, and ethylene glycol monoethyl ether acetate.

Preferable examples of the alkylene glycol monoalkyl ether include propylene glycol monomethyl ether, propylene glycol monoethyl ether, propylene glycol monopropyl ether, propylene glycol monobutyl ether, ethylene glycol monomethyl ether, and ethylene glycol monoethyl ether.

Preferable examples of the alkyl lactate include methyl lactate, ethyl lactate, propyl lactate, and butyl lactate.

Preferable examples of the alkyl alkoxy propionate include 3-ethyl ethoxypropionate, 3-methyl methoxypropionate, 3-methyl ethoxypropionate, and ethyl 3-methoxypropionate.

Examples of the cyclic lactone having 4 to 10 carbon atoms include β-propiolactone, β-butyrolactone, γ-butyrolactone, α-methyl-γ-butyrolactone, β-methyl-γ-butyrolactone, γ-valerolactone, γ-caprolactone, γ-octanoic lactone, and α-hydroxy-γ-butyrolactone.

Preferable examples of the monoketone compound having 4 to 10 carbon atoms which may include a ring include 2-butanone, 3-methylbutanone, pinacolone, 2-pentanone, 3-pentanone, 3-methyl-2-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-3-hexanone, 2-heptanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexen-2-one, 3-penten-2-one, cyclopentanone, 2-methylcyclopentanone, 3-methylcyclopentanone, 2,2-dimethylcyclopentanone, 2,4,4-trimethylcyclopentanone, cyclohexanone, 3-methylcyclohexanone, 4-methylcyclohexanone, 4-ethylcyclohexanone, 2,2-dimethylcyclohexanone, 2,6-dimethylcyclohexanone, 2,2,6-trimethylcyclohexanone, cycloheptanone, 2-methylcycloheptanone, and 3-methylcycloheptanone.

Preferable examples of the alkylene carbonate include propylene carbonate, vinylene carbonate, ethylene carbonate, and butylene carbonate.

Preferable examples of the alkyl acetate include 2-methoxyethyl acetate, 2-ethoxyethyl acetate, 2-(2-ethoxyethoxy)ethyl acetate, 3-methoxy-3-methylbutyl acetate, and 1-methoxy-2-propyl acetate.

Preferable examples of the alkyl pyruvate include methyl pyruvate, ethyl pyruvate, and propyl pyruvate.

Preferable examples of the solvent which can be used include a solvent having a boiling point of 130° C. or higher at a normal temperature under a normal pressure. Specific examples of the solvent include cyclopentanone, γ-butyrolactone, cyclohexanone, ethyl lactate, ethylene glycol monoethyl ether acetate, propylene glycol monomethyl ether acetate, 3-ethyl ethoxypropionate, ethyl pyruvate, 2-ethoxyethyl acetate, 2-(2-ethoxyethoxy)ethyl acetate, and propylene carbonate.

In the present invention, as the solvent, one kind may be used alone, or two or more kinds may be used in combination.

In the present invention, as the organic solvent, a mixed solvent in which a solvent having a hydroxyl group in a structure is mixed with a solvent having no hydroxyl group may be used.

Examples of the solvent having a hydroxyl group include ethylene glycol, ethylene glycol monomethyl ether, ethylene glycol monoethyl ether, propylene glycol, propylene glycol monomethyl ether, propylene glycol monoethyl ether, and ethyl lactate. Among these, propylene glycol monomethyl ether or ethyl lactate is preferable.

Examples of the solvent having no hydroxyl group include propylene glycol monomethyl ether acetate, ethyl ethoxypropionate, 2-heptanone, γ-butyrolactone, cyclohexanone, butyl acetate, N-methylpyrrolidone, N,N-dimethylacetamide, and dimethyl sulfoxide. Among these, propylene glycol monomethyl ether acetate, ethyl ethoxypropionate, 2-heptanone, γ-butyrolactone, cyclohexanone, or butyl acetate is more preferable, and propylene glycol monomethyl ether acetate, ethyl ethoxypropionate, 2-heptanone is most preferable.

A mixing ratio of the solvent having a hydroxyl group to the solvent having no hydroxyl group is preferably 1/99 to 99/1, more preferably 10/90 to 90/10, and still more preferably 20/80 to 60/40 by mass. In particular, a mixed solvent including 50 mass % or higher of the solvent having no hydroxyl group is preferable from the viewpoint of coating uniformity.

It is preferable that the solvent is a mixed solvent including two or more propylene glycol monomethyl ether acetates.

As the solvent, for example, a solvent described in paragraphs “0013” to “0029” of JP2014-219664A can also be used.

(E) Basic Compound

In order to reduce a change in performance with the lapse of time from exposure to heating, it is preferable that the actinic ray-sensitive or radiation-sensitive composition includes a basic compound (E).

Preferable examples of the basic compound include compounds having structures represented by the following Formulae (A) to (E).

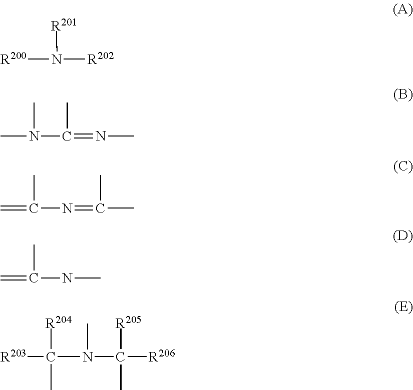

In Formulae (A) and (E), R²⁰⁰, R²⁰¹, and R²⁰² may be the same as or different from each other and each independently represent a hydrogen atom, an alkyl group (preferably having 1 to 20 carbon atoms), a cycloalkyl group (preferably having 3 to 20 carbon atoms), or an aryl group (preferably having 6 to 20 carbon atoms). Here, R²⁰¹ and R²⁰² may be bonded to each other to form a ring.

As the alkyl group having a substituent, an aminoalkyl group having 1 to 20 carbon atoms, a hydroxyalkyl group having 1 to 20 carbon atoms, or a cyanoalkyl group having 1 to 20 carbon atoms is preferable.

R²⁰³, R²⁰⁴, R²⁰⁵, and R²⁰⁶ may be the same as or different from each other and each independently represent an alkyl group having 1 to 20 carbon atoms.

It is more preferable that the alkyl group in the Formulae (A) and (E) is unsubstituted.

Examples of a preferable compound include guanidine, aminopyrrolidine, pyrazole, pyrazoline, piperazine, aminomorpholine, aminoalkylmorpholine, and piperidine. Examples of a more preferable compound include a compound having an imidazole structure, a diazabicyclo structure, an onium hydroxide structure, an onium carboxylate structure, a trialkylamine structure, an aniline structure, or a pyridine structure, an alkylamino derivative having a hydroxyl group and/or an ether bond, and an aniline derivative having a hydroxyl group and/or an ether bond.

Examples of the compound having an imidazole structure include imidazole, 2,4,5-triphenylimidazole, and benzimidazole. Examples of the compound having a diazabicyclo structure include 1,4-diazabicyclo[2,2,2]octane, 1,5-diazabicyclo[4,3,0]nona-5-ene, and 1,8-diazabicyclo[5,4,0]undeca-7-ene. As the compound having an onium hydroxide structure, for example, triarylsulfonium hydroxide, phenacyl sulfonium hydroxide, or sulfonium hydroxide having a 2-oxoalkyl group can be used, and specific examples thereof include triphenylsulfonium hydroxide, tris(t-butylphenyl)sulfonium hydroxide, bis(t-butylphenyl)iodonium hydroxide, phenacyl thiophenium hydroxide, and 2-oxopropylthiophenium hydroxide. As the compound having an onium carboxylate structure, for example, a compound obtained by carboxylation of the anion site of a compound having an omnium hydroxide structure can be used, and examples thereof include acetate, adamantane-1-carboxylate, and perfluoroalkyl carboxylate. Examples of the compound having trialkylamine structure include tri-(n-butyl)amine and tri-(n-octyl)amine. Examples of the compound having an aniline structure include 2,6-diisopropylaniline, N,N-dimethylaniline, N,N-dibutylaniline, and N,N-dihexylaniline. Examples of the alkylamino derivative having a hydroxyl group and/or an ether bond include ethanolamine, diethanolamine, triethanolamine, and tris(methoxyethoxyethyl)amine. Examples of the aniline derivative having a hydroxyl group and/or an ether bond include N,N-bis(hydroxyethyl)aniline.

Other preferable examples of the basic compound include an amine compound having a phenoxy group and an ammonium salt compound having a phenoxy group.

As the amine compound, a primary, secondary, or tertiary amine compound can be used, and an amine compound in which at least one alkyl group is bonded to a nitrogen atom is preferable. It is more preferable that the amine compound is a tertiary amine compound. In the amine compound, as long as at least one alkyl group (preferably having 1 to 20 carbon atoms) is bonded to a nitrogen atom, in addition to the alkyl group, a cycloalkyl group (preferably having 3 to 20 carbon atoms) or an aryl group (preferably 6 to 12 carbon atoms) may be bonded to a nitrogen atom.

In addition, it is preferable that the amine compound has an oxygen atom at an alkyl chain to form an oxyalkylene group. The number of oxyalkylene groups is 1 or more, preferably 3 to 9, and still more preferably 4 to 6 in a molecule. Among the oxyalkylene groups, an oxyethylene group (—CH₂CH₂O—) or an oxypropyl group (—CH(CH₃)CH₂O— or —CH₂CH₂CH₂O—) is preferable, and an oxyethylene group is more preferable.

As the ammonium salt compound, a primary, secondary, tertiary, or quaternary ammonium salt compound can be used, and an ammonium salt compound in which at least one alkyl group is bonded to a nitrogen atom is preferable. In the ammonium salt compound, as long as at least one alkyl group (preferably having 1 to 20 carbon atoms) is bonded to a nitrogen atom, in addition to the alkyl group, a cycloalkyl group (preferably having 3 to 20 carbon atoms) or an aryl group (preferably 6 to 12 carbon atoms) may be bonded to a nitrogen atom.

In addition, it is preferable that the ammonium salt compound has an oxygen atom at an alkyl chain to form an oxyalkylene group. The number of oxyalkylene groups is 1 or more, preferably 3 to 9, and still more preferably 4 to 6 in a molecule. Among the oxyalkylene groups, an oxyethylene group (—CH₂CH₂O—) or an oxypropyl group (—CH(CH₃)CH₂O— or —CH₂CH₂CH₂O—) is preferable, and an oxyethylene group is more preferable.

Examples of an anion of the ammonium salt compound include a halogen atom, a sulfonate, a borate, and a phosphate. Among these, a halogen atom or a sulfonate is preferable. As the halogen atom, a chloride, a bromide, or an iodide is preferable. As the sulfonate, an organic sulfonate having 1 to 20 carbon atoms is preferable. Examples of the organic sulfonate include an alkyl sulfonate having 1 to 20 carbon atoms and an aryl sulfonate. The alkyl group of the alkyl sulfonate may have a substituent, and examples of the substituent include fluorine, chlorine, bromine, an alkoxy group, an acyl group, and an aryl group. Specific examples of the alkyl sulfonate include methane sulfonate, ethane sulfonate, butane sulfonate, hexane sulfonate, octane sulfonate, benzyl sulfonate, trifluoromethane sulfonate, pentafluoromethane sulfonate, and nonafluoromethane sulfonate. Examples of the aryl group of the aryl sulfonate include a benzene ring, a naphthalene ring, and an anthracene ring. The benzene ring, the naphthalene ring, and the anthracene ring may have a substituent. As the substituent, a linear or branched alkyl group having 1 to 6 carbon atoms or a cycloalkyl group having 3 to 6 carbon atoms is preferable. Specific examples of the linear or branched alkyl group and the cycloalkyl group include methyl, ethyl, n-propyl, isopropyl, n-butyl, i-butyl, t-butyl, n-hexyl, and cyclohexyl. Other examples of the substituent include an alkoxy group having 1 to 6 carbon atoms, a halogen atom, cyano, nitro, an acyl group, and an acyloxy group.

The amine compound having a phenoxy group or the ammonium salt compound having a phenoxy group denotes an amine compound or an ammonium salt compound having a phenoxy group at a terminal of an alkyl group opposite to a nitrogen atom. The phenoxy group may have a substituent. Examples of the substituent of thee phenoxy group include an alkyl group, an alkoxy group, a halogen atom, a cyano group, a nitro group, a carboxyl group, a carboxylate group, a sulfonate group, an aryl group, an aralkyl group, an acyloxy group, and an aryloxy group. The substitution position of the substituent may be any one of the 2- to 6-position. The number of substituents is 1 to 5.

It is preferable that at least one oxyalkylene group is present between a phenoxy group and a nitrogen atom. The number of oxyalkylene groups is 1 or more, preferably 3 to 9, and still more preferably 4 to 6 in a molecule. Among the oxyalkylene groups, an oxyethylene group (—CH₂CH₂O—) or an oxypropyl group (—CH(CH₃)CH₂O— or —CH₂CH₂CH₂O—) is preferable, and an oxyethylene group is more preferable.

The amine compound having a phenoxy group can be obtained by heating a primary or secondary amine having a phenoxy group and haloalkyl ether to react with each other, adding an aqueous solution of a strong base such as sodium hydroxide, potassium hydroxide, or tetraalkylammonium to the obtained reaction product, and performing extraction with an organic solvent such as ethyl acetate or chloroform. Alternatively, the amine compound having a phenoxy group can be obtained by heating a primary or secondary amine and haloalkyl ether having a phenoxy group at a terminal to react with each other, adding an aqueous solution of a strong base such as sodium hydroxide, potassium hydroxide, or tetraalkylammonium to the obtained reaction product, and performing extraction with an organic solvent such as ethyl acetate or chloroform.

(Compound (PA) having Proton-accepting Functional Group which is decomposed to generate Compound in which Proton Accepting Properties deteriorate, disappear, or change to Acidic Properties when irradiated with Actinic Ray or Radiation) The composition according to the present invention may further include, as a basic compound, a compound (hereinafter, also referred to as “compound (PA)”) having a proton-accepting functional group which is decomposed to generate a compound in which proton accepting properties deteriorate, disappear, or change to acidic properties when irradiated with an actinic ray or radiation.

The proton-accepting functional group denotes a functional group having a group or an electron which can electrostatically interact with a proton, for example, a functional group which has a macrocyclic structure such as cyclic polyether or a functional group which has a nitrogen atom having an unshared electron pair not contributing to r-conjugation. Examples of the nitrogen atom having an unshared electron pair not contributing to π-conjugation include a nitrogen atom having a partial structure represented by the following formula.

Preferable examples of a partial structure of the proton-accepting functional group include crown ether, azacrown ether, primary to tertiary amine, pyridine, imidazole, and a pyrazine structure.

The compound (PA) is decomposed to generate a compound in which proton accepting properties deteriorate, disappear, or change to acidic properties when irradiated with an actinic ray or radiation. Here, proton accepting properties deteriorating, disappearing, or changing to acidic properties represents a change in proton accepting properties caused by adding a proton to the proton-accepting functional group, and specifically represents that, when a proton adduct is generated using the compound (PA) having a proton-accepting functional group and a proton, an equilibrium constant in the equilibrium constant is reduced.

Specific examples of the compound (PA) include the following compounds. Further, specific examples of the compound (PA) include compounds described in paragraphs “0421” to “0428” of JP2014-41328A and paragraphs “0108” to “0116” of JP2014-134686A, the content of which is incorporated herein by reference.

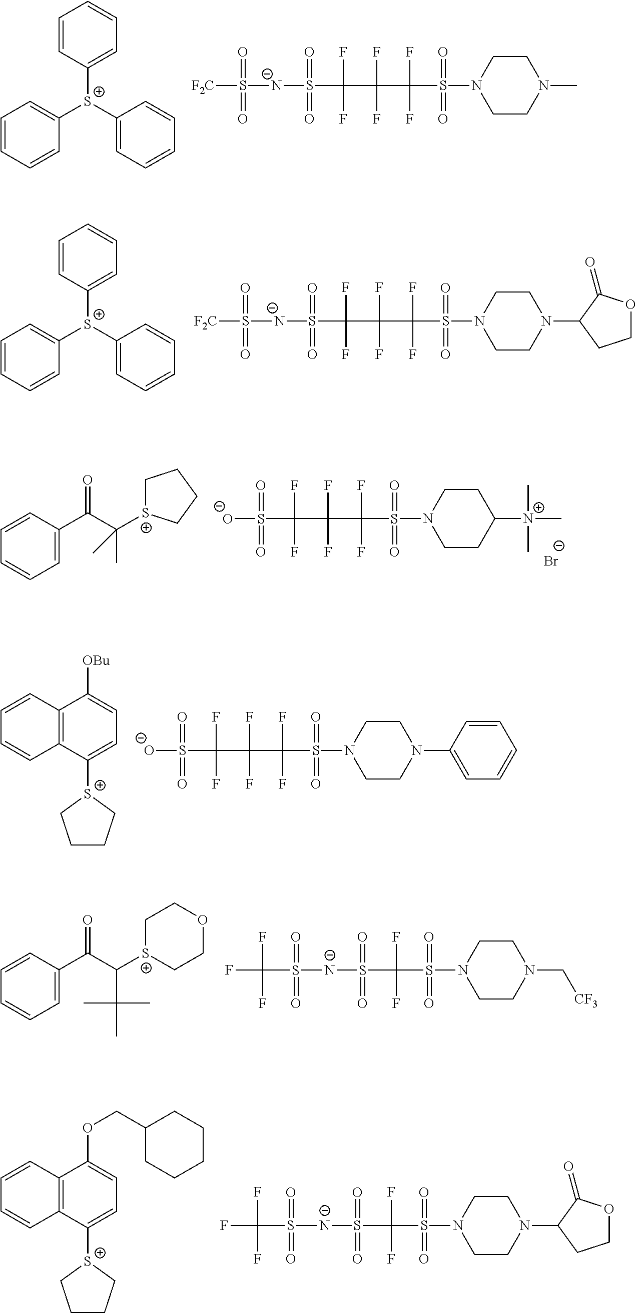

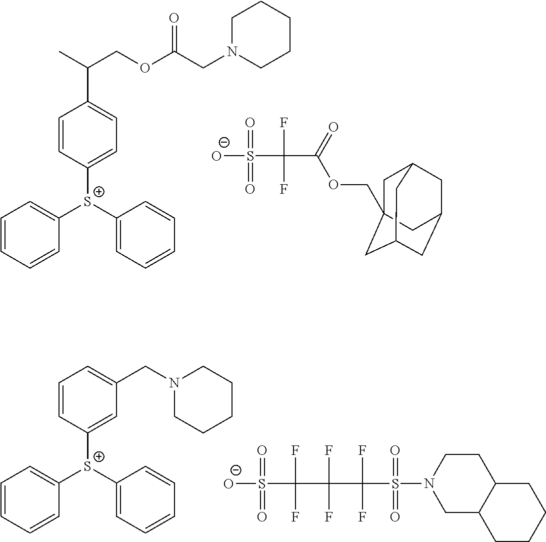 [SMILES: CC(COC(=O)CN1CCCCC1)c1ccc([S+](c2ccccc2)c2ccccc2)cc1 ; O=C(OCC12CC3CC(CC(C3)C1)C2)C(F)(F)S(=O)(=O)[O-] ; c1ccc([S+](c2ccccc2)c2cccc(CN3CCCCC3)c2)cc1 ; O=S(=O)([O-])C(F)(F)C(F)(F)C(F)(F)S(=O)(=O)N1CCC2CCCCC2C1]

Among the basic compounds, one kind may be used alone, or two or more kinds may be used in combination.

The amount of the basic compound used is typically 0.001 to 10 mass % and preferably 0.01 to 5 mass % with respect to the solid content of the actinic ray-sensitive or radiation-sensitive composition.

It is preferable that a ratio (molar ratio; photoacid generator/basic compound) of the photoacid generator used to the basic compound used in the composition is 2.5 to 300. That is, the molar ratio is preferably 2.5 or higher from the viewpoints of sensitivity and resolution, and is preferably 300 or lower from the viewpoint of suppressing deterioration in resolution caused by thickening of a resist pattern with the lapse of time until a heating treatment after exposure. The molar ratio (photoacid generator/basic compound) is more preferably 5.0 to 200 and still more preferably 7.0 to 150.

As the basic compound, for example, a compound (for example, an amine compound, an amido group-containing compound, a urea compound, or a nitrogen-containing heterocyclic compound) described in paragraphs “0140” to “0144” of JP2013-11833A can be used.

(E) Hydrophobic Resin

The actinic ray-sensitive or radiation-sensitive composition may include a hydrophobic resin (E) in addition to the resin (A).

It is preferable that the hydrophobic resin is designed to be localized on a surface of a resist film. Unlike the surfactant, the hydrophobic resin does not necessarily have a hydrophilic group in a molecule and does not necessarily contribute to uniform mixing with a polar/non-polar material.

Examples of an effect obtained by the addition of the hydrophobic resin include an effect of suppressing a static/dynamic contact angle of a resist film surface with respect to water and an effect of suppressing out gas.

From the viewpoint of localization on the film surface layer, the hydrophobic resin includes preferably one or more kinds and more preferably two or more kinds among “a fluorine atom”, “a silicon atom”, and “a CH₃ partial structure included in a side chain of the resin”. In addition, it is preferable that the hydrophobic resin includes a hydrocarbon group having 5 or more carbon atoms. These groups may be present at a main chain or a side chain of the resin.

In a case where the hydrophobic resin includes a fluorine atom and/or a silicon atom, the fluorine atom and/or the silicon atom in the hydrophobic resin may be present at a main chain or a side chain of the resin.

In a case where the hydrophobic resin includes a fluorine atom, it is preferable that a partial structure having a fluorine atom is an alkyl group having a fluorine atom, a cycloalkyl group having a fluorine atom, or an aryl group having a fluorine atom.

The alkyl group having a fluorine atom (preferably having 1 to 10 carbon atoms and more preferably having 1 to 4 carbon atoms) is a linear or branched alkyl group in which at least one hydrogen atom is substituted with a fluorine atom and may further have a substituent other than a fluorine atom.

The cycloalkyl group having a fluorine atom is a monocyclic or polycyclic cycloalkyl group in which at least one hydrogen atom is substituted with a fluorine atom and may further have a substituent other than a fluorine atom.

Examples of the aryl group having a fluorine atom include an aryl group, such as a phenyl group or a naphthyl group, in which at least one hydrogen atom is substituted with a fluorine atom. The aryl group having a fluorine atom may further have a substituent other than a fluorine atom.

Examples of a repeating unit having a fluorine atom or a silicon atom include a repeating unit described in paragraph “0519” of US2012/0251948A1.

In addition, as described above, it is preferable that the hydrophobic resin includes a CH₃ partial structure at a side chain.

Here, examples of the CH₃ partial structure included at a side chain of the hydrophobic resin include a CH₃ partial structure such as an ethyl group or a propyl group.

On the other hand, a methyl group (for example, an α-methyl group of a repeating unit having a methacrylic acid group) which is directly bonded to a main chain of the hydrophobic resin has little contribution to the surface localization of the hydrophobic resin caused by the effect of the main chain, and thus is not included in examples of the CH₃ partial structure according to the present invention.

The details of the hydrophobic resin can be found in paragraphs “0348” to “0415” of JP2014-010245A, the content of which is incorporated herein by reference.

As the hydrophobic resin, resins described in JP2011-248019A, JP2010-175859A, and JP2012-032544A can also be preferably used.

In the pattern forming method according to the present invention, after forming a resist film on a substrate using the actinic ray-sensitive or radiation-sensitive composition, a top coat layer may be formed on the resist film, for example, using a top coat composition including the hydrophobic resin. The thickness of the resist film is preferably 10 to 100 nm, and the thickness of the top coat layer is preferably 10 to 200 nm, more preferably 20 to 100 nm, and still more preferably 40 to 80 nm.

As a method of applying the actinic ray-sensitive or radiation-sensitive composition to the substrate, spin coating method is preferable. In this case, the rotation speed is preferably 1000 to 3000 rpm.

For example, the actinic ray-sensitive or radiation-sensitive composition is applied to the substrate (for example, a silicon-silicon dioxide coating), which is used for manufacturing a precision integrated circuit element, using an appropriate coating method such as a method using a spinner, a coater, or the like and then is dried. As a result, a resist film is formed. A well-known antireflection film may be formed in advance. In addition, it is preferable that the resist film is dried before forming the top coat layer.

Next, the top coat composition is applied to the obtained resist film and dried using the same means as that in the method of forming the resist film. As a result, the top coat layer can be formed.

The resist film on which the top coat layer is formed is typically irradiated with an electron beam (EB), an X-ray, or an EUV ray through a mask and is preferably baked (heated) for development. As a result, a satisfactory pattern can be obtained.

(F) Surfactant

The actinic ray-sensitive or radiation-sensitive composition may further include a surfactant (F). By the actinic ray-sensitive or radiation-sensitive composition including the surfactant, particularly in a case where an exposure light source having a wavelength of 250 nm or shorter, in particular, 220 nm or shorter is used, a pattern having adhesiveness and reduced development defects can be formed with high sensitivity and resolution.

As the surfactant, a fluorine surfactant and/or a silicon surfactant is preferably used.

Examples of the fluorine surfactant and/or the silicon surfactant include surfactants described in paragraph “0276” of US2008/0248425A. In addition, F-TOP EF301 or EF303 (manufactured by Shin-akita Chemical Co., Ltd.); FLUORAD FC430, 431 or 4430 (manufactured by Sumitomo 3M Ltd.); MEGAFACE F171, F173, F176, F189, F113, F110, F177, F120, or R08 (manufactured by DIC Corporation); SURFLON S-382, SC101, 102, 103, 104, 105, or 106 (manufactured by Asahi Glass Co., Ltd.); TROYSOL S-366 (manufactured by Troy Corporation); GF-300 or GF-150 (manufactured by Toagosei Co., Ltd.); SURFLON S-393 (manufactured by AGC Seimi Chemical Co., Ltd.); F-TOP EF121, EF122A, EF122B, RF122C, EF125M, EF135M, EF351, EF352, EF801, EF802, or EF601 (manufactured by Gemco Inc.); PF636, PF656, PF6320, or PF6520 (manufactured by OMNOVA Corp.); or FTX-204G, 208G, 218G, 230G, 204D, 208D, 212D, 218D, or 222D (manufactured by Neos Co., Ltd.) may be used. A polysiloxane polymer KP-341 (manufactured by Shin-Etsu Chemical Co., Ltd.) can also be used as the silicon surfactant.

In addition, in addition to the above-described surfactants, a surfactant may be synthesized using a fluoro aliphatic compound manufactured using a telomerization method (also referred to as a telomer method) or an oligomerization method (also referred to as an oligomer method). Specifically, a polymer including a fluoro aliphatic group derived from fluoro aliphatic compound may be used as the surfactant. This fluoro aliphatic compound can be synthesized, for example, using a method described in JP2002-90991A. In addition, a surfactant other than a fluorine surfactant and/or a silicon surfactant which is described in paragraph “0280” of US2008/0248425A may be used.

Among these surfactants, one kind may be used alone, or two or more kinds may be used in combination.

In a case where the actinic ray-sensitive or radiation-sensitive composition includes the surfactant, the content of the surfactant is preferably 0 to 2 mass %, more preferably 0.0001 to 2 mass %, and still more preferably 0.0005 to 1 mass % with respect to the total solid content of the composition.

(G) Other Additives

The actinic ray-sensitive or radiation-sensitive composition may further include a dissolution inhibiting compound, a dye, a plasticizer, a photosensitizer, a light absorber, and/or a compound for promoting solubility in the developer (for example, a phenol compound having a molecular weight of 1000 or lower, or an aliphatic or alicyclic compound having a carboxy group).

The actinic ray-sensitive or radiation-sensitive composition may further include a dissolution inhibiting compound.

Here, “dissolution inhibiting compound” denotes a compound having a molecular weight of 3000 or lower which is decomposed by the action of an acid such that the solubility in the organic developer decreases.

[Allowable Content of Impurities]

It is preferable that the actinic ray-sensitive or radiation-sensitive composition and various materials (for example, the treatment liquid (the developer, the rinsing liquid) according to the present invention, a resist solvent, a composition for forming an antireflection film, a composition for forming a top coat) used in the pattern forming method according to the present invention do not include impurities such as metal, a metal salt including halogen, an acid, or alkali. The content of the impurities in the materials is preferably 1 ppm or lower, more preferably 1 ppb or lower, still more preferably 100 ppt or lower, and even still more preferably 10 ppt or lower, and it is most preferable that the materials do not substantially include the impurities (the measured value is lower than a detection limit value of a measuring device).

Examples of a method of removing impurities from the various materials include filtration using a filter. The pore size of the filter is preferably 10 nm or less, more preferably 5 nm or less, and still more preferably 3 nm or less. As a material of the filter, polytetrafluoroethylene, polyethylene, or nylon is preferable. The filter may be formed of a composite material including a combination of various materials and an ion exchange medium. The filter may be washed with an organic solvent in advance. In a filter filtration step, plural kinds of filters may be connected in series or in parallel. In a case where plural kinds of filters are used, filters having different pore sizes and/or formed of different materials may be used in combination. In addition, various materials may be filtered multiple times, and a step of filtering various materials multiple times may be a cycle filtration step.

In addition, examples of a method of reducing impurities such as metal from the various materials include a method of performing distillation under conditions where contamination is reduced as much as possible, for example, by selecting materials having a low metal content as raw materials constituting the various materials, filtering raw materials constituting the various materials through a filter, or lining the inside of a device with TEFLON (registered trade name). Preferable conditions for the filtration of filtering raw materials constituting the various materials through a filter are the same as the above-described conditions.

Impurities may be removed using an absorbent instead of filtration using a filter, or filtration using a filter and the method using an absorbent may be used in combination. As the absorbent, a well-known absorbent can be used, and examples thereof include an inorganic absorbent such as silica or zeolite, and an organic absorbent such as activated carbon.

[Storage Container of Treatment Liquid]

It is preferable that the treatment liquid according to the present invention such as the developer or the rinsing liquid is stored in a storage container for a treatment liquid for patterning a chemically amplified resist film, the storage container including a storage portion. For example, it is preferable that the storage container is a storage container for a treatment liquid for patterning a chemically amplified resist film in which an inner wall of the storage portion in contact with the treatment liquid is formed of a resin other than a polyethylene resin, a polypropylene resin, and a polyethylene-polypropylene resin or is formed of a metal which is treated to inhibit rust and to prevent metal elution. In the storage portion of the storage container, a predetermined organic solvent to be used as a treatment liquid for patterning a chemically amplified resist film is stored. During the patterning of the chemically amplified resist film, this organic solvent is discharged from the storage portion and used.

In a case where the storage container further includes a seal portion that seals the storage portion, it is preferable that the seal portion is formed of a resin other than one or more resins selected from the group consisting of a polyethylene resin, a polypropylene resin, and a polyethylene-polypropylene resin or is formed of a metal which is treated to inhibit rust and to prevent metal elution.

Here, the seal portion denotes a member that can isolate the storage portion from outside air, and preferable examples thereof include a packing and an O-ring.

It is preferable that the resin other than one or more resins selected from the group consisting of a polyethylene resin, a polypropylene resin is a perfluororesin.

Examples of the perfluororesin include a polytetrafluoroethylene resin (PTFE), a polytetrafluoroethylene-perfluoroalkyl vinyl ether copolymer resin (PFA), a polytetrafluoroethylene-hexafluoropropylene copolymer resin (FEP), a polytetrafluoroethylene-ethylene copolymer resin (ETFE), a polychlorotrifluoroethylene-ethylene copolymer resin (ECTFE), a vinylidene fluoride resin (PVDF), a polychlorotrifluoroethylene copolymer resin (PCTFE), and a vinyl fluoride resin (PVF).

Preferable examples of the perfluororesin include a polytetrafluoroethylene resin, a polytetrafluoroethylene-perfluoroalkyl vinyl ether copolymer resin, and a polytetrafluoroethylene-hexafluoropropylene copolymer resin.

Examples of the metal which is treated to inhibit rust and to prevent metal elution include carbon steel, alloy steel, nickel-chromium steel, nickel-chromium-molybdenum steel, chromium steel, chromium-molybdenum steel, and manganese steel.

As the treatment for inhibiting rust and preventing metal elution, coating techniques are preferably used.

The coating techniques are roughly classified into three kinds: metal coating (various kinds of plating); inorganic coating (for example, various kinds of chemical conversion coating, glass coating, concrete coating, or ceramic coating); and organic coating (rust-preventing oil coating, paint coating, rubber coating, or plastic coating).

Preferable examples of the coating technique include a surface treatment using rust-preventing oil, a rust-preventing agent, a corrosion inhibitor, a chelate compound, a strippable plastic, or a lining agent.

Among these, a corrosion inhibitor such as various chromates, a nitrite, a silicate, a phosphate, a carboxylic acid (for example, oleic acid, dimer acid, or naphthenic acid), a metal soap of a carboxylic acid, a sulfonate, an amine salt, or an ester (a glycerin ester or a phosphoric acid ester of higher fatty acid); a chelate compound such as ethylenediaminetetraacetic acid, gluconic acid, nitrilotriacetic acid, hydroxyethyl ethylenediaminetriacetic acid, or diethylenetriamine pentaacetic acid; or a fluororesin lining is preferable. A phosphate treatment or a fluororesin lining is more preferable.

In addition, as a treatment method which extends a period in which rust is inhibited by a coating treatment, “pre-treatment” which is performed before a rust inhibiting treatment is also preferably adopted performed although this pre-treatment does not directly inhibit rust unlike a direct coating treatment.

Preferable specific examples of the pre-treatment include a treatment of removing various corrosive factors such as a chloride or a sulfate present on a metal surface by washing or polishing.

Specific examples of the storage container are as follows.

FluoroPurePFA composite drum (manufactured by Entegris, Inc.; inner surface in contact with liquid: PFA resin lining)
Steel drum can (manufactured by JFE Steel Corporation; inner surface in contact with liquid: zinc phosphate coating)

In addition, examples of the storage container include a storage container described in paragraphs “0013” to “0030” of JP1999-021393A (JP-H11-021393A) and a storage container described in paragraphs “0012” to “0024” of JP1998-45961A (JP-H10-45961A).

A conductive compound may be added to the treatment liquid according to the present invention in order to prevent electrostatic charge and to prevent a chemical pipe or various parts (for example, a filter, an O-ring, or a tube) from being damaged by electric discharge accompanied by electrostatic charge. The conductive compound is not particularly limited, and examples thereof include methanol. The addition amount is not particularly limited, and is preferably 10 mass % or lower and more preferably 5 mass % or lower from the viewpoint of maintaining preferable developing properties. Regarding the member of the chemical pipe, stainless steel (SUS) or pipes coated with polyethylene which is treated to be antistatic, polypropylene, or a fluororesin (for example, polytetrafluoroethylene or a perfluoroalkoxy resin) can be used. Regarding the filter or the O-ring, similarly, Regarding a member of the chemical pipe, polyethylene which is treated to be antistatic, polypropylene, or a fluororesin (for example, polytetrafluoroethylene or a perfluoroalkoxy resin) can be used.

### EXAMPLES

Hereinafter, the present invention will be described in more detail using examples. However, the present invention is not limited to the following examples as long as it does not depart from the scope of the present invention. Unless specified otherwise, “part(s)” represents “part(s) by mass”.

The quantities of metal salts including alkali or halogen in a treatment liquid (treatment liquid shown in Table 5) used for developing or rinsing in a subsequent step are determined. As a result, it was found that the treatment liquid included substantially no metal salts including alkali or halogen.

1. EUV Exposure (Examples 1 to 18 and Comparative Examples 1 and 2)

<Resin (A) and the Like>

### (Synthesis Example 1) Synthesis of Resin (A-1)

600 g of cyclohexanone was put into a 2 L flask, and nitrogen purge was performed at a flow rate of 100 mL/min. Next, 4.60 g (0.02 mol) of a polymerization initiator V-601 (manufactured by Wako Pure Chemical Industries, Ltd.) was put into the flask, and the flask was heated until the internal temperature reached 80° C. Next, the following monomer and 4.60 g (0.02 mol) of the polymerization initiator V-601 (manufactured by Wako Pure Chemical Industries, Ltd.) were dissolved in 200 g of cyclohexanone to prepare a monomer solution. The monomer solution was added dropwise to the flask heated to 80° C. for 6 hours. After completion of the dropwise addition, a reaction was performed at 80° C. for 2 hours.

4-acetoxystyrene: 48.66 g (0.3 mol)

1-ethylcyclopentyl methacrylate: 109.4 g (0.6 mol)

Monomer 1: 22.2 g (0.1 mol)

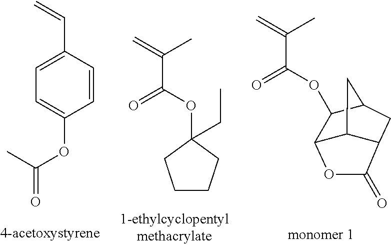

The reaction solution was cooled to room temperature and was added dropwise to 3 L of hexane to precipitate a polymer. The solid obtained by filtration was dissolved in 500 mL of acetone, and the acetone solution was added dropwise again to 3 L of hexane to precipitate a polymer. The solid obtained by filtration was dried under reduced pressure. As a result, 160 g of a 4-acetoxystyrene/1-ethylcyclopentyl methacrylate/monomer 1 copolymer (A-la) was obtained.

10 g of the copolymer (A-la) obtained as described above, 40 mL of methanol, 200 mL of 1-methoxy-2-propanol, and 1.5 mL of concentrated hydrochloric acid were added to a reaction vessel, were heated to 80° C., and were stirred for 5 hours. The reaction solution was allowed to cool to room temperature and was added dropwise to 3 L of distilled water to precipitate a polymer. The solid obtained by filtration was dissolved in 200 mL of acetone, and the acetone solution was added dropwise again to 3 L of distilled water to precipitate a polymer. The solid obtained by filtration was dried under reduced pressure. As a result, a resin (A-1) (8.5 g) was obtained. When measured by gel permeation chromatography (GPC; solvent: tetrahydrofuran (THF)) in terms of standard polystyrene, the weight-average molecular weight (Mw) was 11200, and the dispersity (Mw/Mn) was 1.45.

Resins (A-2) to (A-7) having a structure shown in Table 3 were synthesized using the same method as in Synthesis Example 1, except that the monomer used was changed.

In Table 3, a composition ratio (molar ratio) of the resin was calculated by ¹H-nuclear magnetic resonance (NMR). The weight-average molecular weight of the resin (Mw: in terms of polystyrene) and the dispersity (Mw/Mn) were calculated by GPC (solvent: THF).

TABLE 3

| | | Composition Ratio | | |
|---|---|---|---|---|
| | | (Molar Ratio), | | Mw/ |
| | Structure | From Left | Mw | Mn |
| Resin A-1 | 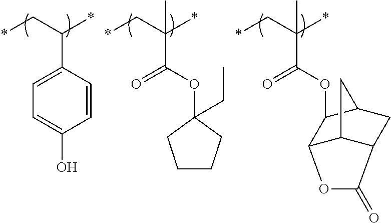 | 30/60/10 | 11,200 | 1.45 |
| Resin A-2 | 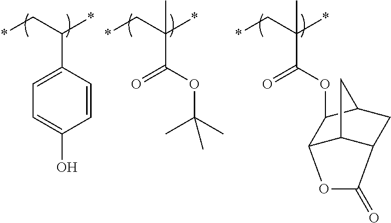 | 30/60/10 | 12,300 | 1.51 |
| Resin A-3 | 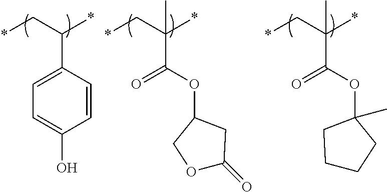 | 40/20/40 | 9,200 | 1.68 |
| Resin A-4 | 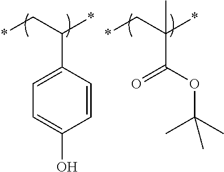 | 20/80 | 12,500 | 1.52 |
| Resin A-5 | 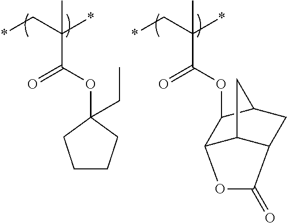 | 50/50 | 13,000 | 1.56 |
| Resin A-6 | 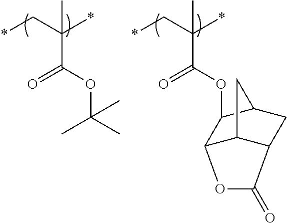 | 70/30 | 12,500 | 1.43 |
| Resin A-7 | 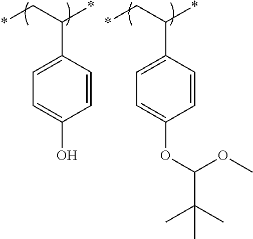 | 20/80 | 18,000 | 1.12 |

<Photoacid Generator (B)>

As a photoacid generator, one of the following compounds was used.

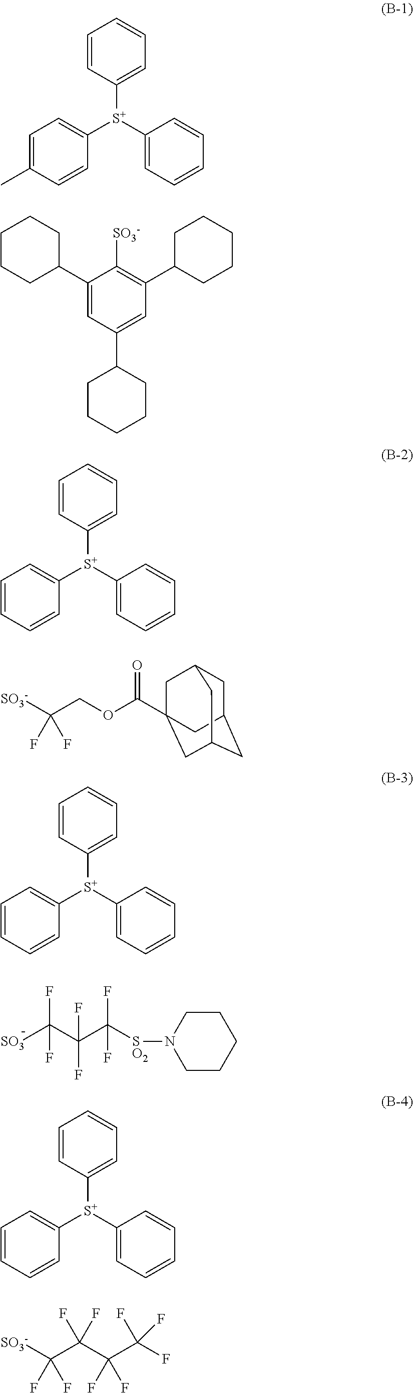

<Basic Compound (E)>

As a basic compound, one of the following compounds was used.

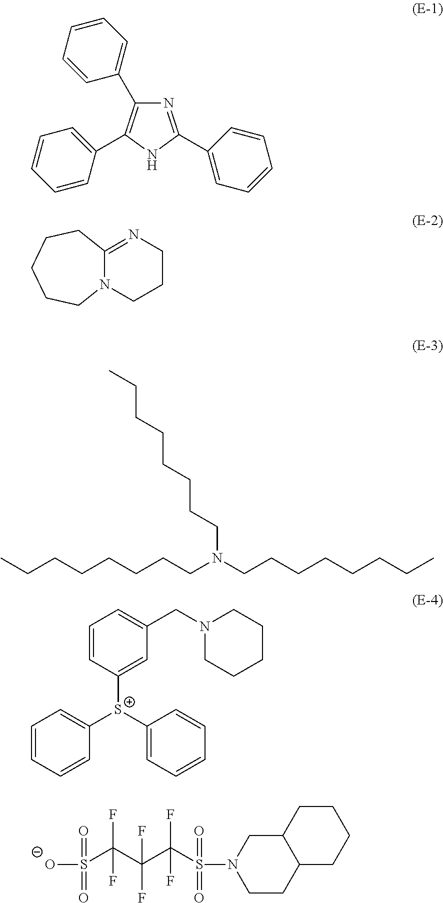

<Solvent (C)>

As a resist solvent, one of the following compounds was used.

C-1: propylene glycol monomethyl ether acetate

C-2: propylene glycol

C-3: ethyl lactate

C-4: cyclohexanone

<Resist Composition>

Respective components shown in Table 4 below were dissolved in a solvent shown in Table 4. The obtained solution was filtered through a polyethylene filter having a pore size of 0.03 μm to obtain a resist composition.

TABLE 4

| | | Photoacid | Basic | | |
|---|---|---|---|---|---|
| | Resin | Generator | Compound | | |
| | (A) | (B) | (E) | Solvent (C) | |
| Resist Composition 1 | A-1 | B-1 | E-3 | C-1 | C-3 |
| | 0.77 g | 0.2 g | 0.03 g | 67.5 g | 7.5 g |
| Resist Composition 2 | A-2 | B-2 | E-1 | C-1 | C-2 |
| | 0.79 g | 0.18 g | 0.03 g | 45 g | 30 g |
| Resist Composition 3 | A-3 | B-3 | E-2 | C-1 | C-4 |
| | 0.8 g | 0.19 g | 0.01 g | 67.5 g | 7.5 g |
| Resist Composition 4 | A-4 | B-2 | E-1 | C-1 | C-3 |
| | 0.79 g | 0.18 g | 0.03 g | 60 g | 15 g |
| Resist Composition 5 | A-5 | B-3 | E-3 | C-1 | C-3 |
| | 0.78 g | 0.19 g | 0.03 g | 67.5 g | 7.5 g |
| Resist Composition 6 | A-6 | B-2 | E-1 | C-1 | C-3 |
| | 0.79 g | 0.18 g | 0.03 g | 67.5 g | 7.5 g |
| Resist Composition 7 | A-7 | B-4 | E-4 | C-1 | C-4 |
| | 0.79 g | 0.2 g | 0.01 g | 45 g | 30 g |

<EUV Exposure Evaluation>

Using each of the resist compositions shown in Table 4, a resist pattern was formed through the following operation.

[Application of Resist Composition and Baking (PB) after Application] Each of the resist compositions obtained as described above was applied to a 4-inch silicon wafer treated with hexamethyldisilazane (HMDS), was baked under a condition of 90° C. to 120° C. for 60 seconds. As a result, a resist film having a thickness of 40 nm was formed.

[Exposure]

Using an EUV exposure device, the wafer on which the resist film was formed was exposed to EUV under conditions of a numerical aperture (NA) of 0.3 and dipole illumination. Specifically, the EUV exposure was performed through a mask including a pattern for forming a line-and-space pattern having a size of 15 to 45 nm while changing the exposure dose.

[Post Exposure Baking (PEB)]

After the exposure, the wafer was taken out from the EUV exposure device, and then immediately the wafer was baked under a condition of 80° C. to 140° C. for 60 seconds.

[Development]

Next, using a shower type developing device (ADE3000S, manufactured by ActesKyosan Inc.), a developer (23° C.) shown in Table 5 was sprayed on the wafer for development at a flow rate of 200 mL/min for a predetermined time while rotating the wafer at 50 rpm. S-1, S-2, S-5, S-6, or S-9 shown in Table 5 were used as the developer. In Table 5, a numerical value in “Major Component” denotes a mixing ratio by mol.

In Table 5, the amount of impurities in each of the developers/the rinsing liquids was adjusted by distilling and/or filtering raw materials.

The content of the sulfur-containing compound in each of the treatment liquids was measured using a method defined in JIS K 2541-6:2013 “Determination of Sulfur Content (Ultraviolet Fluorescence Method)”.

In addition, the content of the compound containing a phosphorus atom in each of the treatment liquids was determined as the total phosphorus content by absorption photometry based on a method defined in JIS K 0102:2013.

TABLE 5

| Developer/ | | Impurity (Sulfur-Containing | | Impurity (Phosphorus-Containing | |
|---|---|---|---|---|---|
| Rinsing | | Compound) | | Compound) | |
| Liquid | Major Component | Kind | Content | Kind | Content |
| S-1 | Butyl Acetate | Substantially Not | Determination | Substantially | Determination or |
| | | Included | or Lower | Not Included | Lower |
| S-2 | Isoamyl Acetate | Substantially Not | Determination | Substantially | Determination or |
| | (3-Methylbutyl Acetate) | Included | or Lower | Not Included | Lower |
| S-3 | Decane | Dibenzothiophene | 0.5 mmol/L | Substantially | Determination or |
| | | | | Not Included | Lower |
| S-4 | Undecane | Benzothiophene | 1 mmol/L | Substantially | Determination or |
| | | | | Not Included | Lower |
| S-5 | Butyl Acetate/Decane = 80/20 | Dimethyl Sulfide | 0.05 mmol/L | Substantially | Determination or |
| | | | | Not Included | Lower |
| S-6 | Isoamyl Acetate/Undecane = 90/10 | Benzothiophene | 0.05 mmol/L | Substantially | Determination or |
| | | | | Not Included | Lower |
| S-7 | Butyl Acetate/Decane = 20/80 | Ethylmercaptan | 5 mmol/L | Substantially | Determination or |
| | | | | Not Included | Lower |
| S-8 | Isoamyl Acetate/Undecane = 20/80 | Dibenzothiophene | 8 mmol/L | Substantially | Determination or |
| | | | | Not Included | Lower |
| S-9 | Butyl Acetate | Substantially Not | Determination | Phosphorus | 5 mmol/L |
| | | Included | or Lower | Acid | |
| S-10 | Undecane/Decane = 80/20 | Dibenzothiophene | 3 mmol/L | Substantially | Determination or |
| | | | | Not Included | Lower |
| S-11 | Undecane/Decane = 20/80 | Benzothiophene | 0.1 mmol/L | Substantially | Determination or |
| | | | | Not Included | Lower |
| S-12 | 2,2,4,6,6-Pentamethylheptane | Benzothiophene | 0.03 mmo1/L | Substantially | Determination or |
| | | | | Not Included | Lower |
| S-13 | Dodecane | Dimethyl Sulfide | 0.01 mmol/L | Substantially | Determination or |
| | | | | Not Included | Lower |
| SA-1 | Dodecane | Benzothiophene | 20 mmo1/L | Substantially | Determination or |
| | | | | Not Included | Lower |
| SA-2 | Dodecane | Dibenzothiophene | 100 mmol/L | Substantially | Determination or |
| | | | | Not Included | Lower |

[Rinsing]

Next, a rinsing liquid (23° C.) shown in Table 5 was sprayed on the wafer for rinsing at a flow rate of 200 mL/min for a predetermined time while rotating the wafer at 50 rpm.

Finally, the wafer was dried while rotating the wafer at a high speed of 2500 rpm for 60 seconds. In Table 5, S-3, S-4, S-7, S-8, S-10 to S-13, SA-1, or SA-2 was used as the rinsing liquid.

[Evaluation Test]

Regarding the following items, the resist pattern was evaluated. The details of the results are shown in Table 6.

(Sensitivity)

The obtained resist pattern was observed with a scanning electron microscope (S-9380II, manufactured by Hitachi, Ltd.). An irradiation energy at which lines and spaces were separately resolved at a ratio of 1:1 at a line width of 30 nm was set as a sensitivity (mJ/cm²).

(Limit Resolution)

A resolution state at 45 nm to 15 nm was observed with a scanning electron microscope (S-9380II, manufactured by Hitachi, Ltd.), and a value at which a 1:1 line-and-space pattern was resolved without any problems was set as a value of limit resolution.

(Residue Defect)

The resolution state at a line width of 30 nm obtained using the above-described method and a pattern shape were observed with a scanning electron microscope (S-9380II, manufactured by Hitachi, Ltd.) to obtain the number of residue defects. While shifting a position to be measured one micron by one micron, 1000 images were obtained to count the number of residue defects observed on the pattern. The less the number of residue defects, the higher the performance.

(Relationship between Evaluation Results and Number of Residue Defects in Table)

A: 0

B: 1 to 4

C: 5 to 9

D: 10 to 19

E: 20 or more

TABLE 6

| | | PB | PEB | | | 30 nm Sensitivity | Limit | Residue |
|---|---|---|---|---|---|---|---|---|
| | | (60 Seconds) | (60 Seconds) | Development | Rinsing | [mJ/cm²] | Resolution (nm) | Defects |
| Example 1 | Resist Composition 1 | 120° C. | 100° C. | S-1 | — | 22 | 23 | A |
| Example 2 | Resist Composition 2 | 110° C. | 110° C. | S-2 | S-3 | 30 | 19 | A |
| Example 3 | Resist Composition 3 | 100° C. | 110° C. | S-5 | S-4 | 45 | 23 | A |
| Example 4 | Resist Composition 4 | 90° C. | 110° C. | S-6 | S-7 | 41 | 23 | C |
| Example 5 | Resist Composition 5 | 130° C. | 110° C. | S-1 | S-8 | 35 | 17 | C |
| Example 6 | Resist Composition 6 | 120° C. | 120° C. | S-2 | — | 30 | 22 | A |
| Example 7 | Resist Composition 7 | 110° C. | 80° C. | S-5 | S-3 | 36 | 18 | A |
| Example 8 | Resist Composition 1 | 100° C. | 110° C. | S-6 | S-4 | 32 | 24 | A |
| Example 9 | Resist Composition 2 | 90° C. | 110° C. | S-1 | S-7 | 46 | 22 | C |
| Example 10 | Resist Composition 3 | 130° C. | 90° C. | S-2 | S-8 | 42 | 19 | C |
| Example 11 | Resist Composition 4 | 120° C. | 110° C. | S-1 | S-3 | 24 | 22 | A |
| Example 12 | Resist Composition 5 | 110° C. | 110° C. | S-2 | S-4 | 24 | 21 | A |
| Example 13 | Resist Composition 6 | 100° C. | 110° C. | S-5 | S-7 | 36 | 22 | C |
| Example 14 | Resist Composition 7 | 90° C. | 110° C. | S-9 | S-3 | 39 | 25 | C |
| Example 15 | Resist Composition 2 | 90° C. | 110° C. | S-2 | S-10 | 43 | 20 | C |
| Example 16 | Resist Composition 2 | 100° C. | 110° C. | S-2 | S-11 | 28 | 23 | A |
| Example 17 | Resist Composition 2 | 100° C. | 110° C. | S-2 | S-12 | 29 | 21 | A |
| Example 18 | Resist Composition 2 | 100° C. | 110° C. | S-2 | S-13 | 31 | 19 | A |
| Comparative Example 1 | Resist Composition 1 | 120° C. | 130° C. | S-1 | SA-1 | 60 | 30 | D |
| Comparative Example 2 | Resist Composition 1 | 120° C. | 140° C. | S-1 | SA-2 | 50 | 30 | E |

2. EB Exposure (Examples to 19 to 36 and Comparative Examples 3 and 4)

<EB Exposure Evaluation>

Using each of the resist compositions shown in Table 4, a resist pattern was formed through the following operation.

[Application of Resist Composition and Baking after Application]

A composition DUV44 (manufactured by Brewer Science, Inc.) for forming an organic film was applied to a 6-inch silicon wafer and was baked at 200° C. for 60 seconds. As a result, an organic film having a thickness of 60 nm was formed. A resist composition shown in Table 7 was applied to the organic film and was baked under a condition of 90° C. to 120° C. for 60 seconds. As a result, a resist film having a thickness of 40 nm was formed.

[Exposure]

Using an electron beam irradiating device (JBX6000FS/E, manufactured by JEOL Ltd.; acceleration voltage: 50 keV), the wafer on which the resist film was formed was exposed to EB to form a line-and-space pattern having a size of 20 nm to 17.5 nm (0.12 mm in the length direction; number of lines drawn: 20) at an interval of 1.25 nm while changing the exposure dose.

[Post Exposure Baking]

After the exposure, the wafer was taken out from the electron beam irradiating device, and then immediately the wafer was heated using a hot plate under a condition of 80° C. to 140° C. for 60 seconds.

[Development]

Using a shower type developing device (ADE3000S, manufactured by ActesKyosan Inc.), a developer (23° C.) shown in Table 5 was sprayed on the wafer for development at a flow rate of 200 mL/min for a predetermined time while rotating the wafer at 50 rpm. S-1, S-2, S-5, S-6, or S-9 shown in Table 5 were used as the developer. In Table 5, a numerical value in “Major Component” denotes a mixing ratio by mol.

[Rinsing]

Next, a rinsing liquid (23° C.) shown in Table 5 was sprayed on the wafer for rinsing at a flow rate of 200 mL/min for a predetermined time while rotating the wafer at 50 rpm. Finally, the wafer was dried while rotating the wafer at a high speed of 2500 rpm for 60 seconds. In Table 5, S-3, S-4, S-7, S-8, S-10 to S-13, SA-1, or SA-2 was used as the rinsing liquid.

The same items of the resist pattern described above in “EUV Exposure Evaluation” were evaluated using the same method as described above, except that a scanning electron microscope “S-9220” (manufactured by Hitachi, Ltd.) was used to evaluate the sensitivity and the resolution limit. The details of the results are shown in Table 7.

TABLE 7

| | | PB | PEB | | | 30 nm Sensitivity | Limit | Residue |
|---|---|---|---|---|---|---|---|---|
| | | (60 Seconds) | (60 Seconds) | Development | Rinsing | [mJ/cm²] | Resolution (nm) | Defects |
| Example 19 | Resist Composition 1 | 120° C. | 100° C. | S-1 | — | 92 | 21 | A |
| Example 20 | Resist Composition 2 | 110° C. | 110° C. | S-2 | S-3 | 124 | 19 | A |
| Example 21 | Resist Composition 3 | 100° C. | 110° C. | S-5 | S-4 | 84 | 18 | A |
| Example 22 | Resist Composition 4 | 90° C. | 110° C. | S-6 | S-7 | 125 | 22 | C |
| Example 23 | Resist Composition 5 | 130° C. | 110° C. | S-1 | S-8 | 112 | 23 | C |
| Example 24 | Resist Composition 6 | 120° C. | 120° C. | S-2 | — | 71 | 24 | A |
| Example 25 | Resist Composition 7 | 110° C. | 80° C. | S-5 | S-3 | 60 | 21 | A |
| Example 26 | Resist Composition 1 | 100° C. | 110° C. | S-6 | S-4 | 74 | 23 | A |
| Example 27 | Resist Composition 2 | 90° C. | 110° C. | S-1 | S-7 | 118 | 20 | C |
| Example 28 | Resist Composition 3 | 130° C. | 90° C. | S-2 | S-8 | 134 | 22 | C |
| Example 29 | Resist Composition 4 | 120° C. | 110° C. | S-1 | S-3 | 85 | 23 | A |
| Example 30 | Resist Composition 5 | 110° C. | 110° C. | S-2 | S-4 | 105 | 17 | A |
| Example 31 | Resist Composition 6 | 100° C. | 110° C. | S-5 | S-7 | 133 | 16 | C |
| Example 32 | Resist Composition 7 | 90° C. | 110° C. | S-9 | S-3 | 90 | 22 | B |
| Example 33 | Resist Composition 2 | 90° C. | 110° C. | S-2 | S-10 | 69 | 25 | C |
| Example 34 | Resist Composition 2 | 100° C. | 110° C. | S-2 | S-11 | 79 | 20 | A |
| Example 35 | Resist Composition 2 | 100° C. | 110° C. | S-2 | S-12 | 105 | 19 | A |
| Example 36 | Resist Composition 2 | 100° C. | 110° C. | S-2 | S-13 | 83 | 18 | A |
| Comparative Example 3 | Resist Composition 1 | 120° C. | 130° C. | S-1 | SA-1 | 150 | 35 | D |
| Comparative Example 4 | Resist Composition 1 | 120° C. | 140° C. | S-1 | SA-2 | 145 | 35 | E |

3. Evaluation Results

It was found from Tables 6 and 7 that, in a case where any exposure light source is used, when the content of the sulfur-containing compound in at least one treatment liquid of the developer or the rinsing liquid is low, the number of residue defects is small (refer to Examples).

On the other hand, it was found that, in a case where at least one treatment liquid of the developer or the rinsing liquid having a low content of the sulfur-containing compound is not used, the number of residue defects increases (refer to Comparative Examples).

This way, it was found that, in a case where at least one treatment liquid of the developer or the rinsing liquid having a low content of the sulfur-containing compound is not used, the number of residue defects increases, which adversely affects the performance of the pattern such as sensitivity or limit resolution.

In addition, it can be seen that, by reducing the content of the sulfur-containing compound and the content of the phosphorus-containing compound as described above, the number of residue defects can be further reduced, the performance of the pattern such as sensitivity or limit resolution can be further improved.

The treatment liquid according to the present invention was stored in the FluoroPurePFA composite drum (manufactured by Entegris, Inc.; inner surface in contact with liquid: PFA resin lining) and the steel drum can (manufactured by JFE Steel Corporation; inner surface in contact with liquid: zinc phosphate coating) using a method described in JP2014-112176A at room temperature for 14 days. In a case where wet particle analysis, organic impurity concentration analysis, and metal impurity concentration analysis were performed on the treatment liquid, it was found that the results of the treatment liquid stored in the FluoroPurePFA composite drum (manufactured by Entegris, Inc.; inner surface in contact with liquid: PFA resin lining) was more satisfactory than those of the treatment liquid stored in the Steel drum can (manufactured by JFE Steel Corporation; inner surface in contact with liquid: zinc phosphate coating).

What is claimed is:

1. A treatment liquid for rinsing and patterning a resist film obtained from an actinic ray-sensitive or radiation-sensitive composition, the treatment liquid including an organic solvent,
wherein
a content of a compound containing a sulfur atom in the treatment liquid is 10 mmol/L or lower, and
the organic solvent is a hydrocarbon solvent.

2. The treatment liquid according to claim 1,
wherein the organic solvent is a hydrocarbon solvent having 5 or more carbon atoms.

3. The treatment liquid according to claim 1,
wherein the hydrocarbon solvent includes undecane.

4. The treatment liquid according to claim 1,
wherein a content of a compound containing a phosphorus atom in the treatment liquid is 10 mmol/L or lower.

5. The treatment liquid according to claim 1,
wherein a boiling point of the compound containing a sulfur atom is 190° C. or higher.

6. A pattern forming method comprising:
forming a resist film using an actinic ray-sensitive or radiation-sensitive composition;
exposing the resist film; and
treating the exposed resist film with the treatment liquid according to claim 1.

7. The pattern forming method according to claim 6,
wherein the treating includes rinsing with a rinsing liquid, and
the rinsing liquid is the treatment liquid.
